(19) United States
(12) Patent Application Publication
(10) Pub. No.: US 2023/0309377 A1
(43) Pub. Date: Sep. 28, 2023

(54) ORGANOMETALLIC COMPOUND, LIGHT-EMITTING DEVICE INCLUDING THE SAME, AND ELECTRONIC APPARATUS INCLUDING THE LIGHT-EMITTING DEVICE

(71) Applicant: Samsung Electronics Co., Ltd., Suwon-si (KR)

(72) Inventors: Jongwon Choi, Seongnam-si (KR); Yongsuk Cho, Hwaseong-si (KR); Ohyun Kwon, Seoul (KR); Bumwoo Park, Yongin-si (KR); Myungsun Sim, Suwon-si (KR); Sunghun Lee, Hwaseong-si (KR); Kijung Jung, Suwon-si (KR); Byoungki Choi, Hwaseong-si (KR); Dmitry KRAVCHUK, Hwaseong-si (KR)

(21) Appl. No.: 18/187,985

(22) Filed: Mar. 22, 2023

(30) Foreign Application Priority Data
Mar. 23, 2022 (KR) 10-2022-0036207

(51) Int. Cl. H10K 85/30; C07F 15/00; C09K 11/06; H10K 85/40

(52) U.S. Cl. CPC H10K 85/342; C07F 15/0033; C09K 11/06; H10K 85/40; C09K 2211/185; C09K 2211/1037; H10K 50/11

(57) ABSTRACT

An organometallic compound represented by Formula 1:

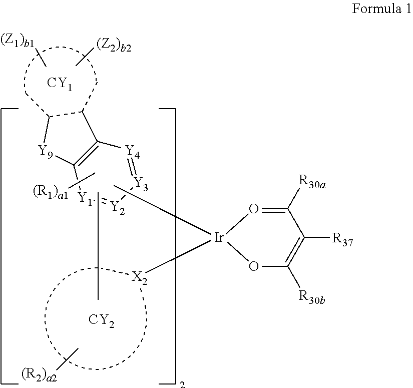

wherein, Y₁ to Y₄ are each independently C or N, one of Y₁ to Y₄ is N bonded to Ir in Formula 1, and one of the remaining Y₁ to Y₄ is C bonded to ring CY₂ in Formula 1, Y₉ is O, S, N(R₁₉), C(R₁₉ₐ)(R_{19b}), or Si(R₁₉ₐ)(R_{19b}), X₂ is C, ring CY₁ and ring CY₂ are each independently a C₅-C₃₀ carbocyclic group or a C₁-C₃₀ heterocyclic group, Z₁ is a group represented by —Si(Q₃)(Q₄)(Q₅) or a group represented by —Ge(Q₃)(Q₄)(Q₅), a1 is an integer from 0 to 2, a2 is an integer from 0 to 20, b1 and b2 are each independently an integer from 1 to 10, and R₁, R₁₉, R₁₉ₐ, R_{19b}, R₂, R₃₀ₐ, R_{30b}, R₃₇, and Z₂ are as described herein.

### CROSS-REFERENCE TO RELATED APPLICATION

This application is based on and claims priority to Korean Patent Application No. 10-2022-0036207, filed on Mar. 23, 2022, in the Korean Intellectual Property Office, and all the benefits accruing therefrom under 35 U.S.C. § 119, the content of which is incorporated by reference herein in its entirety.

### BACKGROUND

### 1. Field

One or more embodiments relate to an organometallic compound, a light-emitting device including the same, and an electronic apparatus including the light-emitting device.

### 2. Description of the Related Art

From among light-emitting devices, organic light-emitting devices (OLEDs) are self-emissive devices that have improved characteristics, including better viewing angles, response time, luminance, driving voltage, and response speed. In addition, OLEDs can produce full-color images.

For example, a typical organic light-emitting device includes an anode, a cathode, and an organic layer located between the anode and the cathode, wherein the organic layer includes an emission layer. A hole transport region may be arranged between the anode and the emission layer, and an electron transport region may be arranged between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transition from an excited state to a ground state to thereby generate light (for example, visible light).

### SUMMARY

Provided are an organometallic compound, a light-emitting device including the same, and an electronic apparatus including the light-emitting device.

Additional aspects will be set forth in part in the detailed description that follows and, in part, will be apparent from the detailed description, or may be learned by practice of the presented one or more exemplary embodiments provided herein.

According to one or more aspects, provided is an organometallic compound represented by Formula 1.

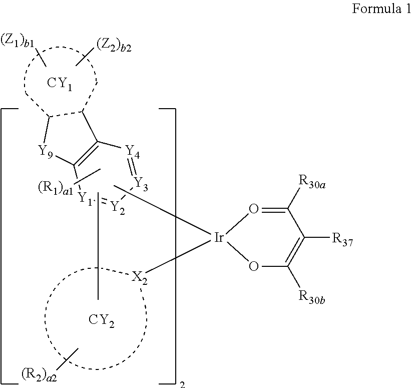

In Formula 1,
Y₁ to Y₄ are each independently C or N,
one of Y₁ to Y₄ is N bonded to Ir in Formula 1, and one of the remaining Y₁ to Y₄ is C bonded to ring CY₂ in Formula 1,
Y₉ is O, S, N(R₁₉), C(R₁₉ₐ)(R_{19b}), or Si(R₁₉ₐ)(R_{19b}),
X₂ is C,
ring CY₁ and ring CY₂ are each independently a C₅-C₃₀ carbocyclic group or a C₁-C₃₀ heterocyclic group,
Z₁ is a group represented by —Si(Q₃)(Q₄)(Q₅) or a group represented by —Ge(Q₃)(Q₄)(Q₅),
R₁, R₁₉, R₁₉ₐ, R_{19b}, R₂, R₃₀ₐ, R_{30b}, R₃₇, and Z₂ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —B(Q₆)(Q₇), —P(═O)(Q₈)(Q₉), or —P(Q₈)(Q₉),
with the provisos that i) at least one of Z₂ is not hydrogen, and ii) at least one of R₃₀ₐ and R_{30b} is not a methyl group,
a1 is an integer from 0 to 2,
a2 is an integer from 0 to 20,
b1 and b2 are each independently an integer from 1 to 10,
two R₁ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of a plurality of R₂ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of R₃₀ₐ, R_{30b}, and R₃₇ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
R₁₀ₐ is as described in connection with R₁,
substituents of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group are each independently:
deuterium, —F, —Cl, —Br, —I, —SF₅, —CDs, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —SF₅, —CDs, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ aryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof,
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉), or
a combination thereof, and
Q₁ to Q₉, Q₁₁ to Q₁₉, Q₂₁ to Q₂₉, and Q₃₁ to Q₃₉ are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

According to another aspect, provided is a light-emitting device including a first electrode, a second electrode, and an organic layer arranged between the first electrode and the second electrode, wherein the organic layer includes an emission layer, and wherein the organic layer includes at least one organometallic compound represented by Formula 1.

The organometallic compound may be included in the emission layer of the organic layer, and the organometallic compound included in the emission layer may act as a dopant.

According to still another aspect, also provided is an electronic apparatus including the light-emitting device.

### BRIEF DESCRIPTION OF THE DRAWING

The above and other aspects, features, and advantages of certain exemplary embodiments will be more apparent from the following detailed description taken in conjunction with the accompanying drawing, in which:

The FIGURE is a schematic cross-sectional view of a light-emitting device according to one or more embodiments.

### DETAILED DESCRIPTION

Reference will now be made in further detail to exemplary embodiments, examples of which are illustrated in the accompanying drawings, wherein like reference numerals refer to like elements throughout the detailed description. In this regard, the present exemplary embodiments may have different forms and should not be construed as being limited to the detailed descriptions set forth herein. Accordingly, the exemplary embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Hereinafter, a work function or a highest occupied molecular orbital (HOMO) energy level is expressed as an absolute value from a vacuum level. In addition, when the work function or the HOMO energy level is referred to be “deep,” “high” or “large,” the work function or the HOMO energy level has a large absolute value based on “0 eV” of the vacuum level, while when the work function or the HOMO energy level is referred to be “shallow,” “low,” or “small,” the work function or HOMO energy level has a small absolute value based on “0 eV” of the vacuum level.

An organometallic compound according to an aspect is represented by Formula 1:

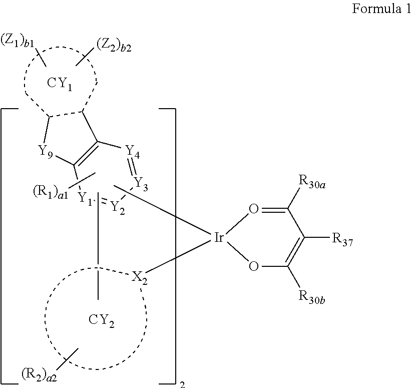

wherein, Y₁ to Y₄ in Formula 1 are each independently C or N. One of Y₁ to Y₄ is N bonded to Ir in Formula 1, and one of the remaining Y₁ to Y₄ is C bonded to ring CY₂ in Formula 1.

In one or more embodiments,
1) Y₂ may be N bonded to Ir in Formula 1, and Y₁ may be C bonded to ring CY₂ in Formula 1,
2) Y₁ may be N bonded to Ir in Formula 1, and Y₂ may be C bonded to ring CY₂ in Formula 1,
3) Y₃ may be N bonded to Ir in Formula 1, and Y₂ may be C bonded to ring CY₂ in Formula 1,
4) Y₂ may be N bonded to Ir in Formula 1, and Y₃ may be C bonded to ring CY₂ in Formula 1,
5) Y₄ may be N bonded to Ir in Formula 1, and Y₃ may be C bonded to ring CY₂ in Formula 1, or
6) Y₃ may be N bonded to Ir in Formula 1, and Y₄ may be C bonded to ring CY₂ in Formula 1.

In Formula 1, Y₉ is O, S, N(R₁₉), C(R₁₉ₐ)(R_{19b}), or Si(R₁₉ₐ)(R_{19b}). R₁₉, R₁₉ₐ, and R_{19b} may each independently be as described herein.

In one or more embodiments, Y₉ may be O, S, or N(R₁₉).

In one or more embodiments, Y₉ may be O or S.

In Formula 1, X₂ is C.

In Formula 1, ring CY₁ and ring CY₂ are each independently a C₅-C₃₀ carbocyclic group or a C₁-C₃₀ heterocyclic group.

In one or more embodiments, ring CY₂ in Formula 1 may be a 6-membered monocyclic group (for example, a benzene group, a pyridine group, a pyrimidine group, a pyrazine group, a pyridazine group, a triazine group, or the like).

In one or more embodiments, ring CY₂ in Formula 1 may be a polycyclic group in which two or more cyclic groups are condensed with each other, and each of the cyclic groups may be a 6-membered monocyclic group (for example, a benzene group, a pyridine group, a pyrimidine group, a pyrazine group, a pyridazine group, a triazine group, or the like) or a 5-membered monocyclic group (for example, a furan group, a thiophene group, a pyrrole group, a cyclopentadiene group, a silole group, or the like).

In one or more embodiments, ring CY₁ and ring CY₂ in Formula 1 may each independently be i) a first ring, ii) a second ring, iii) a condensed ring in which two or more first rings are condensed with each other, iv) a condensed ring in which two or more second rings are condensed with each other, or v) a condensed ring in which one or more first rings and one or more second rings are condensed with each other,
the first ring may be a cyclopentane group, a cyclopentene group, a furan group, a thiophene group, a pyrrole group, a silole group, a germole group, a borole group, a selenophene group, a phosphole group, an oxazole group, an oxadiazole group, an oxatriazole group, a thiazole group, a thiadiazole group, a thiatriazole group, a pyrazole group, an imidazole group, a triazole group, a tetrazole group, an azasilole group, an azagermole group, an azaborole group, an azaselenophene group, or an azaphosphole group, and
the second ring may be an adamantane group, a norbornane group, a norbornene group, a bicyclo[1.1.1]pentane group, a bicyclo[2.1.1]hexane group, a bicyclo[2.2.2]octane group, a cyclohexane group, a cyclohexene group, a benzene group, a pyridine group, a pyrimidine group, a pyrazine group, a pyridazine group, or a triazine group.

In one or more embodiments, ring CY₁ and ring CY₂ in Formula 1 may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a thiophene group, a furan group, a pyrrole group, a cyclopentadiene group, a silole group, a borole group, a phosphole group, a selenophene group, a germole group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a fluorene group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an iso-oxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, adamantane group, a norbornane group, or a norbornene group.

In one or more embodiments, ring CY₁ and ring CY₂ in Formula 1 may each independently be a benzene group, a naphthalene group, a phenanthrene group, a pyridine group, a pyrimidine group, a pyrazine group, a pyridazine group, a quinoline group, an isoquinoline group, a quinoxaline group, a benzoquinoline group, a benzoisoquinoline group, a benzoquinoxaline group, a benzofuran group, or a benzothiophene group.

In one or more embodiments, in Formula 1,
ring CY₁ may be a benzene group, a naphthalene group, a phenanthrene group, a pyridine group, a pyrimidine group, a pyrazine group, a pyridazine group, a quinoline group, an isoquinoline group, a quinoxaline group, a benzoquinoline group, a benzoisoquinoline group, a benzoquinoxaline group, a benzofuran group, or a benzothiophene group, and
ring CY₂ may be a naphthalene group, a phenanthrene group, a quinoline group, an isoquinoline group, a quinoxaline group, a benzoquinoline group, a benzoisoquinoline group, a benzoquinoxaline group, a benzofuran group, or a benzothiophene group.

Z₁ in Formula 1 is a group represented by —Si(Q₃)(Q₄)(Q₅) or a group represented by —Ge(Q₃)(Q₄)(Q₅). Q₃ to Q₅ are each independently as described herein.

R₁, R₁₉, R₁₉ₐ, R_{19b}, R₂, R₃₀ₐ, R_{30b}, R₃₇, and Z₂ in Formula 1 are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₁-C₆₀ heteroaryl alkyl group, a substituted or unsubstituted C₁-C₆₀ heteroaryloxy group, a substituted or unsubstituted C₆-C₆₀ arylthio group, a substituted or unsubstituted monovalent non-aromatic condensed polycyclic group, a substituted or unsubstituted monovalent non-aromatic condensed heteropolycyclic group, —N(Q₁)(Q₂), —B(Q₆)(Q₇), —P(═O)(Q₈)(Q₉), or —P(Q₈)(Q₉), with the provisos that i) at least one of Z₂ is not hydrogen, and ii) at least one of R₃₀ₐ and R_{30b} is not a methyl group.
Q₁ to Q₉ are each independently as described herein.

In one or more embodiments, R₃₀ₐ in Formula 1 may be a group represented by *—C(R₃₁)(R₃₂)(R₃₃). Definitions for each of R₃₁ to R₃₃ may each independently be as provided for the definition of R₃₀ₐ described herein.
R_{30b} in Formula 1 may be a group represented by *—C(R₃₄)(R₃₅)(R₃₆). Definitions for each of R₃₄ to R₃₆ may each independently be as provided for the definition of R_{30b} described herein.

For example, R₁, R₁₉, R₁₉ₐ, R_{19b}, R₂, R₃₀ₐ, R_{30b}, R₃₇, and Z₂ may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₁-C₂₀ alkoxy group, or a C₁-C₂₀ alkylthio group;
a C₁-C₂₀ alkyl group, a C₂-C₂₀ alkenyl group, a C₁-C₂₀ alkoxy group, or a C₁-C₂₀ alkylthio group, each substituted with at least one of deuterium, —F, —Cl, —Br, —I, —SF₅, —CD₃,-CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₂-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₁)(Q₂), —B(Q₆)(Q₇), —P(═O)(Q₈)(Q₉), or —P(Q₈)(Q₉).

In one or more embodiments, Q₁ to Q₉ may each independently be:
deuterium, —F, —CH₃, —CD₃, —CD₂H, —CDH₂, —CH₂CH₃, —CH₂CD₃, —CH₂CD₂H,-CH₂CDH₂, —CHDCH₃, —CHDCD₂H, —CHDCDH₂, —CHDCD₃, —CD₂CD₃, —CD₂CD₂H,-CD₂CDH₂, —CF₃, —CF₂H, —CFH₂, —CH₂CF₃, —CH₂CF₂H, —CH₂CFH₂, —CHFCH₃, —CHFCF₂H, —CHFCFH₂, —CHFCF₃, —CF₂CF₃, —CF₂CF₂H, or —CF₂CFH₂; or
an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, —F, a C₁-C₁₀ alkyl group, a phenyl group, or a combination thereof.

In one or more embodiments, R₁, R₁₉, R₁₉ₐ, R_{19b}, R₂, R₃₀ₐ, R_{30b}, R₃₇, and Z₂ may each independently be:
hydrogen, deuterium, —F, or a cyano group;
a C₁-C₂₀ alkyl group that is unsubstituted or substituted with at least one of deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof; or
a C₃-C₁₀ cycloalkyl group, a C₁-C₁₀ heterocycloalkyl group, a phenyl group, a biphenyl group, a naphthyl group, a pyridinyl group, a fluorenyl group, a carbazolyl group, a dibenzofuranyl group, or a dibenzothiophenyl group, each unsubstituted or substituted with at least one of deuterium, —F, a cyano group, a C₁-C₂₀ alkyl group, a deuterated C₁-C₂₀ alkyl group, a fluorinated C₁-C₂₀ alkyl group, a C₁-C₂₀ alkoxy group, a C₁-C₂₀ alkylthio group, a deuterated C₁-C₂₀ alkoxy group, a fluorinated C₁-C₂₀ alkoxy group, a deuterated C₁-C₂₀ alkylthio group, a fluorinated C₁-C₂₀ alkylthio group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof.

In one or more embodiments, at least one of Z₂(s) in the number of b2 in Formula 1 may include at least one carbon atom.

In one or more embodiments, all of Z₂(s) in the number of b2 in Formula 1 may not include —F.

In one or more embodiments, Z₂ in Formula 1 may be:
—F;
a C₁-C₂₀ alkyl group that is unsubstituted or substituted with at least one of deuterium, —F, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, or a combination thereof; or
a C₃-C₁₀ cycloalkyl group that is unsubstituted or substituted with at least one of deuterium, —F, a C₁-C₂₀ alkyl group, a deuterated C₁-C₂₀ alkyl group, a fluorinated C₁-C₂₀ alkyl group, a C₁-C₂₀ alkoxy group, a C₁-C₂₀ alkylthio group, or a combination thereof.

In one or more embodiments, R₃₇ in Formula 1 may be hydrogen, deuterium, a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted monovalent non-aromatic condensed polycyclic group, or a substituted or unsubstituted monovalent non-aromatic condensed heteropolycyclic group.

In one or more embodiments, R₁, R₁₉, R₁₉ₐ, R_{19b}, R₂, R₃₀ₐ, R_{30b}, R₃₇, and Z₂ may each independently be hydrogen, deuterium, —F, —CH₃, —CDs, —CD₂H, —CDH₂, —CF₃, —CF₂H, —CFH₂, a C₂-C₁ alkenyl group, a C₁-C₁₀ alkoxy group, a C₁-C₁₀ alkylthio group, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-237, a group represented by one of Formulae 9-201 to 9-237 in which at least one hydrogen is substituted with deuterium, a group represented by one of Formulae 9-201 to 9-237 in which at least one hydrogen is substituted with —F, a group represented by one of Formulae 10-1 to 10-129, a group represented by one of Formulae 10-1 to 10-129 in which at least one hydrogen is substituted with deuterium, a group represented by one of Formulae 10-1 to 10-129 in which at least one hydrogen is substituted with —F, a group represented by one of Formulae 10-201 to 10-350, a group represented by one of Formulae 10-201 to 10-350 in which at least one hydrogen is substituted with deuterium, or a group represented by one of Formulae 10-201 to 10-350 in which at least one hydrogen is substituted with —F (wherein i) at least one of Z₂ is not hydrogen, and ii) at least one of R₃₀ₐ and R_{30b} is not a methyl group).

In one or more embodiments, Z₂ may be —F, —SF₅, —CH₃, —CDs, —CD₂H, —CDH₂, —CF₃, —CF₂H, —CFH₂, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-227, a group represented by one of Formulae 9-201 to 9-227 in which at least one hydrogen is substituted with deuterium, a group represented by one of Formulae 9-201 to 9-227 in which at least one hydrogen is substituted with —F, a group represented by one of Formulae 10-1 to 10-9, a group represented by one of Formulae 10-1 to 10-9 in which at least one hydrogen is substituted with deuterium, or a group represented by one of Formulae 10-1 to 10-9 in which at least one hydrogen is substituted with —F.

In one or more embodiments, Z₂ may be —CH₃, —CD₃, —CD₂H, —CDH₂, a group represented by one of Formulae 9-1 to 9-39, a group represented by one of Formulae 9-1 to 9-39 in which at least one hydrogen is substituted with deuterium, a group represented by one of Formulae 9-201 to 9-227, a group represented by one of Formulae 9-201 to 9-227 in which at least one hydrogen is substituted with deuterium, a group represented by one of Formulae 10-1 to 10-9, or a group represented by one of Formulae 10-1 to 10-9 in which at least one hydrogen is substituted with deuterium:

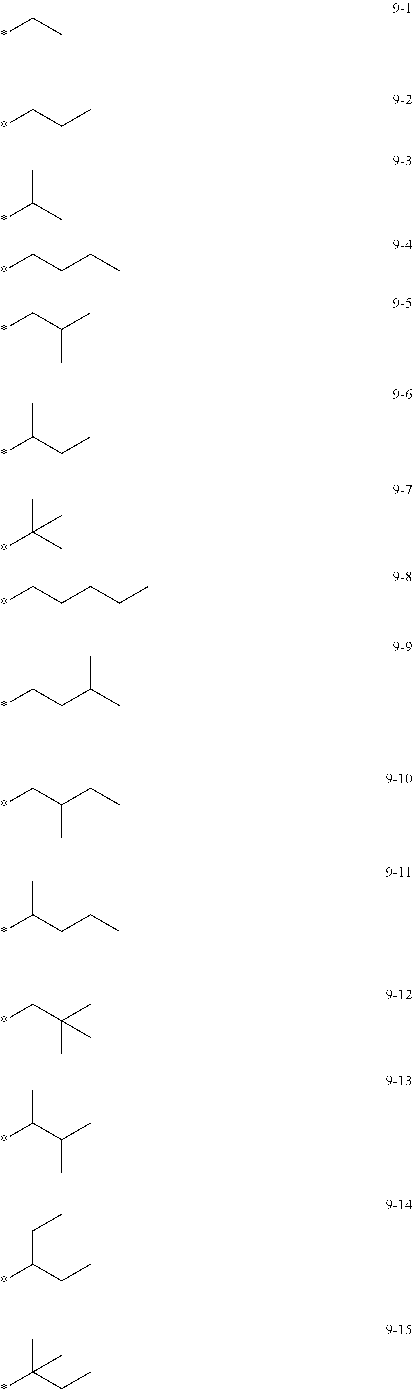

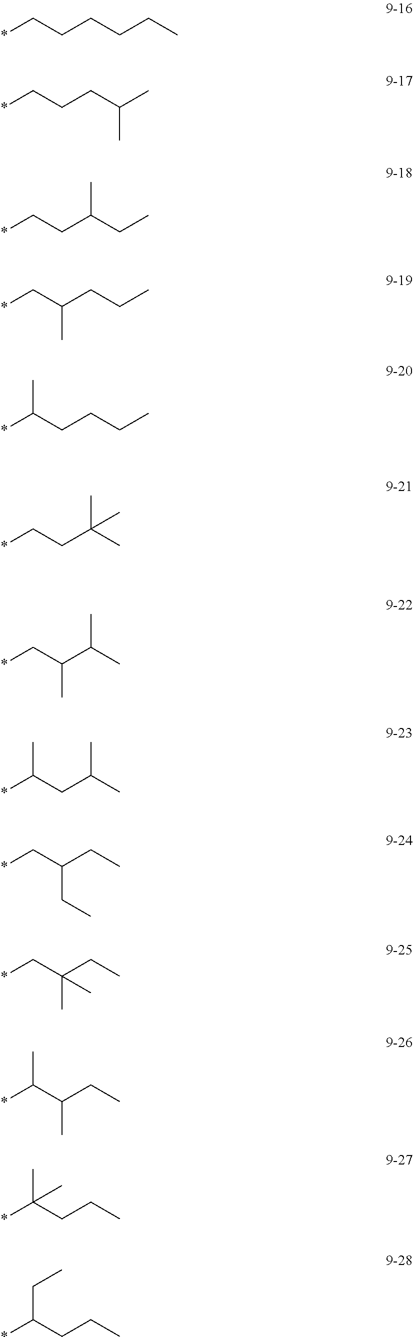

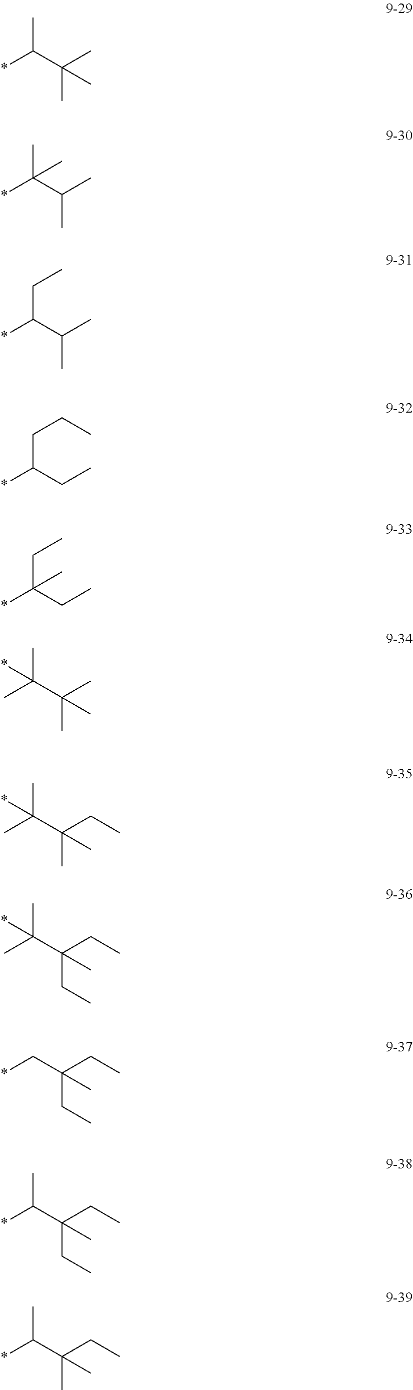

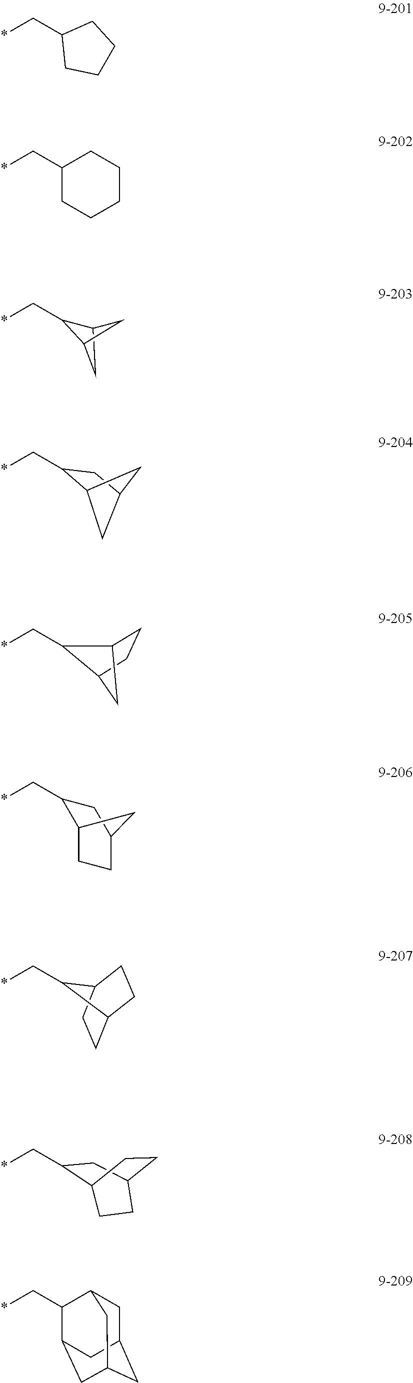

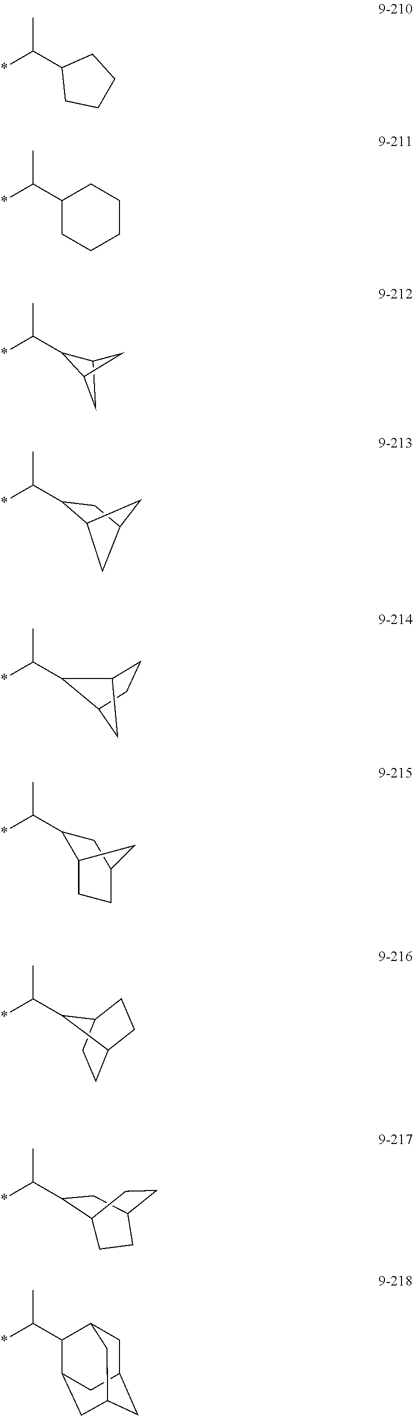

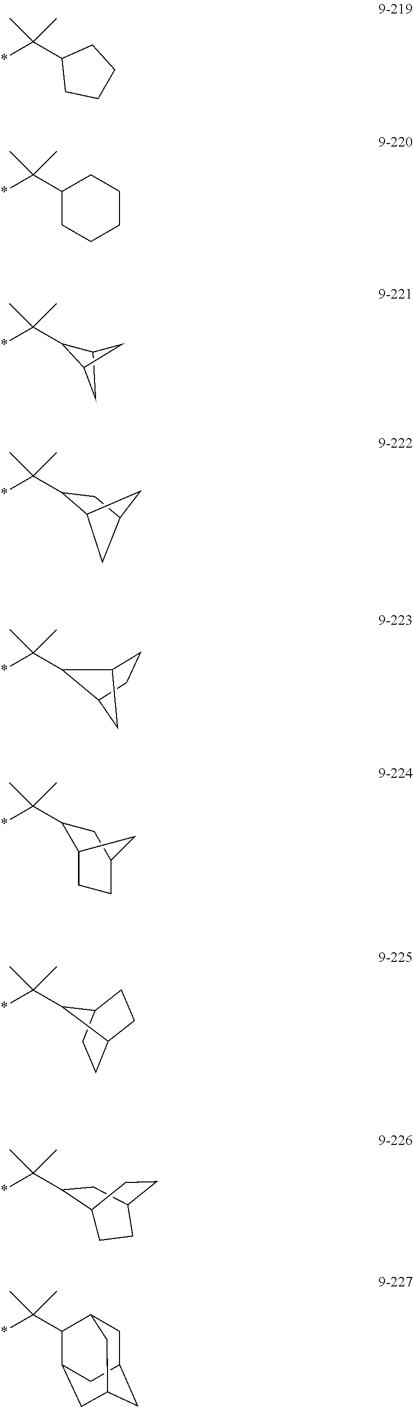

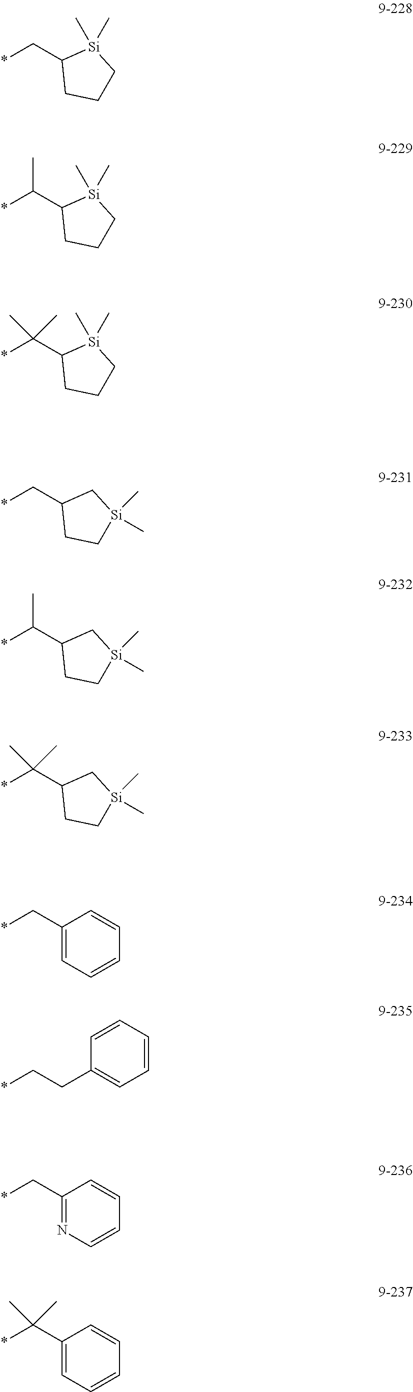

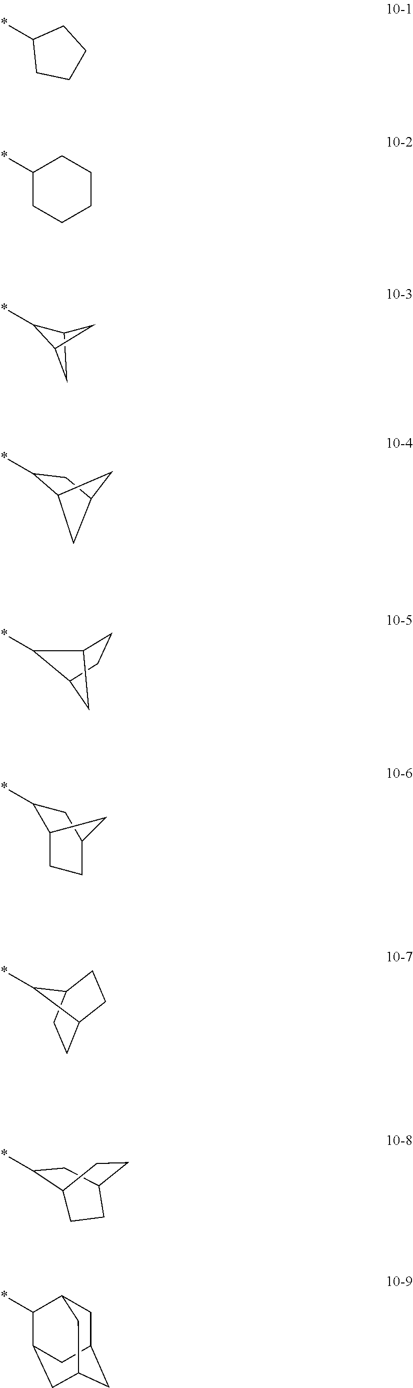

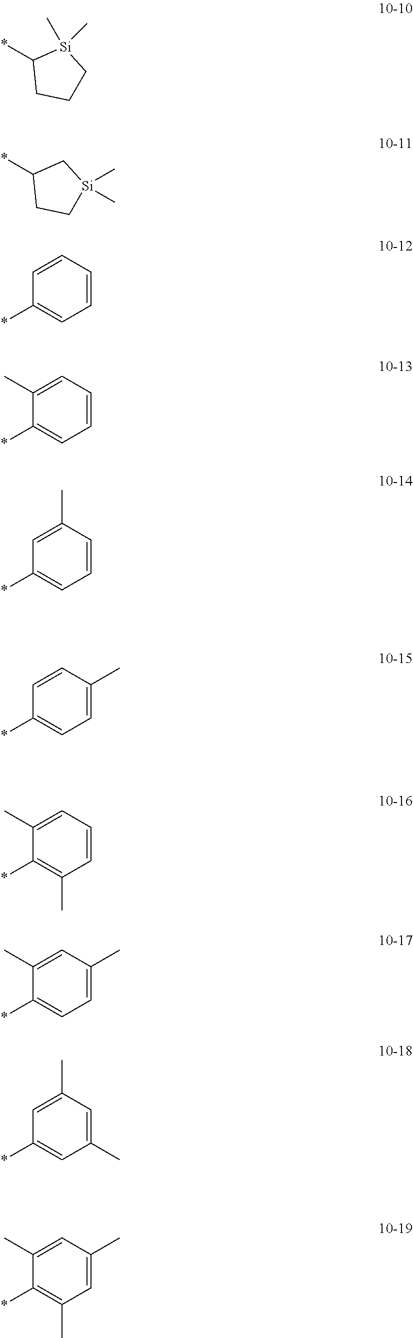

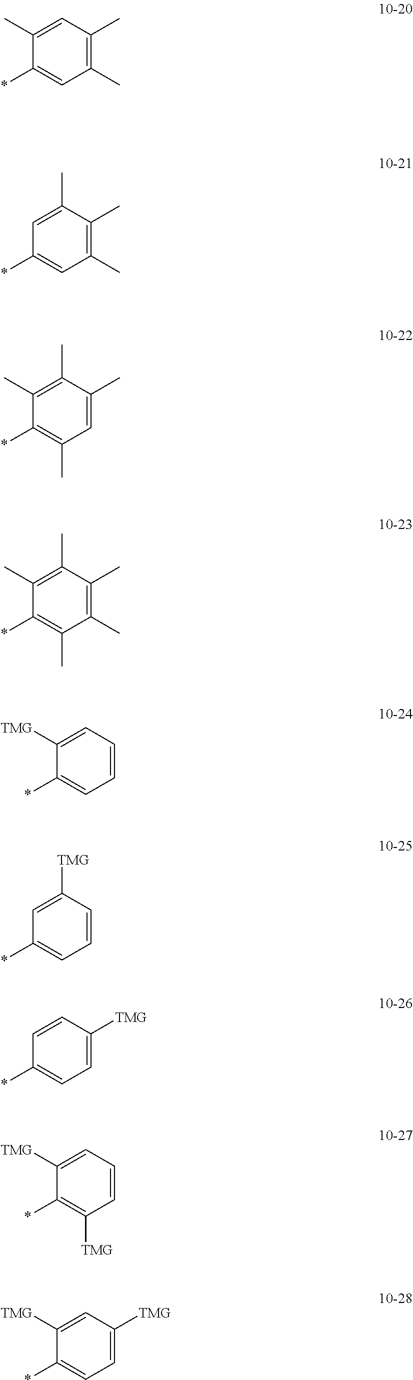

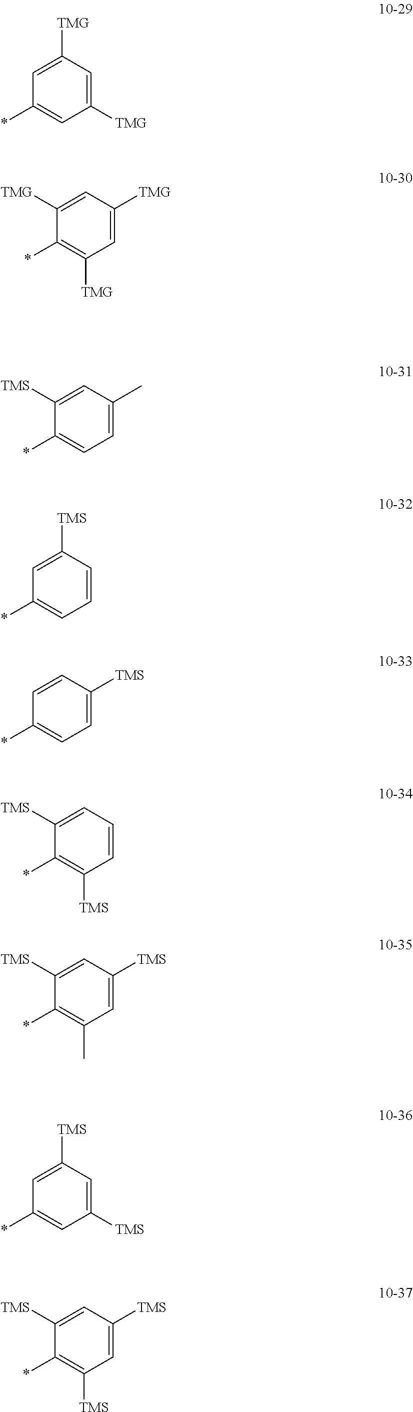

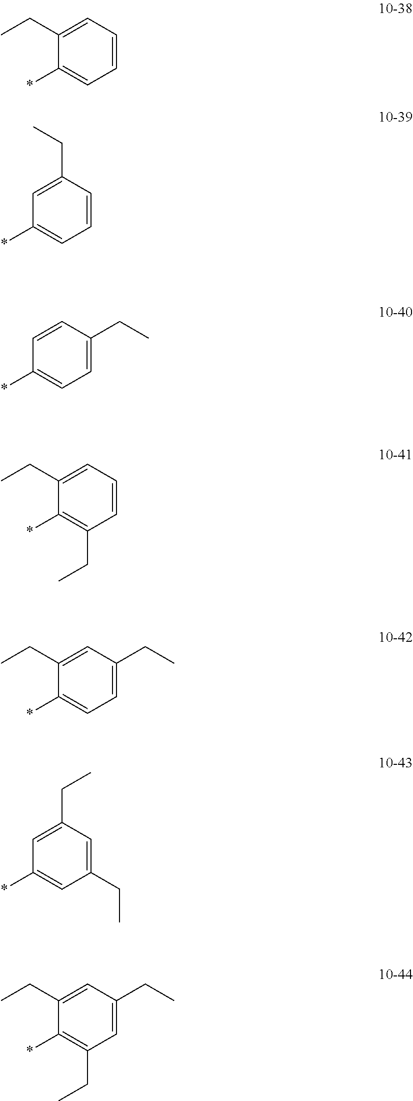

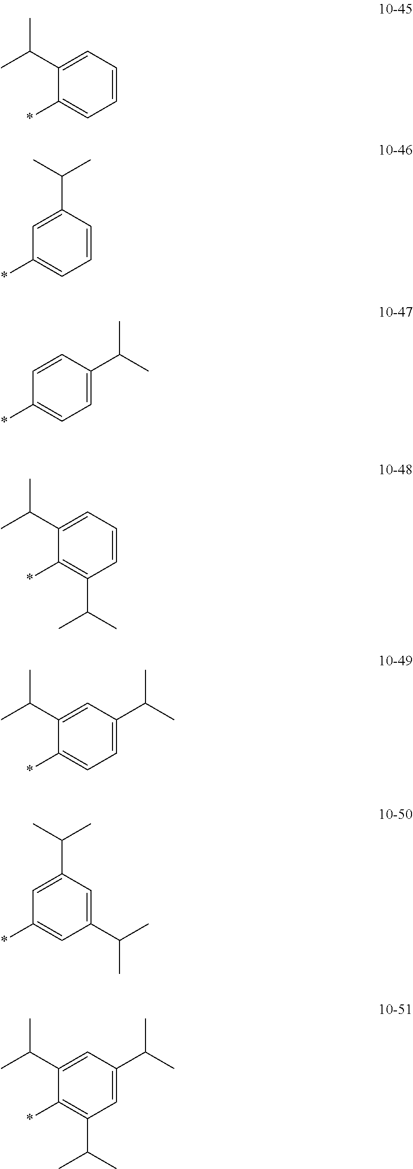

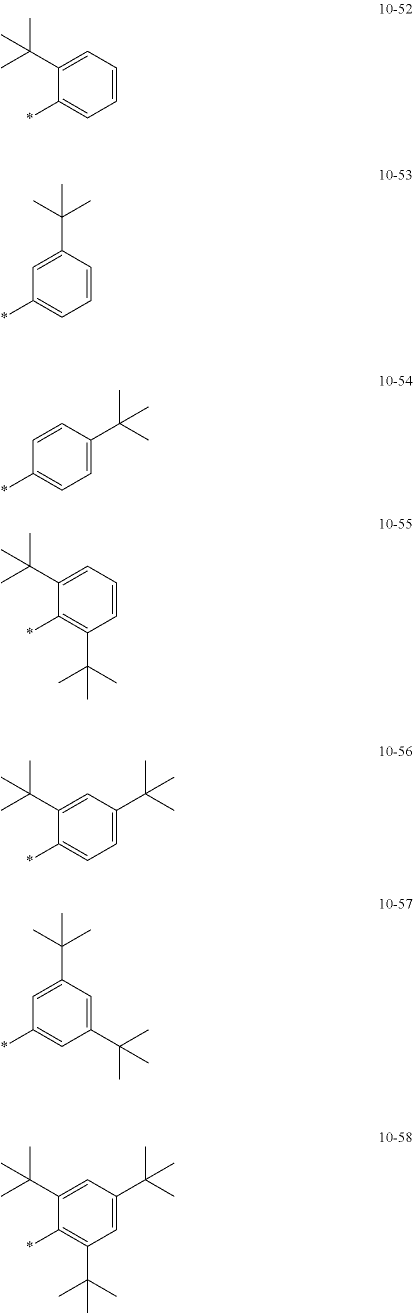

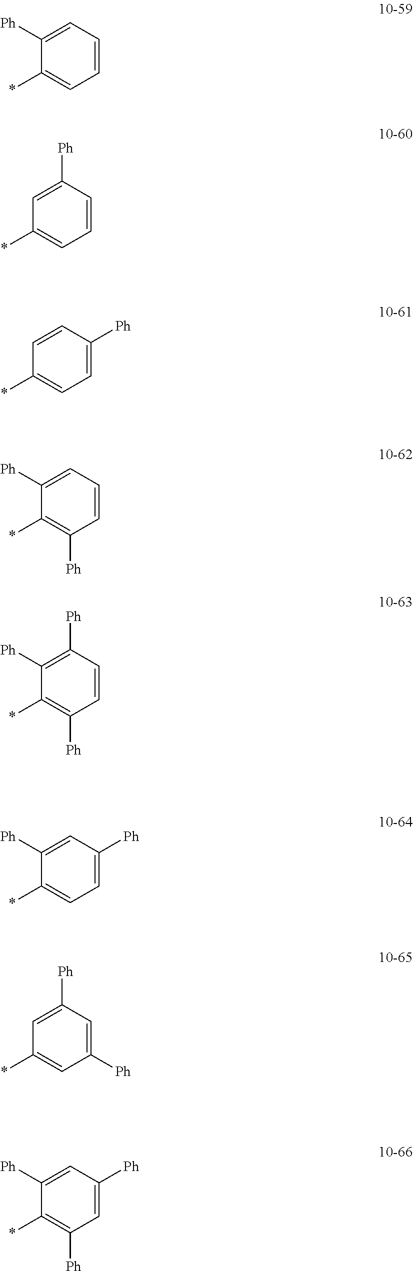

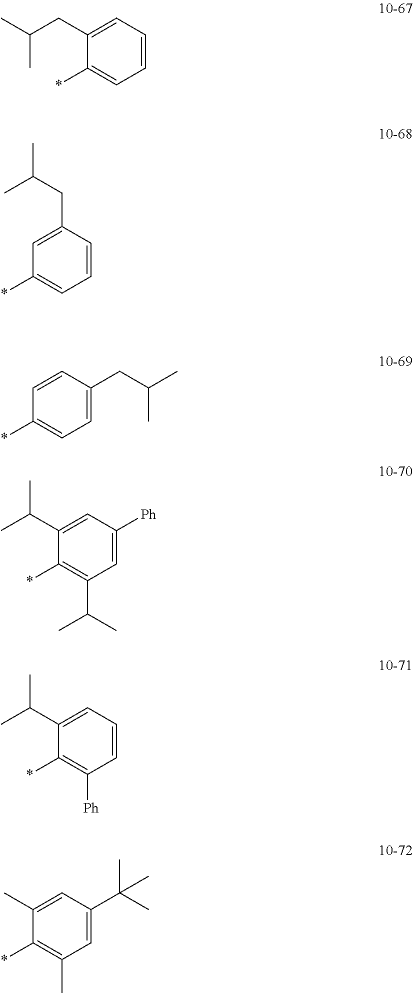

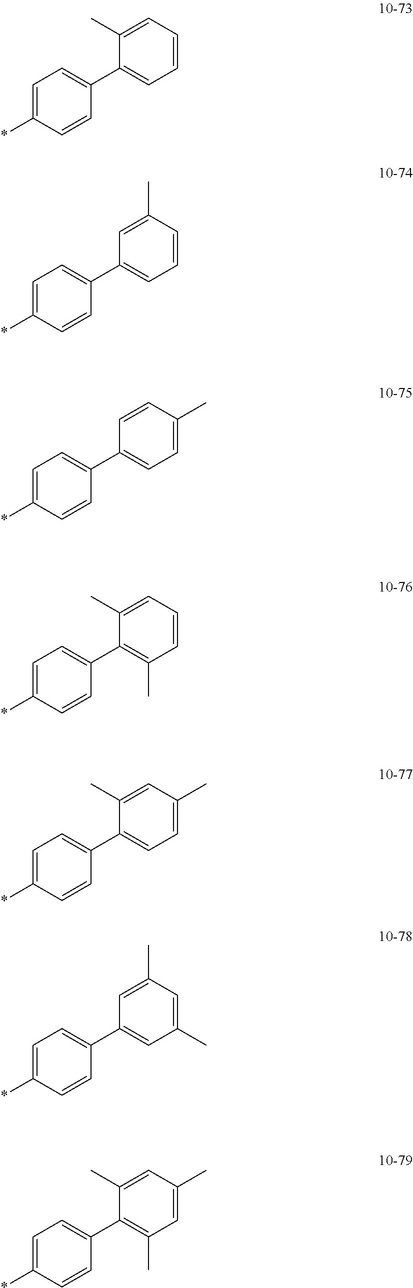

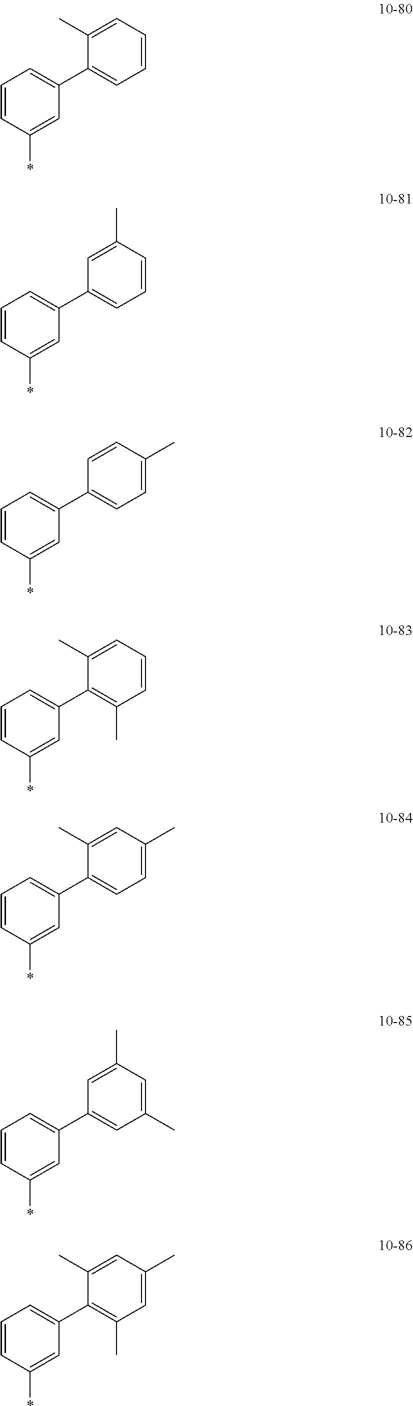

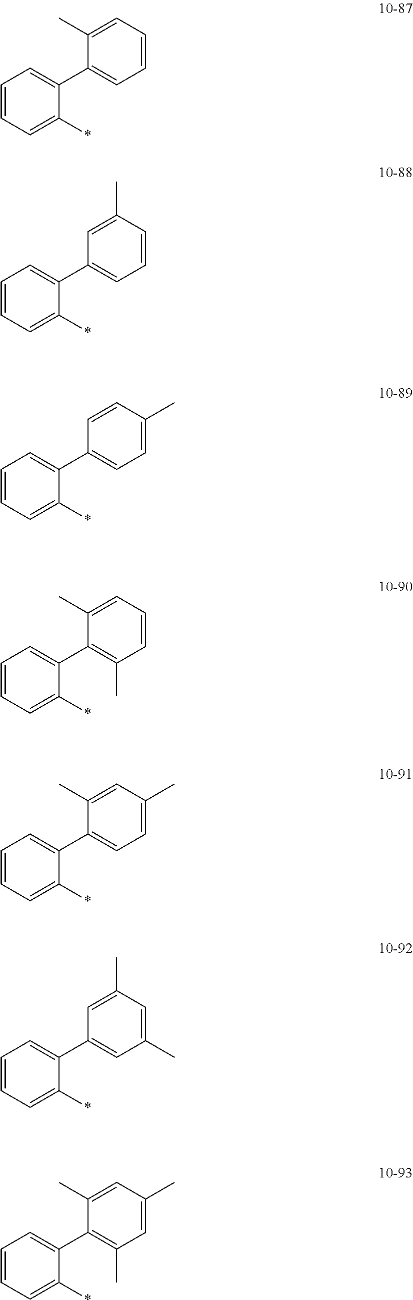

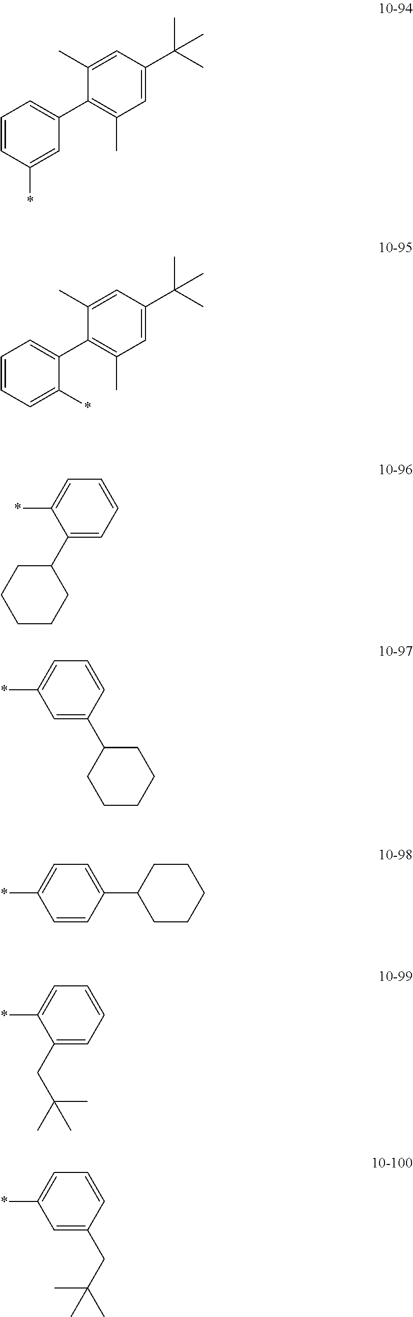

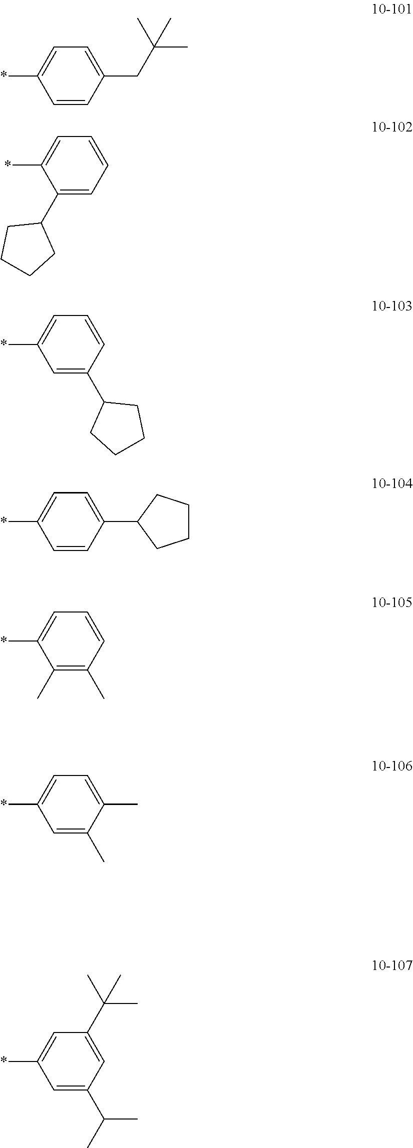

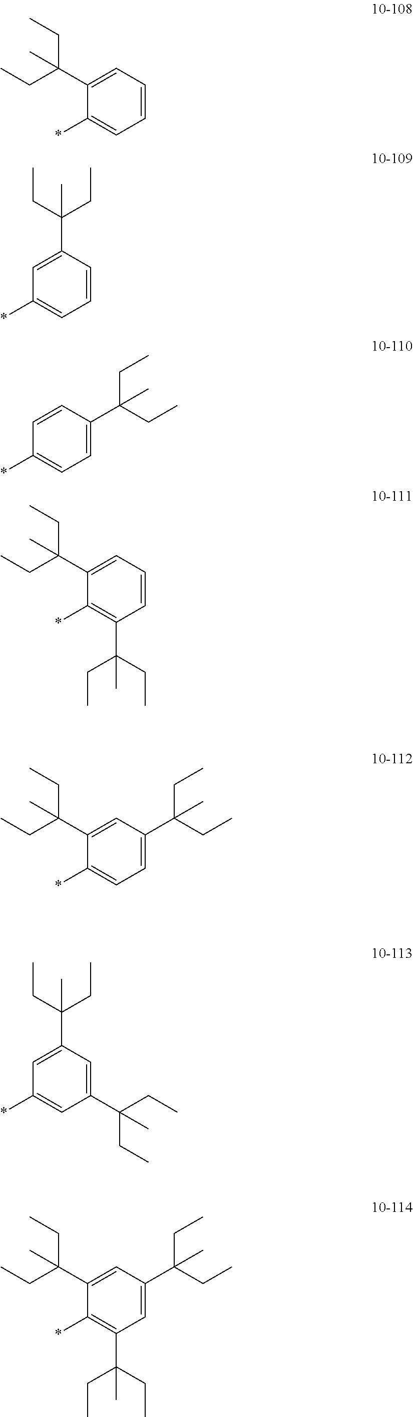

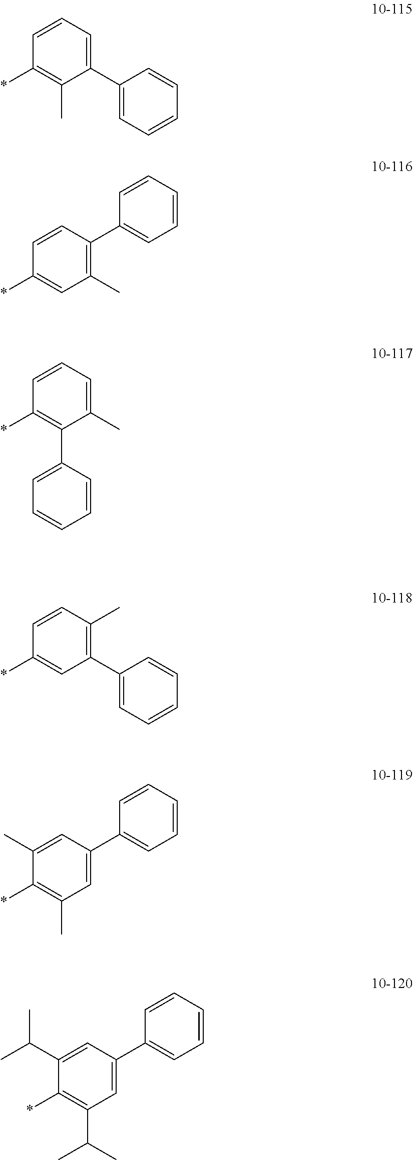

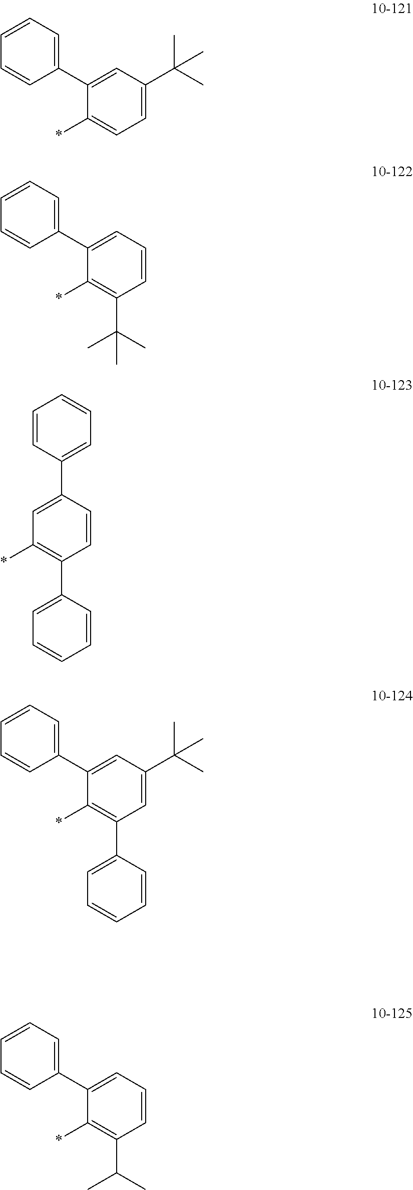 [SMILES: *c1ccc(C(C)(C)C)cc1-c1ccccc1 ; *c1c(-c2ccccc2)cccc1C(C)(C)C ; *c1cc(-c2ccccc2)ccc1-c1ccccc1 ; *c1c(-c2ccccc2)cc(C(C)(C)C)cc1-c1ccccc1 ; *c1c(-c2ccccc2)cccc1C(C)C]

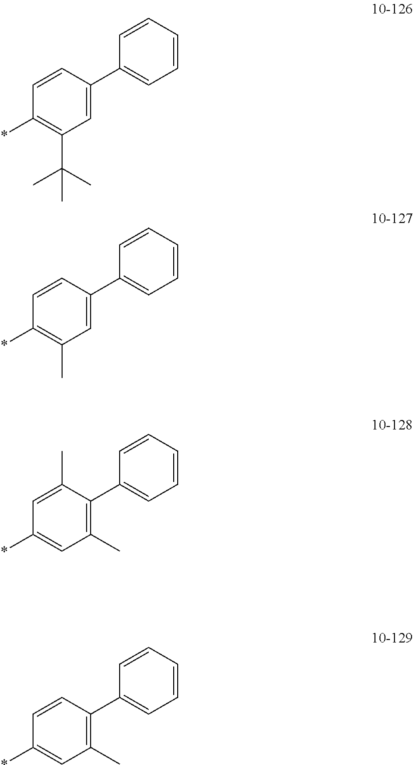 [SMILES: *c1ccc(-c2ccccc2)cc1C(C)(C)C ; *c1ccc(-c2ccccc2)cc1C ; *c1cc(C)c(-c2ccccc2)c(C)c1 ; *c1ccc(-c2ccccc2)c(C)c1]

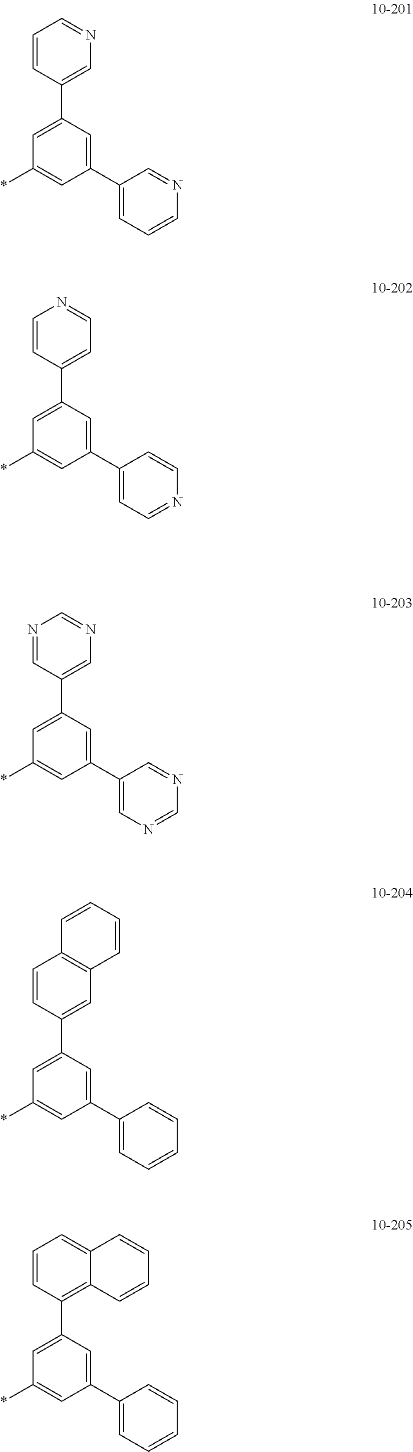 [SMILES: *c1cc(-c2cccnc2)cc(-c2cccnc2)c1 ; *c1cc(-c2ccncc2)cc(-c2ccncc2)c1 ; *c1cc(-c2cncnc2)cc(-c2cncnc2)c1 ; *c1cc(-c2ccccc2)cc(-c2ccc3ccccc3c2)c1 ; *c1cc(-c2ccccc2)cc(-c2cccc3ccccc23)c1]

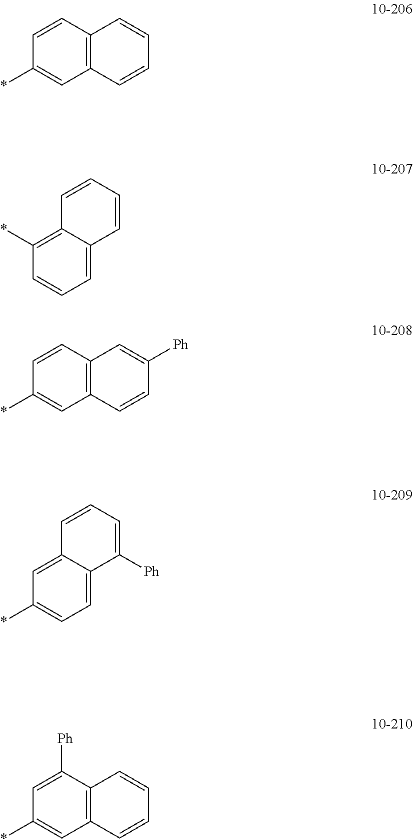 [SMILES: *c1ccc2ccccc2c1 ; *c1cccc2ccccc12 ; *c1ccc2cc(-c3ccccc3)ccc2c1 ; *c1ccc2c(-c3ccccc3)cccc2c1 ; *c1cc(-c2ccccc2)c2ccccc2c1]

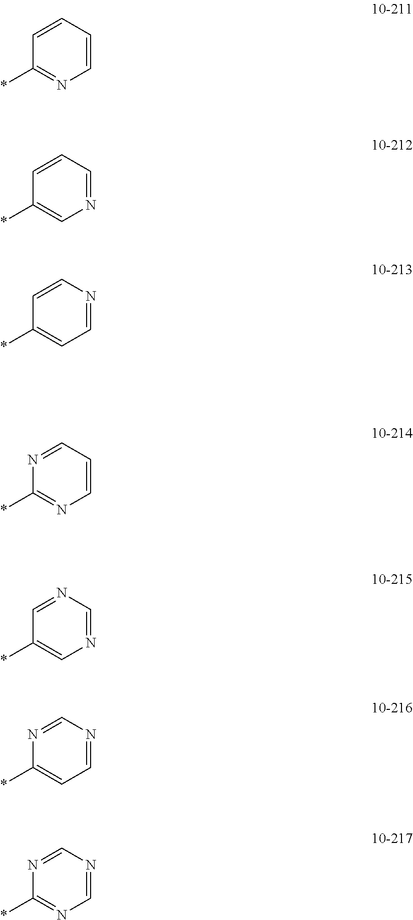

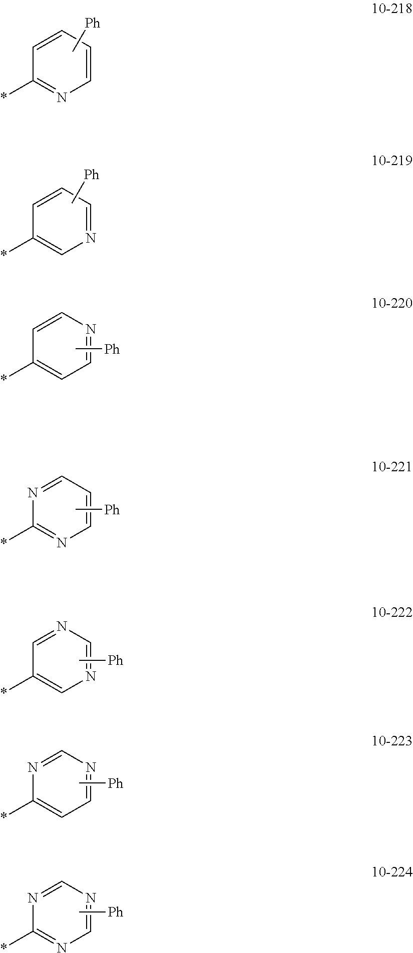

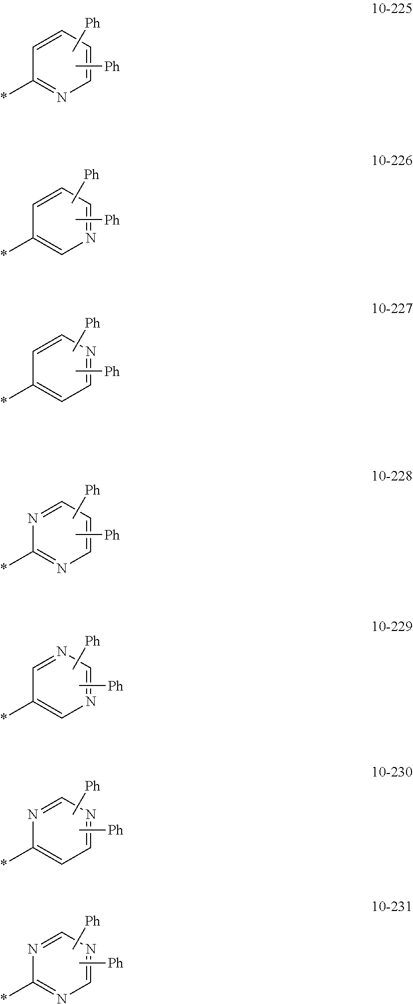

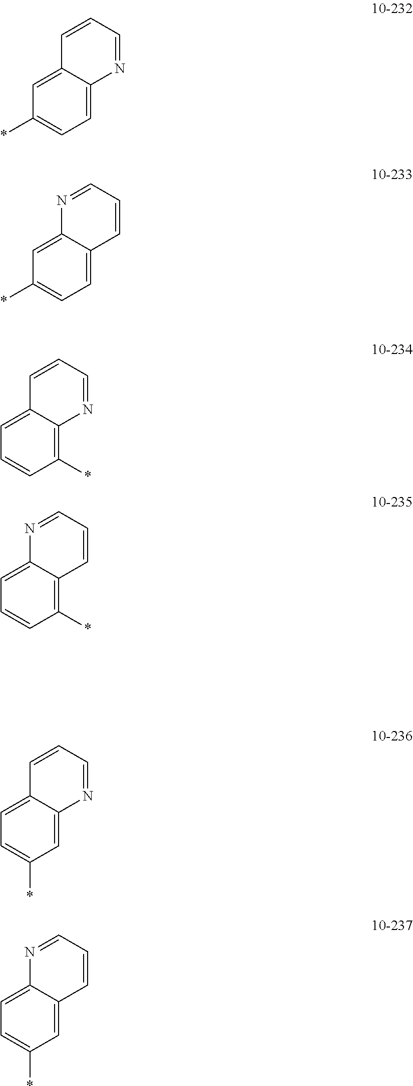

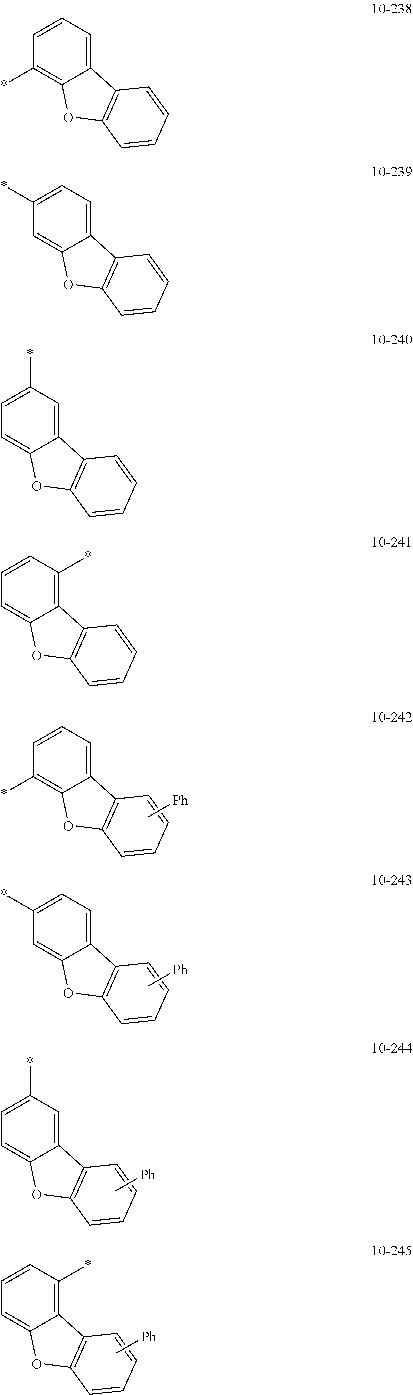

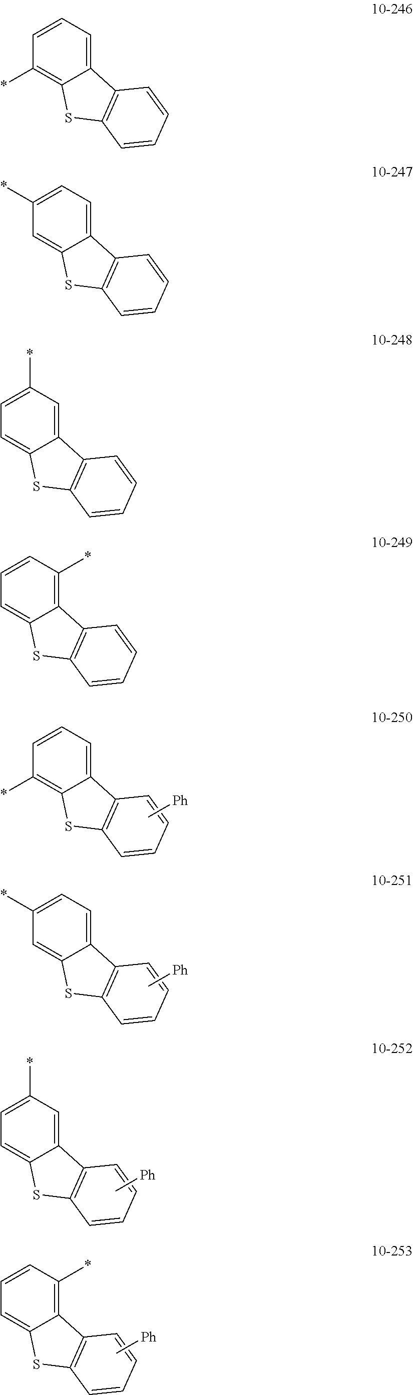

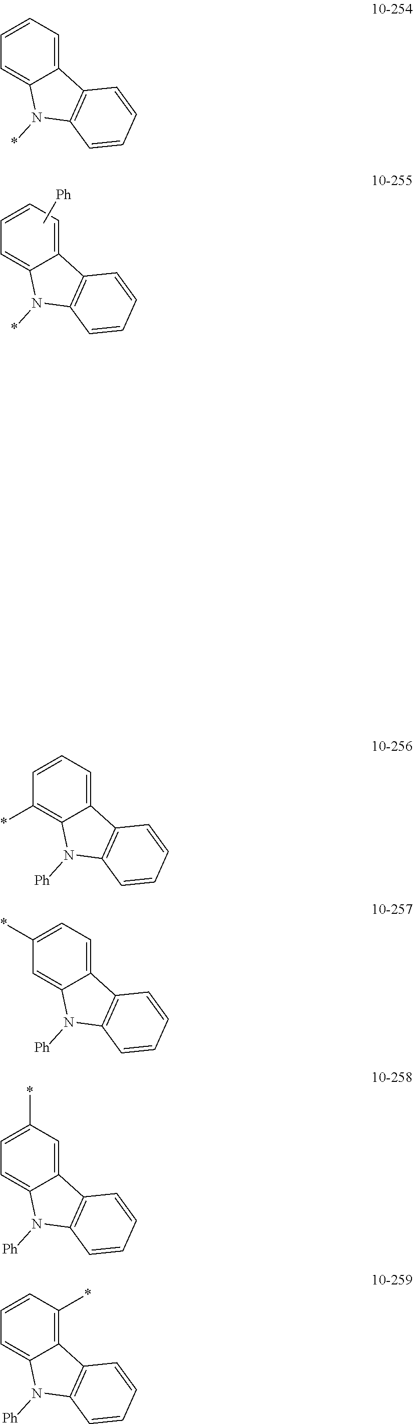

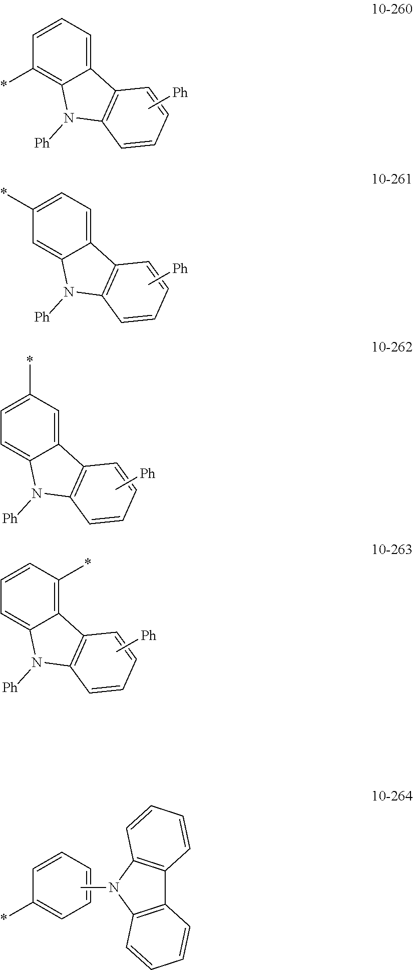

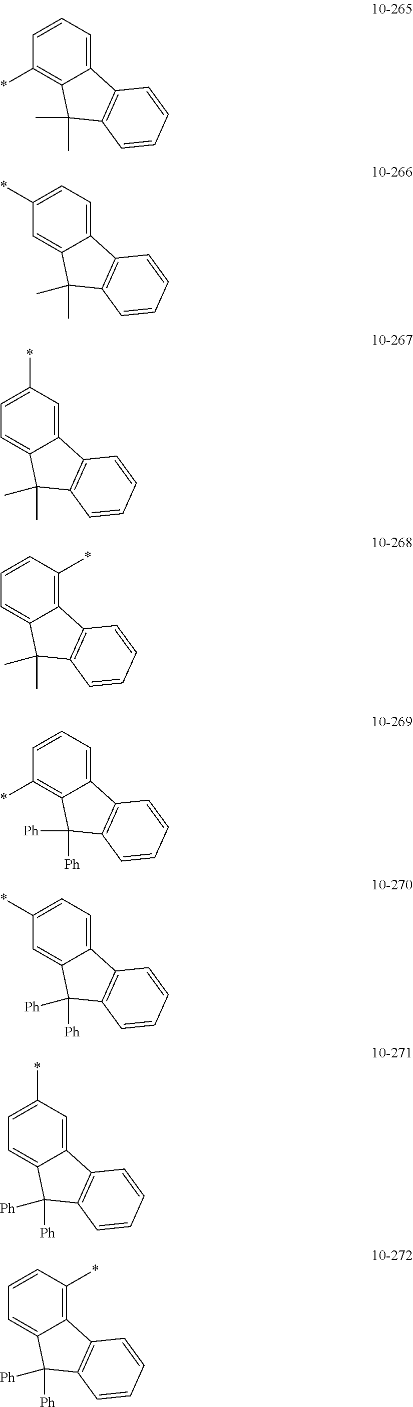

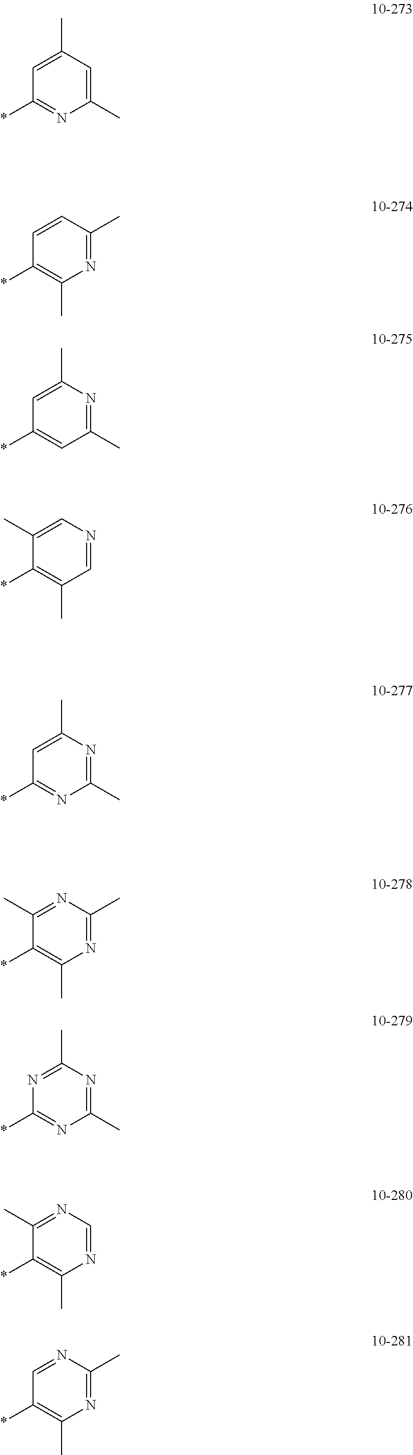

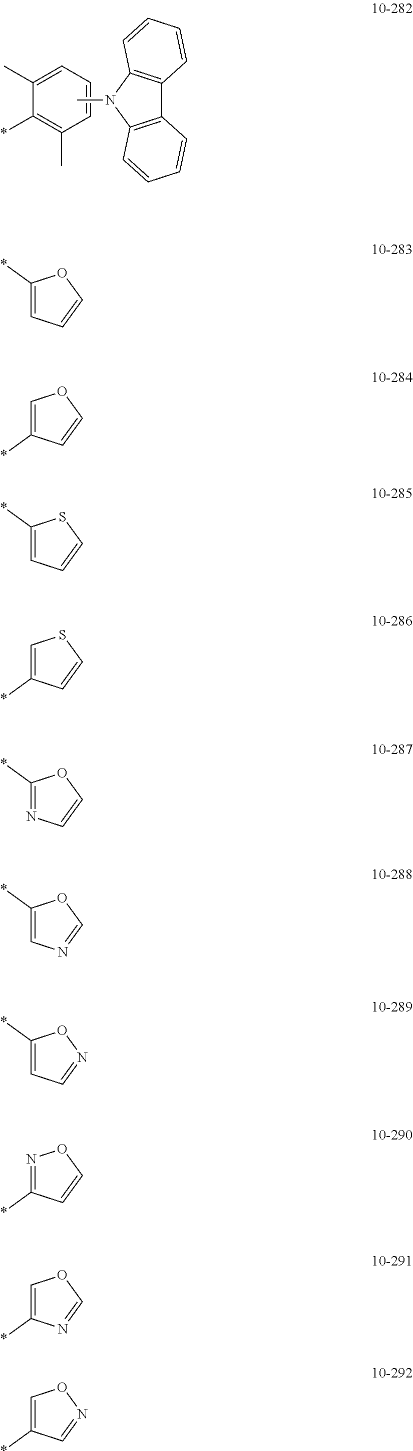

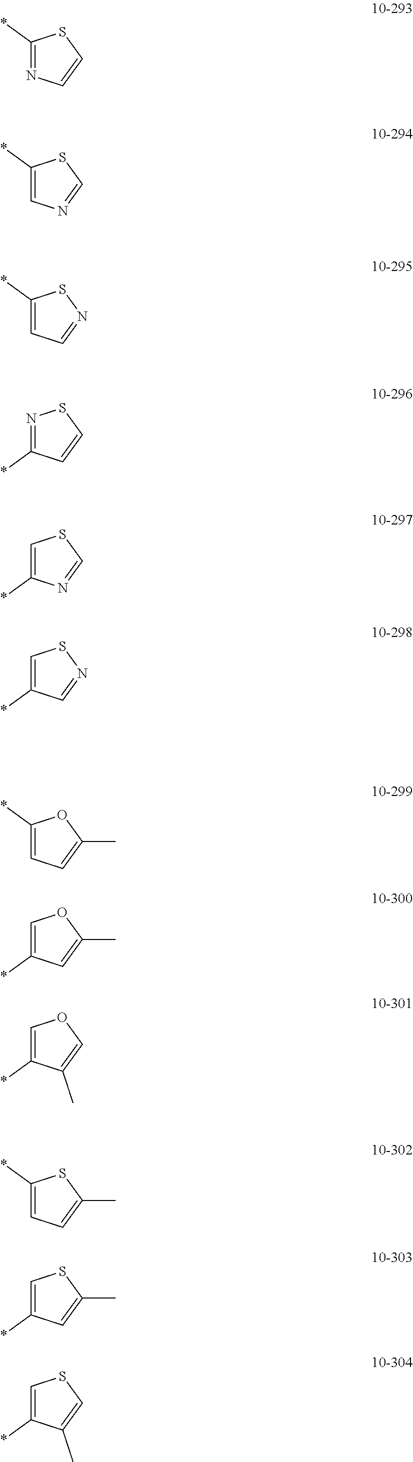

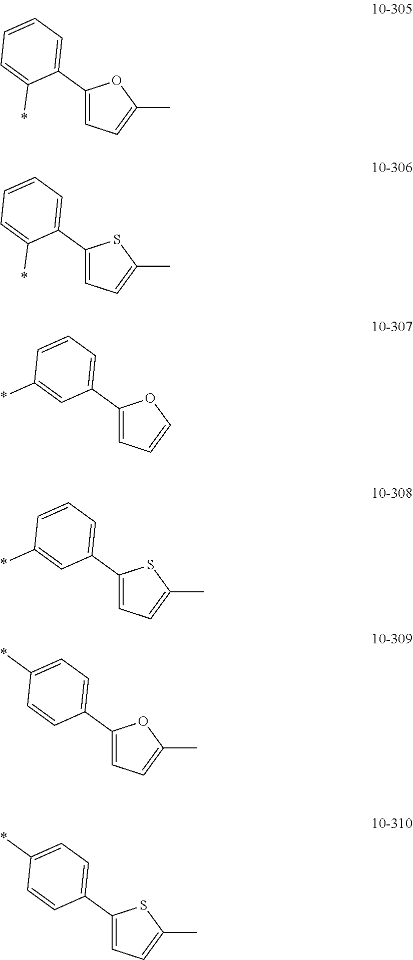 [SMILES: *c1ccccc1-c1ccc(C)o1 ; *c1ccccc1-c1ccc(C)s1 ; *c1cccc(-c2ccco2)c1 ; *c1cccc(-c2ccc(C)s2)c1 ; *c1ccc(-c2ccc(C)o2)cc1 ; *c1ccc(-c2ccc(C)s2)cc1]

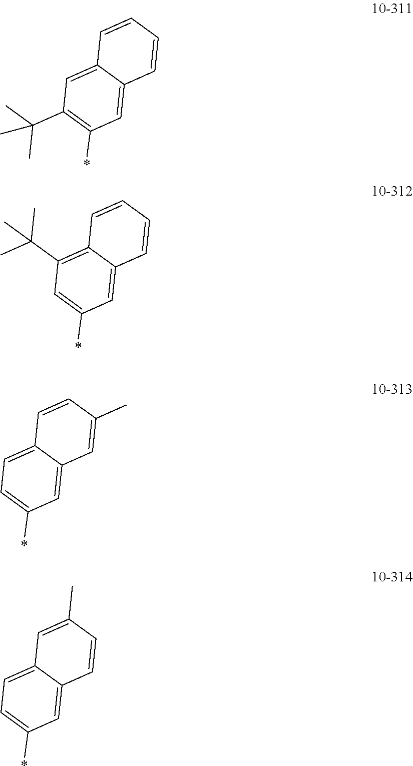 [SMILES: *c1cc2ccccc2cc1C(C)(C)C ; *c1cc(C(C)(C)C)c2ccccc2c1 ; *c1ccc2ccc(C)cc2c1 ; *c1ccc2cc(C)ccc2c1]

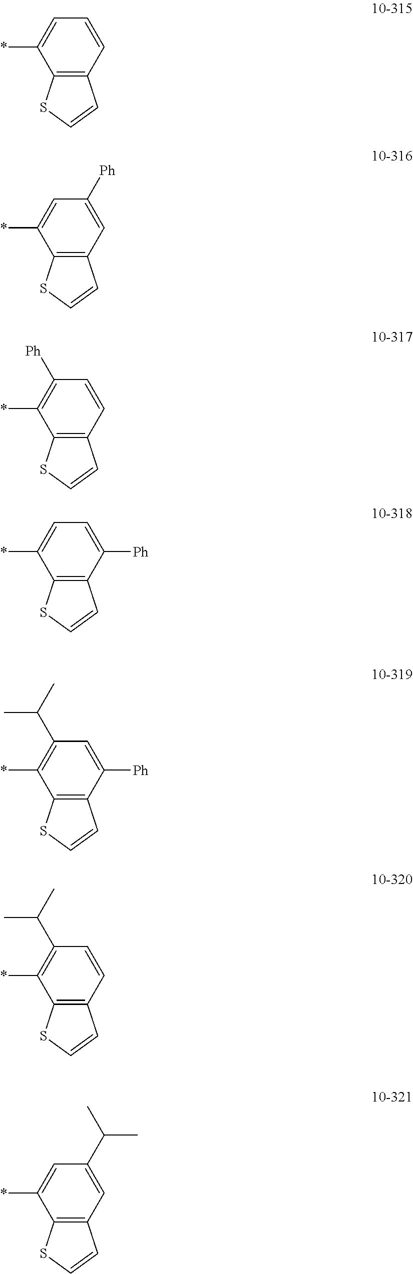

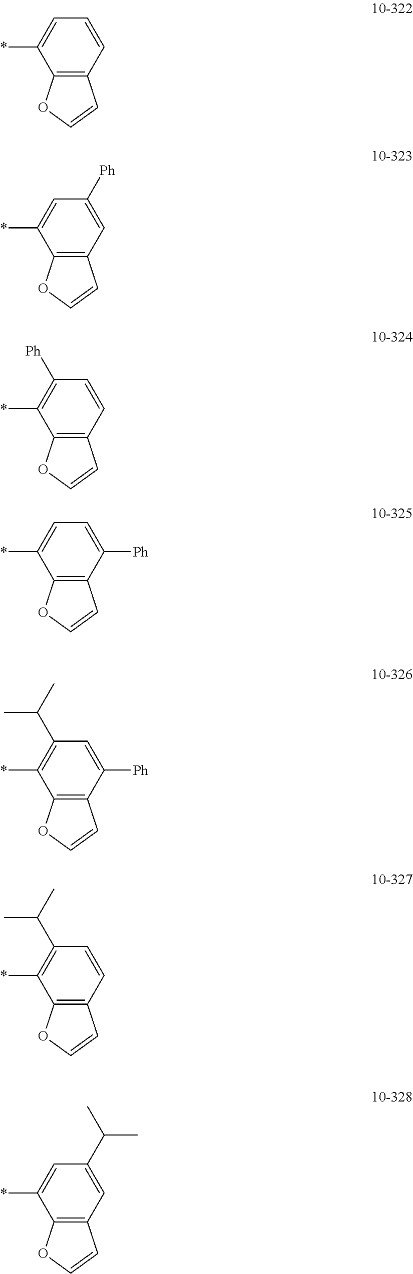

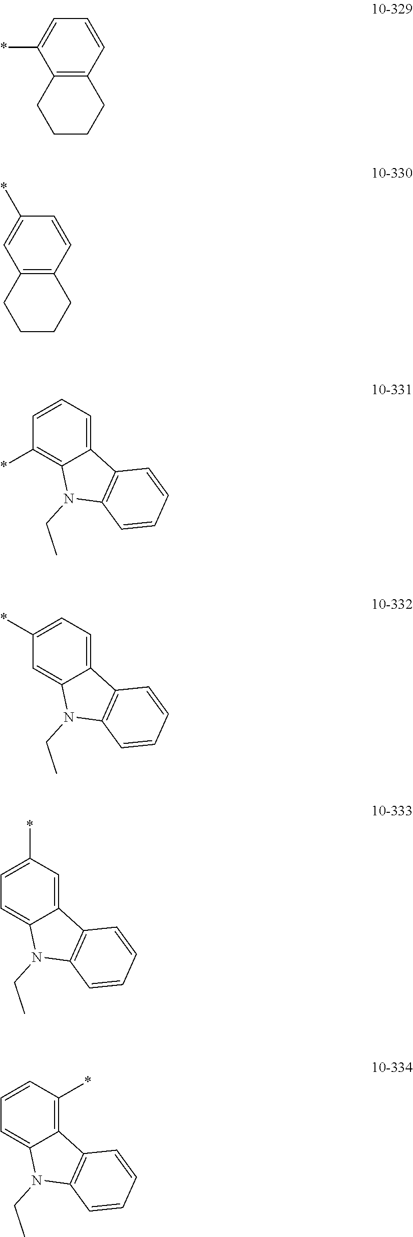 [SMILES: *c1cccc2c1CCCC2 ; *c1ccc2c(c1)CCCC2 ; *c1cccc2c3ccccc3n(CC)c12 ; *c1ccc2c3ccccc3n(CC)c2c1 ; *c1ccc2c(c1)c1ccccc1n2CC ; *c1cccc2c1c1ccccc1n2CC]

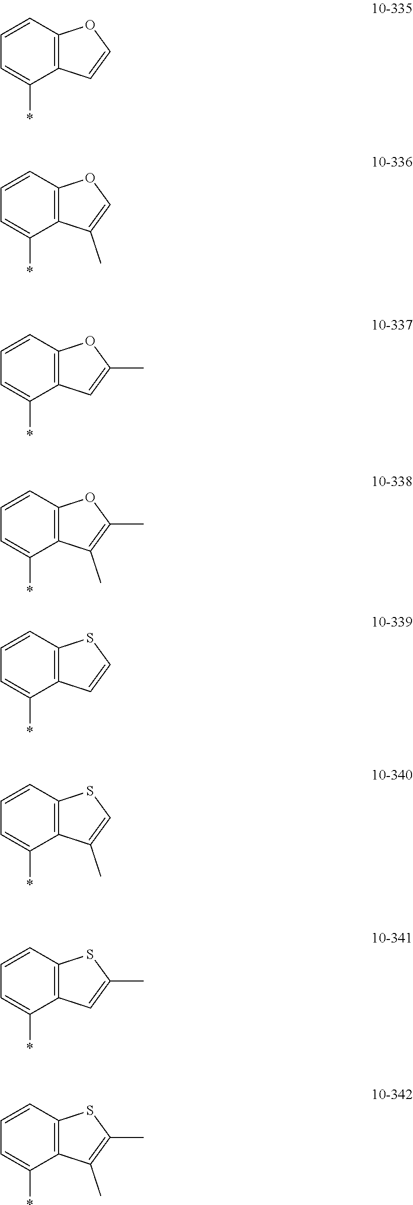

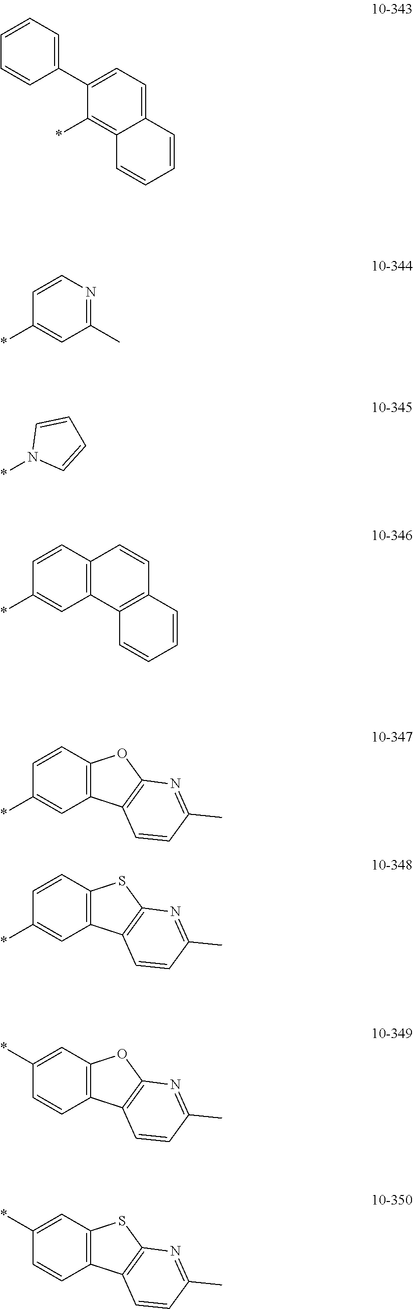

wherein * in Formulae 9-1 to 9-39, 9-201 to 9-237, 10-1 to 10-129, and 10-201 to 10-350 indicates a binding site to a neighboring atom, Ph is a phenyl group, TMS is a trimethylsilyl group, and TMG is a trimethylgermyl group.

The “group represented by one of Formulae 9-1 to 9-39 in which at least one hydrogen is substituted with deuterium” and the “group represented by one of Formulae 9-201 to 9-237 in which at least one hydrogen is substituted with deuterium” may be, for example, a group represented by one of Formulae 9-501 to 9-514 or 9-601 to 9-636:

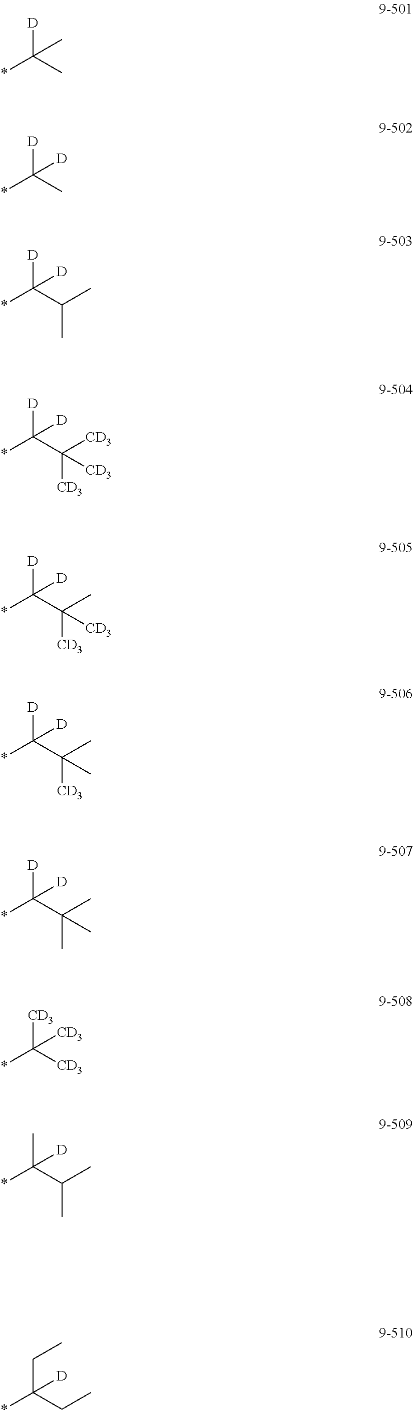

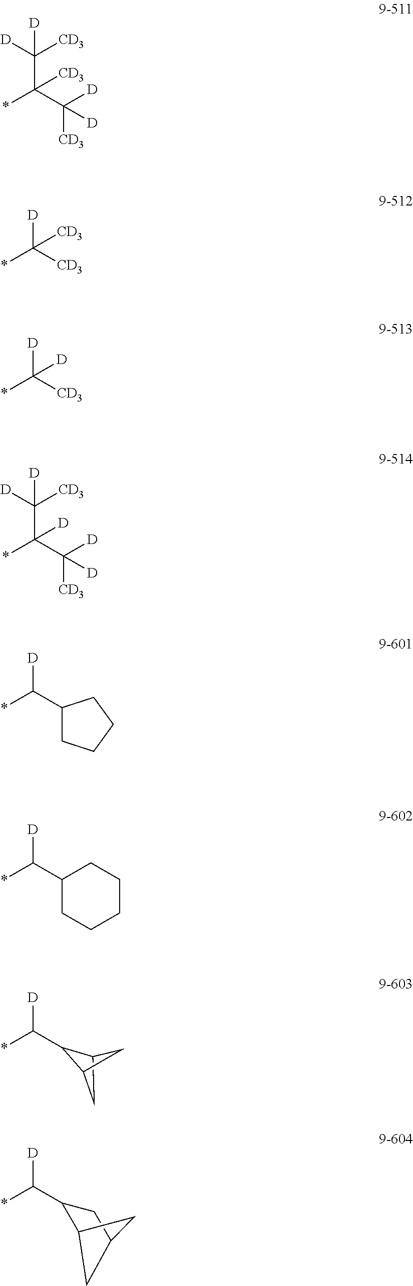

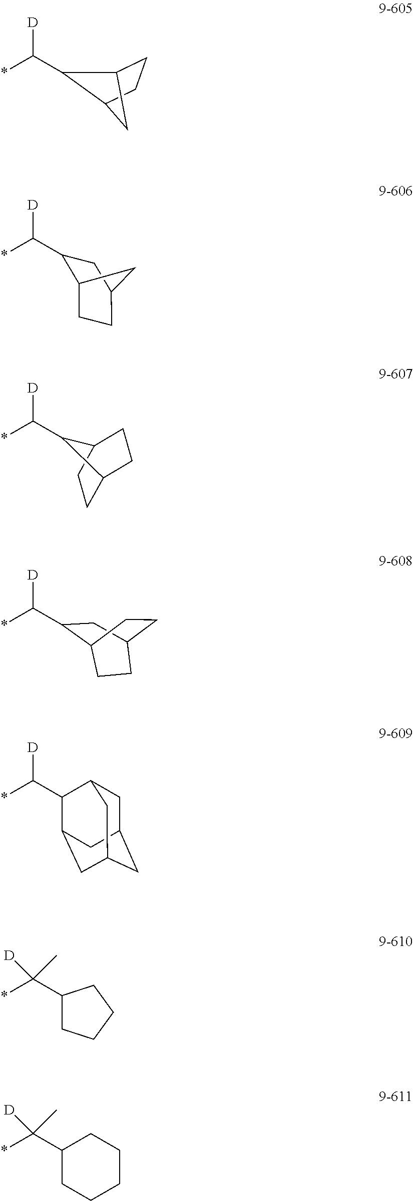

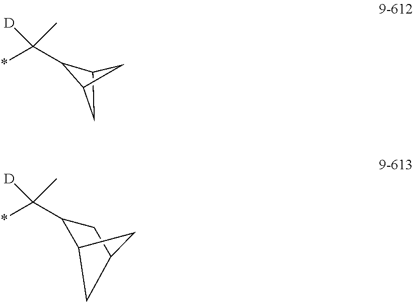

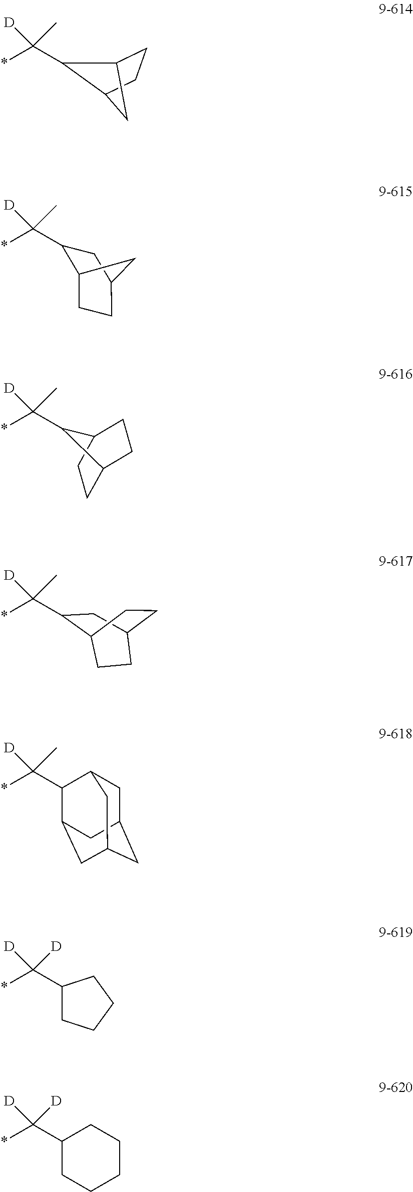

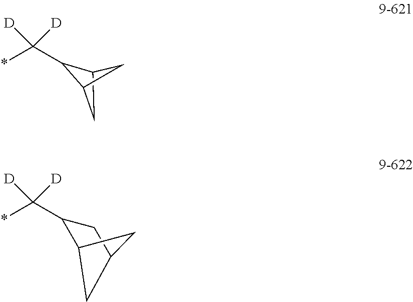 [SMILES: *C([2H])([2H])C1C2CC1C2 ; *C([2H])([2H])C1CC2CC1C2]

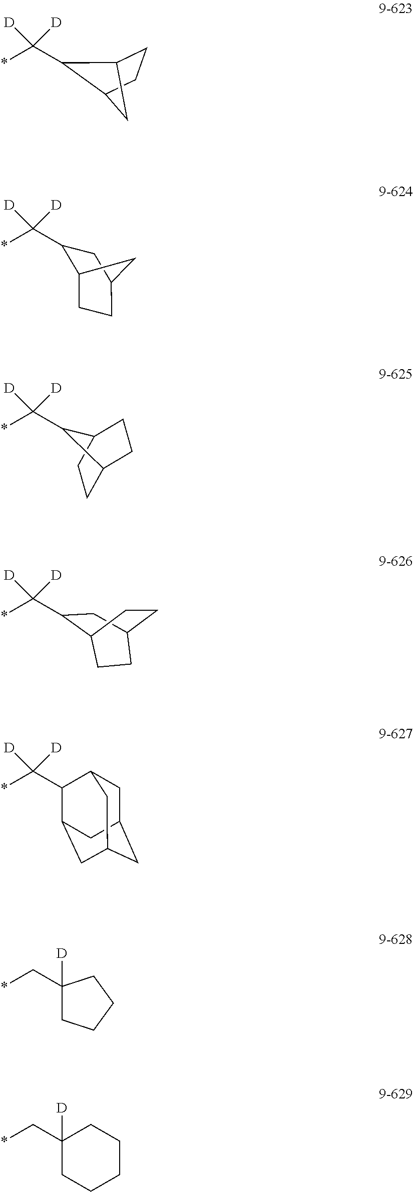

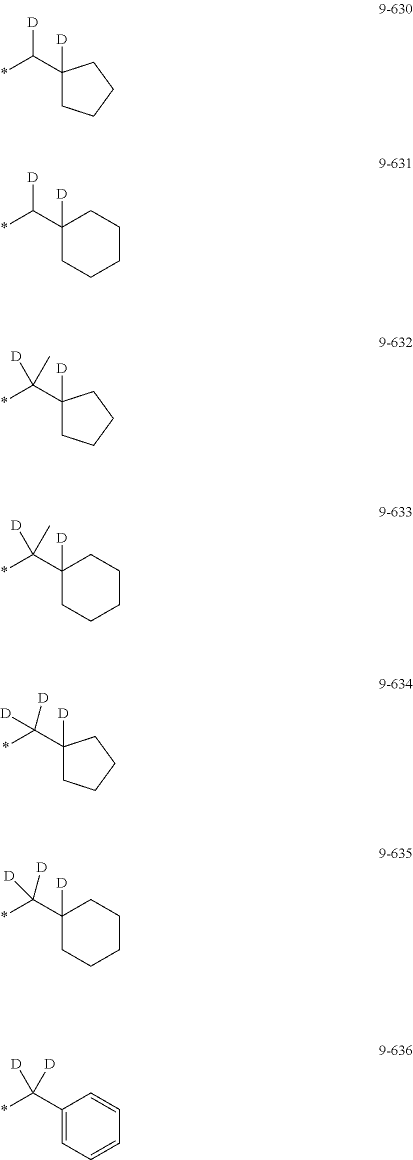

wherein * in Formulae 9-501 to 9-514 and 9-601 to 9-636 indicates a binding site to a neighboring atom.

The “group represented by one of Formulae 9-1 to 9-39 in which at least one hydrogen is substituted with —F” and the “group represented by one of Formulae 9-201 to 9-237 in which at least one hydrogen is substituted with —F” may each be, for example, a group represented by one of Formulae 9-701 to 9-710:

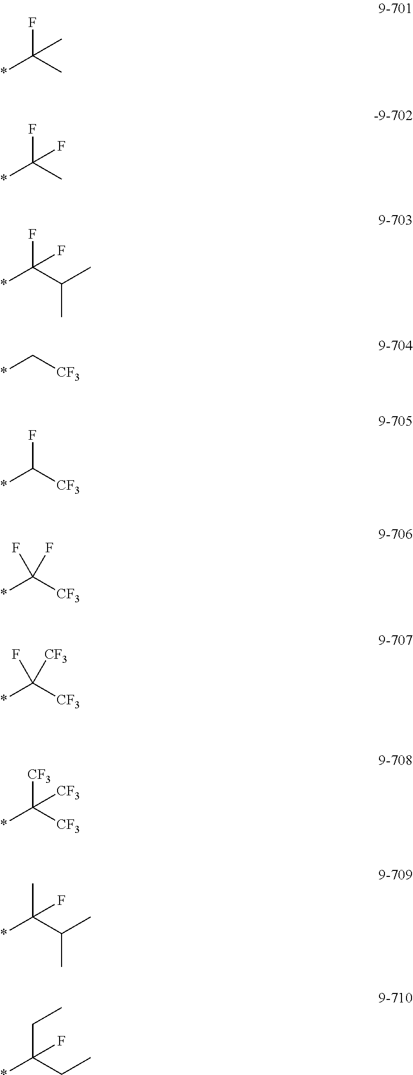

wherein * in Formulae 9-701 to 9-710 indicates a binding site to a neighboring atom.

The “group represented by one of Formulae 10-1 to 10-129 in which at least one hydrogen is substituted with deuterium” and the “group represented by one of Formulae 10-201 to 10-350 in which at least one hydrogen is substituted with deuterium” may be, for example, a group represented by one of Formulae 10-501 to 10-553:

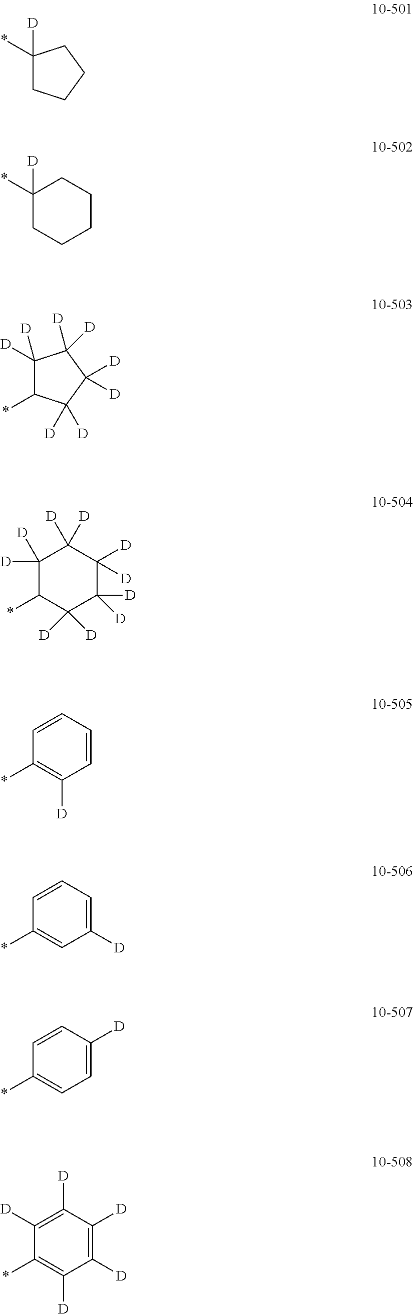

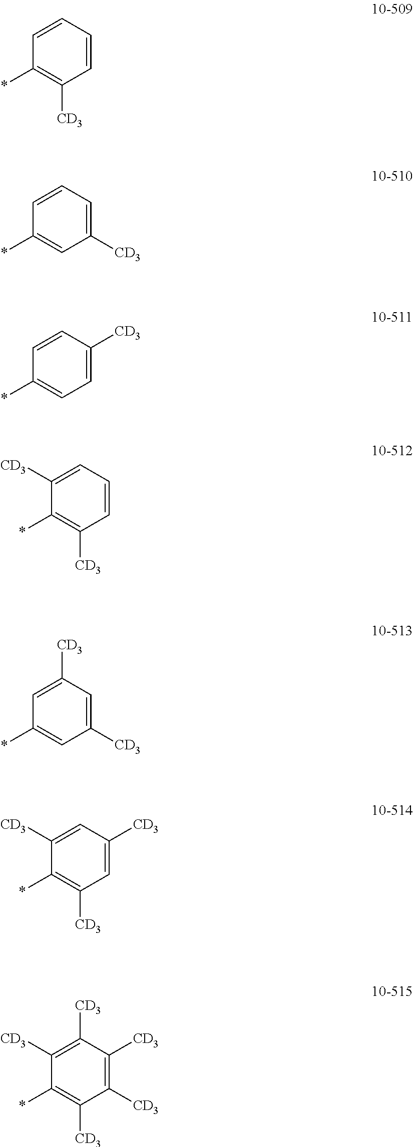

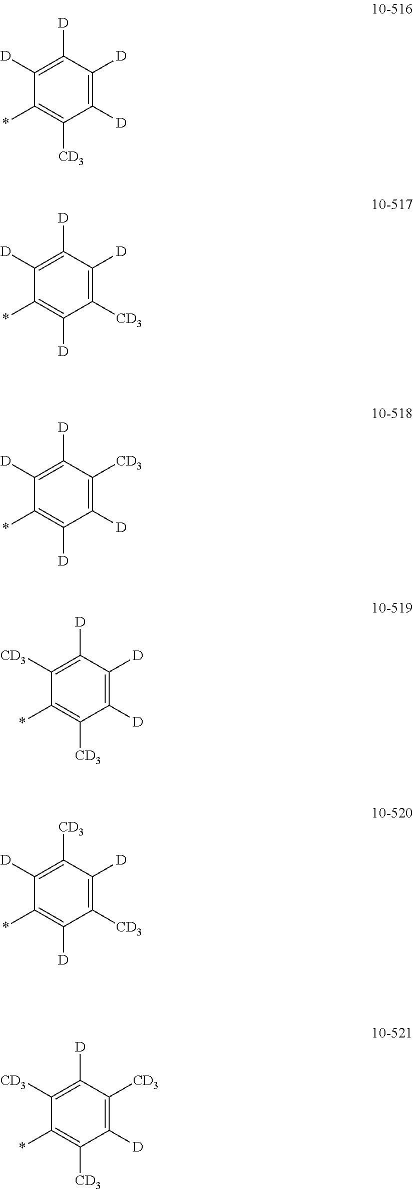 [SMILES: *c1c([2H])c([2H])c([2H])c([2H])c1C([2H])([2H])[2H] ; *c1c([2H])c([2H])c([2H])c(C([2H])([2H])[2H])c1[2H] ; *c1c([2H])c([2H])c(C([2H])([2H])[2H])c([2H])c1[2H] ; *c1c(C([2H])([2H])[2H])c([2H])c([2H])c([2H])c1C([2H])([2H])[2H] ; *c1c([2H])c(C([2H])([2H])[2H])c([2H])c(C([2H])([2H])[2H])c1[2H] ; *c1c(C([2H])([2H])[2H])c([2H])c(C([2H])([2H])[2H])c([2H])c1C([2H])([2H])[2H]]

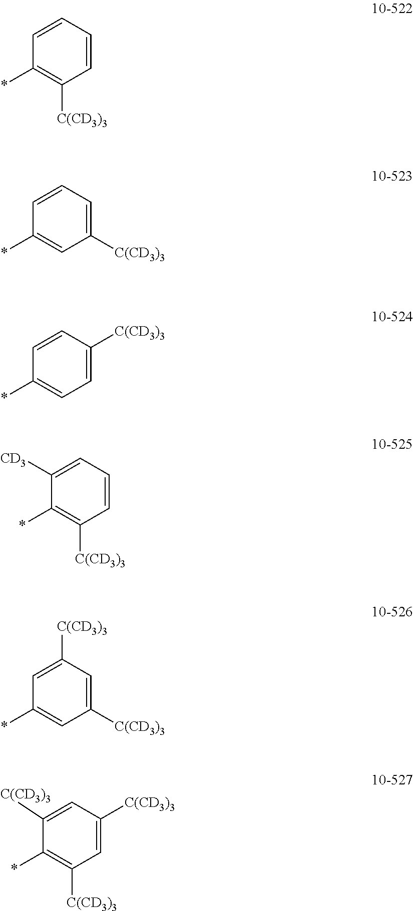

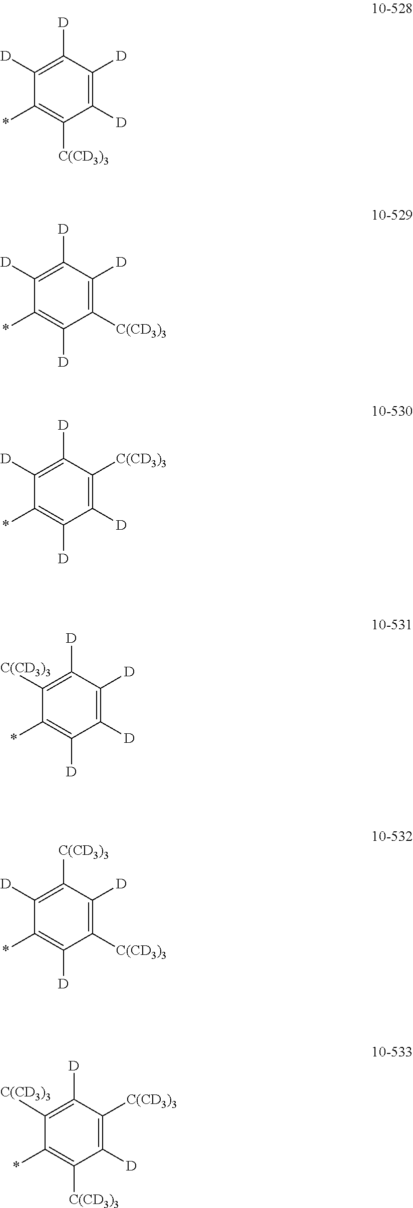

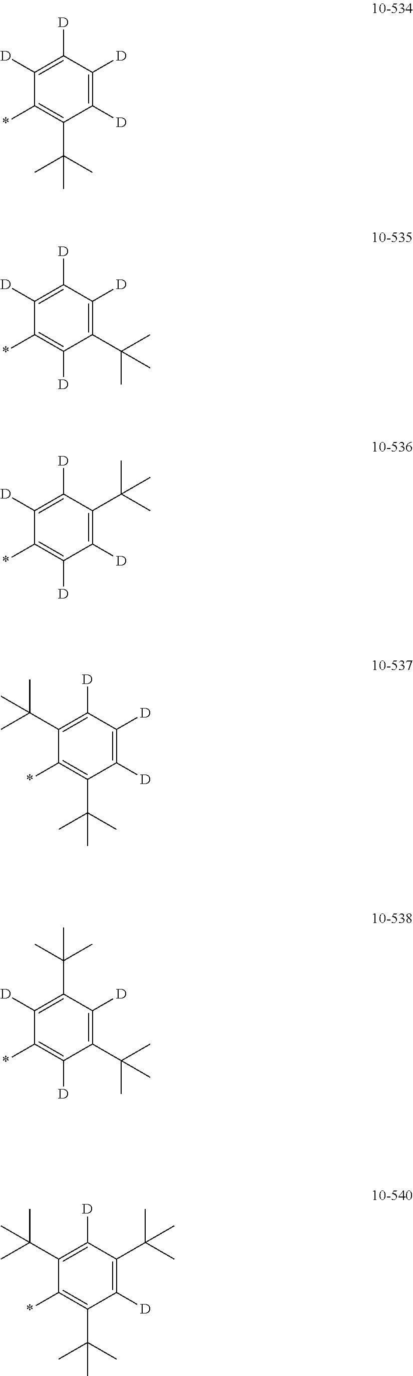

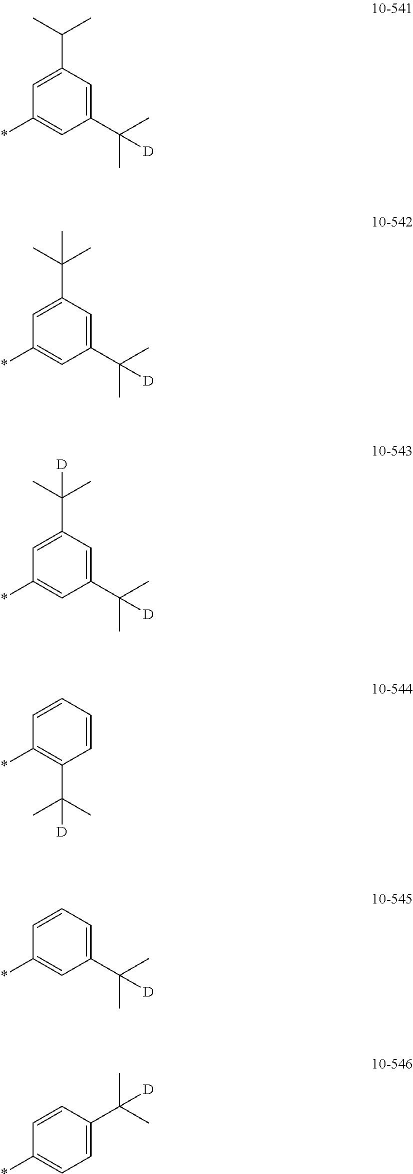 [SMILES: *c1cc(C(C)C)cc(C([2H])(C)C)c1 ; *c1cc(C([2H])(C)C)cc(C(C)(C)C)c1 ; *c1cc(C([2H])(C)C)cc(C([2H])(C)C)c1 ; *c1ccccc1C([2H])(C)C ; *c1cccc(C([2H])(C)C)c1 ; *c1ccc(C([2H])(C)C)cc1]

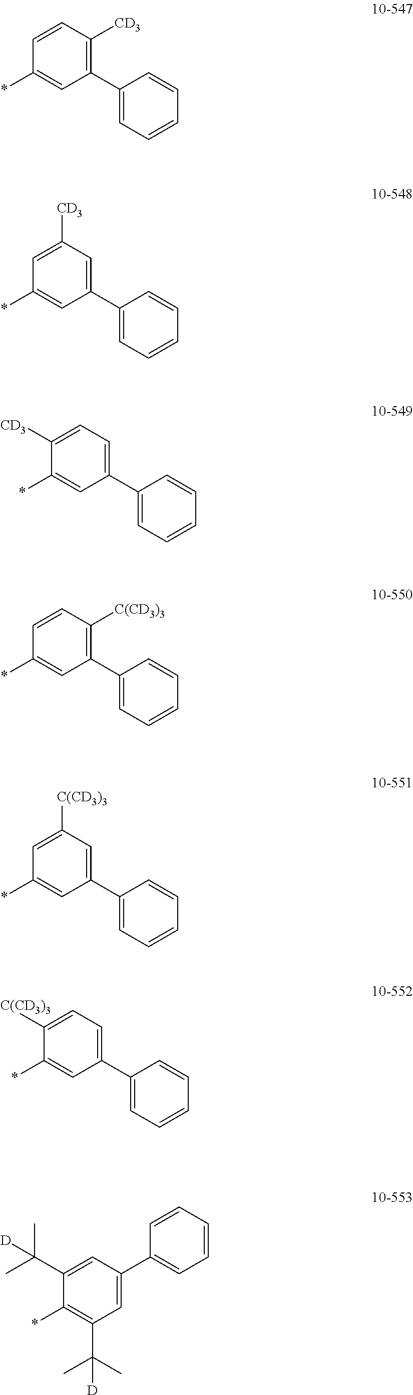

wherein * in Formulae 10-501 to 10-553 indicates a binding site to a neighboring atom.

The “group represented by one of Formulae 10-1 to 10-129 in which at least one hydrogen is substituted with —F” and the “group represented by one of Formulae 10-201 to 10-350 in which at least one hydrogen is substituted with —F” may be, for example, a group represented by one of Formulae 10-601 to 10-617:

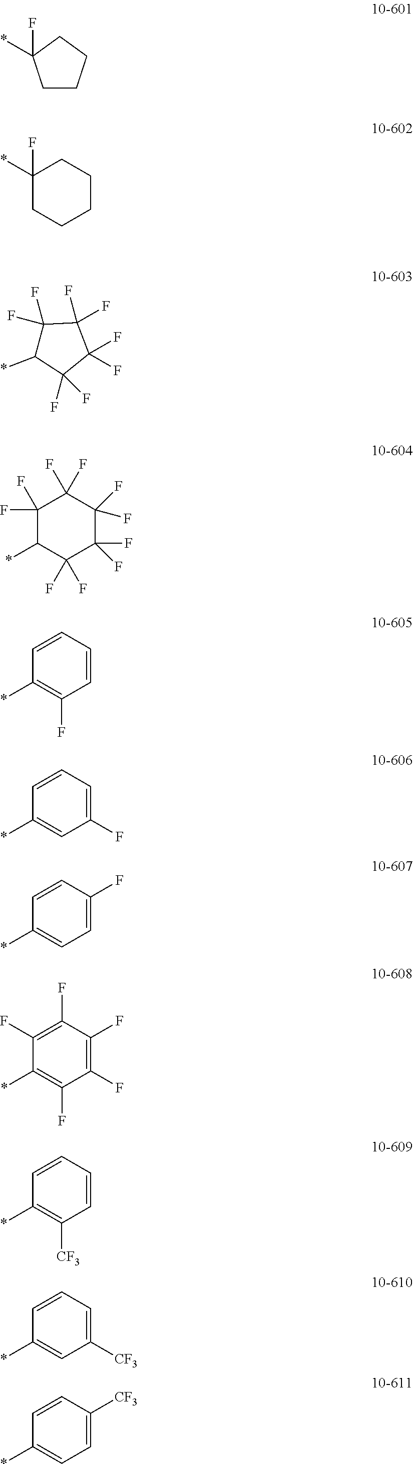

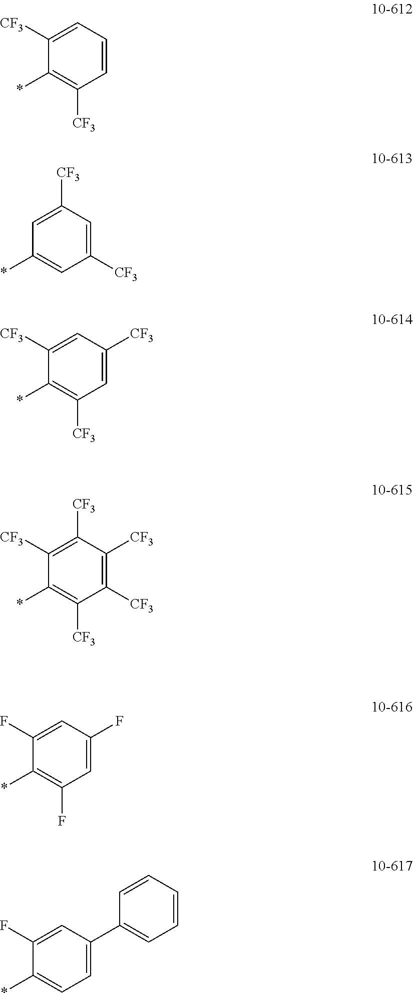 [SMILES: *c1c(C(F)(F)F)cccc1C(F)(F)F ; *c1cc(C(F)(F)F)cc(C(F)(F)F)c1 ; *c1c(C(F)(F)F)cc(C(F)(F)F)cc1C(F)(F)F ; *c1c(C(F)(F)F)c(C(F)(F)F)c(C(F)(F)F)c(C(F)(F)F)c1C(F)(F)F ; *c1c(F)cc(F)cc1F ; *c1ccc(-c2ccccc2)cc1F]

wherein * in Formulae 10-601 to 10-617 indicates a binding site to a neighboring atom.
a1 and a2 in Formula 1 respectively indicate the numbers of R₁ and R₂, wherein a1 is an integer from 0 to 2, and a2 is an integer from 0 to 20. When a1 is 2, two R₁ may be identical to or different from each other, and when a2 is 2 or greater, two or more of R₂ may be identical to or different from each other. In one or more embodiments, a2 may be 0, 1, 2, or 3.
b1 and b2 in Formula 1 respectively indicate the numbers of Z₁ and Z₂, and are each independently an integer from 1 to 10. When b1 is 2 or greater, two or more of Z₁ may be identical to or different from each other, and when b2 is 2 or greater, two or more Z₂ may be identical to or different from each other. Because b1 and b2 are each not 0 and at least one of Z₂ is not hydrogen, Formula 1 includes at least one Z₁ and at least one Z₂ which is not hydrogen. In one or more embodiments, b1 may be 1 or 2, and b2 may be 1, 2, or 3.

In one or more embodiments, the organometallic compound represented by Formula 1 may satisfy one of Condition 1 to Condition 4:

Condition 1
Z₁ is a group represented by —Si(Q₃)(Q₄)(Q₅), and at least one of Z₂(s) in the number of b2 includes at least one carbon atom;

Condition 2
Z₁ is a group represented by —Ge(Q₃)(Q₄)(Q₅), and at least one of Z₂(s) in the number of b2 includes at least one carbon atom;

Condition 3
Z₁ is a group represented by —Si(Q₃)(Q₄)(Q₅), and at least one of Z₂(s) in the number of b2 are —F;

Condition 4
Z₁ is a group represented by —Ge(Q₃)(Q₄)(Q₅), and at least one of Z₂(s) in the number of b2 are —F.

In one or more embodiments, the number of carbon atoms included in each of R₃₀ₐ, and R_{30b} in Formula 1 may each independently be 4 or greater, 5 or greater, or 6 or greater.

In one or more embodiments, R₃₀ₐ in Formula 1 may not be a methyl group.

In one or more embodiments, R_{30b} in Formula 1 may not be a methyl group.

In one or more embodiments, R₃₀ₐ and R_{30b} in Formula 1 may each not be a methyl group at the same time.

In one or more embodiments, R₃₀ₐ in Formula 1 may not be a tert-butyl group.

In one or more embodiments, R_{30b} in Formula 1 may not be a tert-butyl group.

In one or more embodiments, R₃₀ₐ and R_{30b} in Formula 1 may each not be a tert-butyl group at the same time.

In one or more embodiments, the organometallic compound represented by Formula 1 may satisfy one of Condition A1 to Condition A6:

Condition A1
R₃₀ₐ in Formula 1 is a group represented by *—C(R₃₁)(R₃₂)(R₃₃), and
each of R₃₁ to R₃₃ includes one or more carbon atoms;

Condition A2
R₃₀ₐ in Formula 1 is a group represented by *—C(R₃₁)(R₃₂)(R₃₃),
each of R₃₁ and R₃₃ includes one or more carbon atoms, and
R₃₂ is hydrogen, deuterium, or —F;

Condition A3
R₃₀ₐ in Formula 1 is a group represented by *—C(R₃₁)(R₃₂)(R₃₃), and
each of R₃₁ to R₃₃ includes one or more carbon atoms, wherein at least one of R₃₁ to R₃₃ includes two or more carbon atoms;

Condition A4
R₃₀ₐ in Formula 1 is a group represented by *—C(R₃₁)(R₃₂)(R₃₃),
each of R₃₁ and R₃₃ includes one or more carbon atoms, wherein at least one of R₃₁ and R₃₃ includes two or more carbon atoms, and
R₃₂ is hydrogen, deuterium, or —F;

Condition A5
R₃₀ₐ in Formula 1 is a group represented by *—C(R₃₁)(R₃₂)(R₃₃), and
R₃₁ to R₃₃ are each independently hydrogen, deuterium, or —F, wherein at least one of R₃₁ to R₃₃ is deuterium or —F;

Condition A6
R₃₀ₐ in Formula 1 is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, or a substituted or unsubstituted monovalent non-aromatic condensed heteropolycyclic group.

In one or more embodiments, the organometallic compound represented by Formula 1 may satisfy one of Condition B1 to Condition B6:

Condition B1
R_{30b} in Formula 1 is a group represented by *—C(R₃₄)(R₃₅)(R₃₆), and
each of R₃₄ to R₃₆ includes one or more carbon atoms;

Condition B2
R_{30b} in Formula 1 is a group represented by *—C(R₃₄)(R₃₅)(R₃₆),
each of R₃₄ and R₃₆ includes one or more carbon atoms, and
R₃₅ is hydrogen, deuterium, or —F;

Condition B3
R_{30b} in Formula 1 is a group represented by *—C(R₃₄)(R₃₅)(R₃₆), and
each of R₃₄ to R₃₆ includes one or more carbon atoms, wherein at least one of R₃₄ to R₃₆ includes two or more carbon atoms;

Condition B4
R_{30b} in Formula 1 is a group represented by *—C(R₃₄)(R₃₅)(R₃₆),
each of R₃₄ and R₃₆ includes one or more carbon atoms, wherein at least one of R₃₄ and R₃₆ includes two or more carbon atoms, and
R₃₅ is hydrogen, deuterium, or —F;

Condition B5
R_{30b} in Formula 1 is a group represented by *—C(R₃₄)(R₃₅)(R₃₆), and
R₃₄ to R₃₆ are each independently hydrogen, deuterium, or —F, wherein at least one of R₃₄ to R₃₆ is deuterium or —F;

Condition B6
R_{30b} in Formula 1 is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

In one or more embodiments, a group represented by

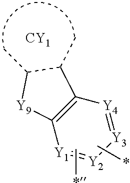

in Formula 1 may be a group represented by one of Formulae CY1(1) to CY1(6):

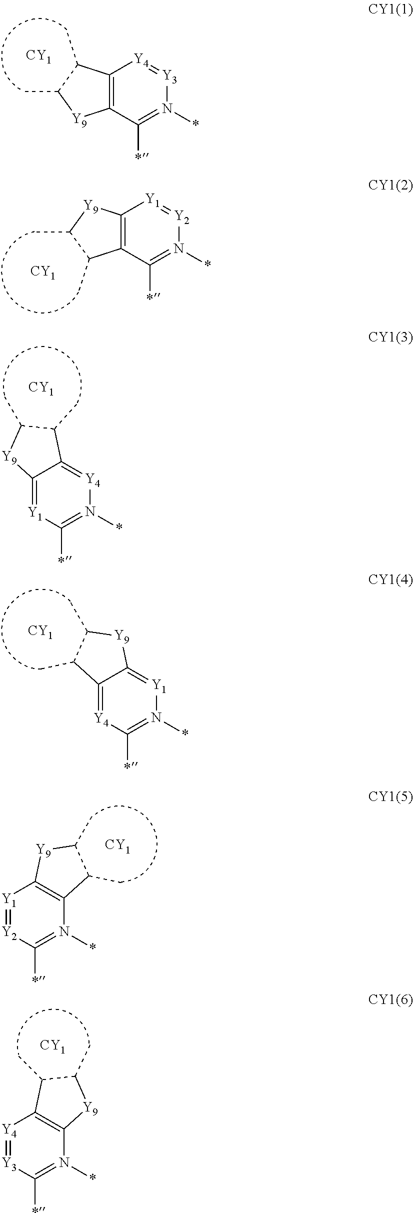

wherein, in Formulae CY1(1) to CY1(6),
Y₉ and ring CY₁ may each independently be as described herein,
Y₁ to Y₄ may each independently be C or N,
* may indicate a binding site to iridium in Formula 1, and
*″ may indicate a binding site to ring CY₂ in Formula 1.

In one or more embodiments, each of Y₁ to Y₄ in in Formulae CY1(1) to CY1(6) may be C.

In one or more embodiments, a group represented by

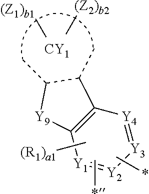

in Formula 1 may be a group represented by one of Formulae CY1-1 to CY1-28:

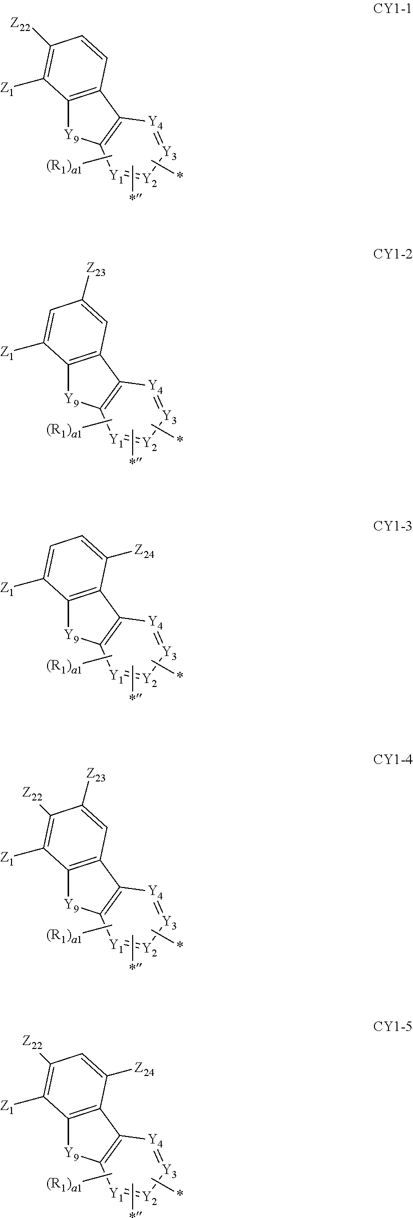

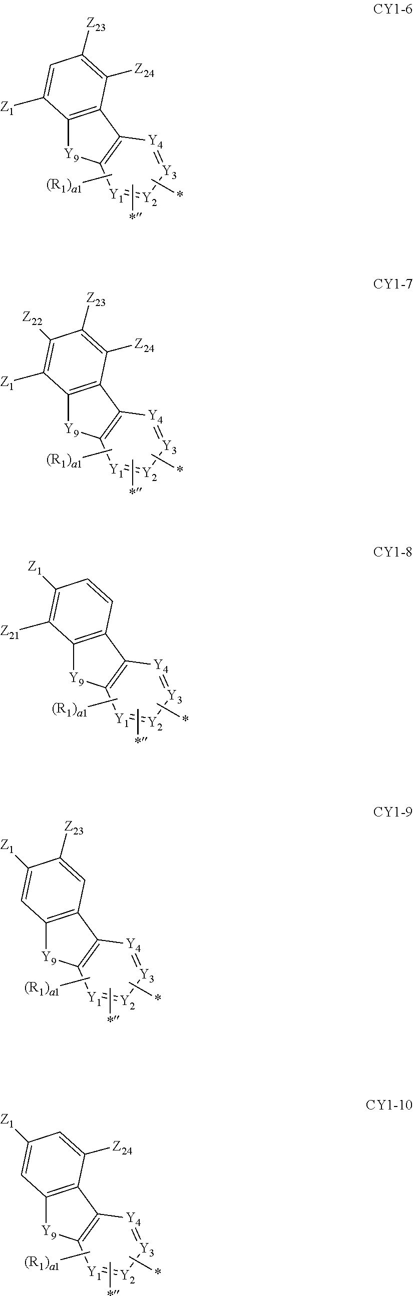

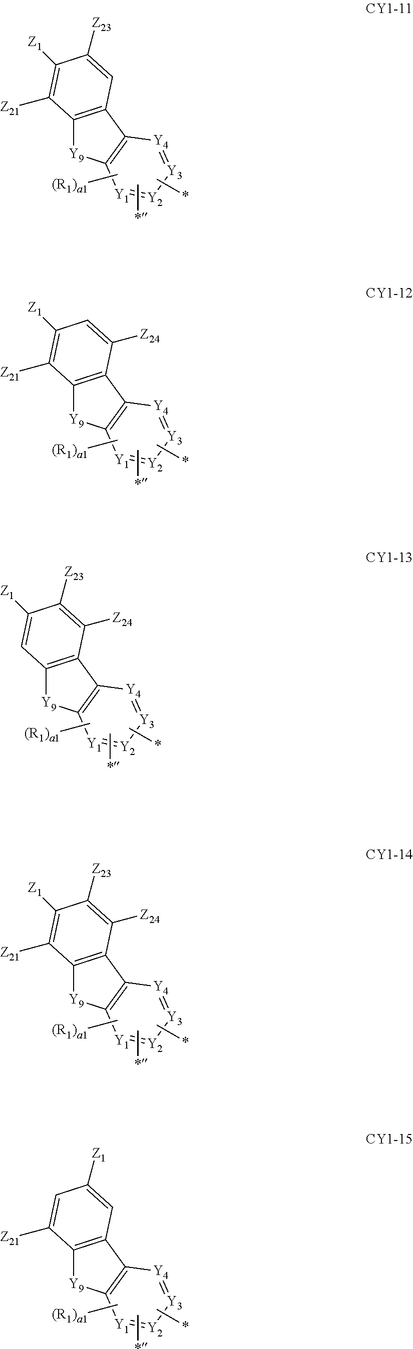

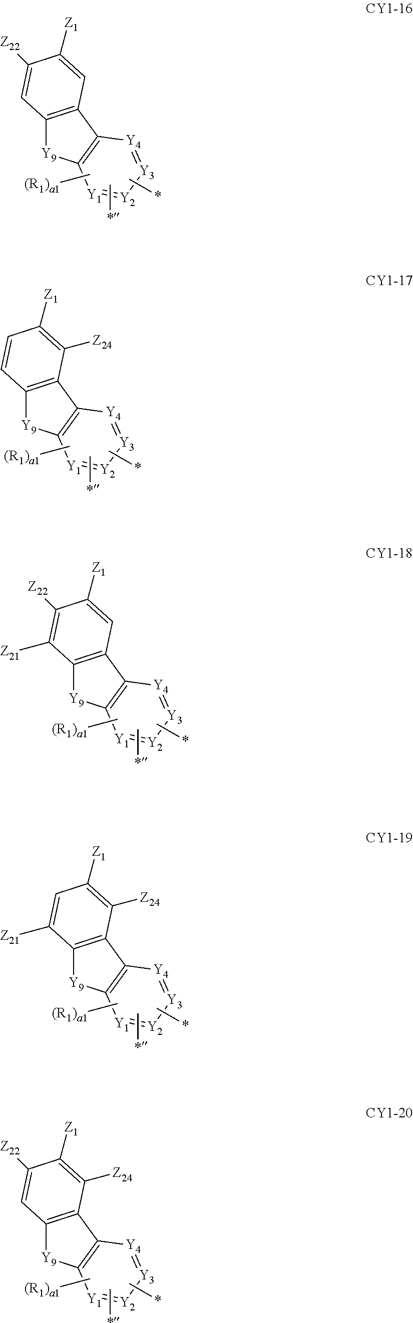

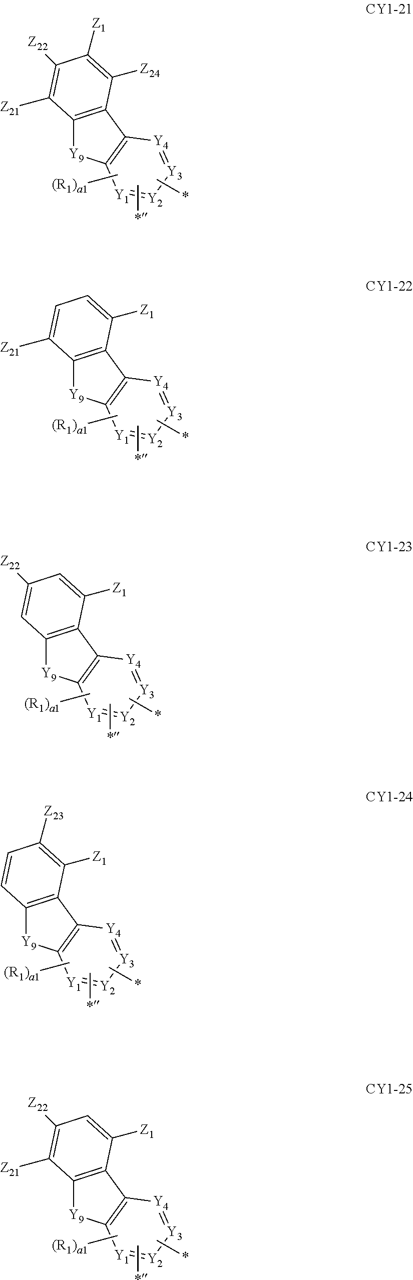

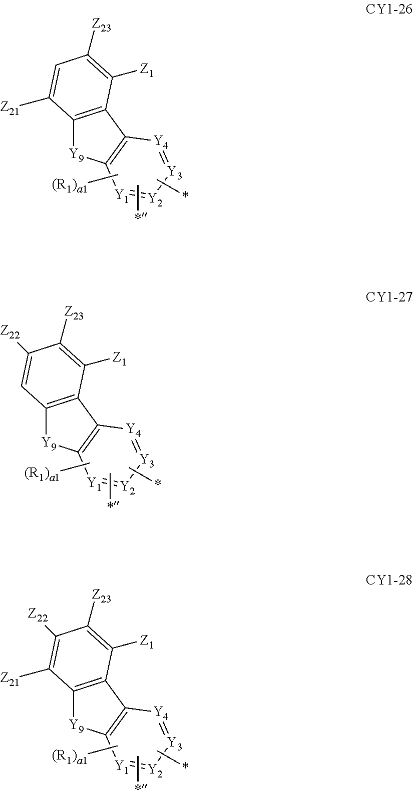

wherein, in Formulae CY1-1 to CY1-28,
Y₁ to Y₄, Y₉, Z₁, R₁, and a1 may each independently be as described herein,
Z₂₁ to Z₂₄ may each independently be as described in connection with Z₂ herein and are not hydrogen,
* may indicate a binding site to iridium in Formula 1, and
*″ may indicate a binding site to ring CY₂ in Formula 1.

In one or more embodiments, in Formulae CY1-1 to CY1-28, Y₂ may be N bonded to Ir in Formula 1, and Y₁ may be C bonded to ring CY₂ in Formula 1.

In one or more embodiments, a group represented by

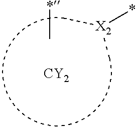

in Formula 1 may be a group represented by one of Formulae CY2(1) to CY2(22) (for example, a group represented by one of Formulae CY2(1) to CY2(21)):

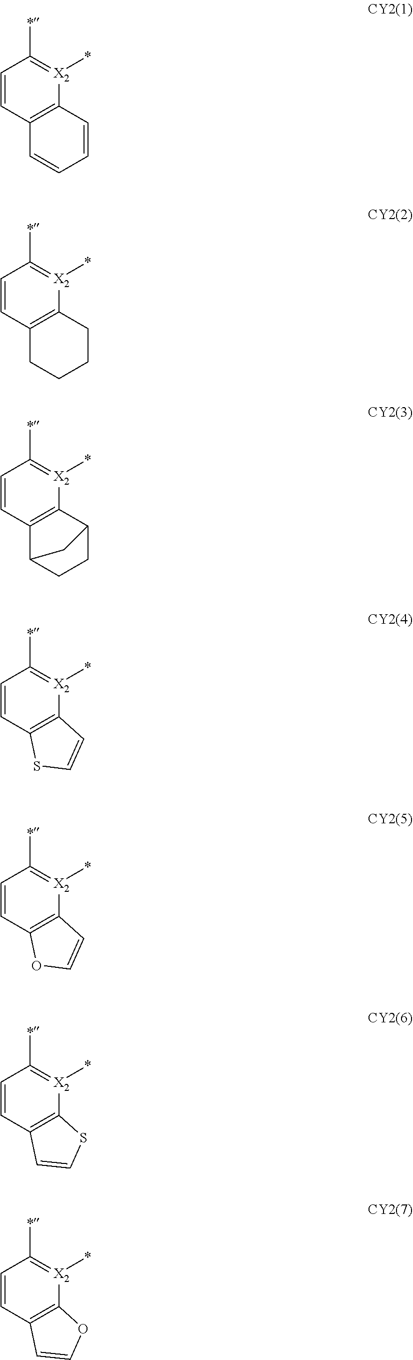

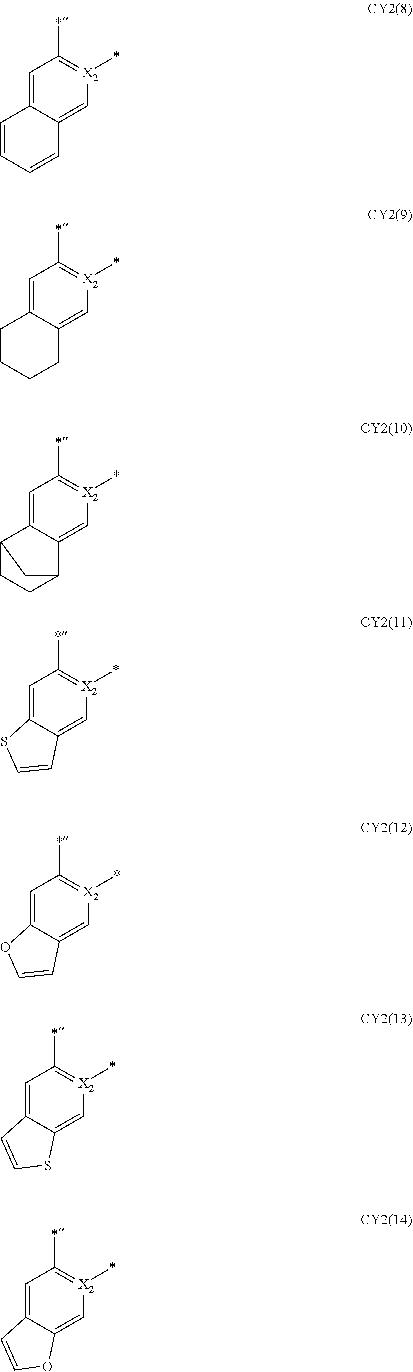

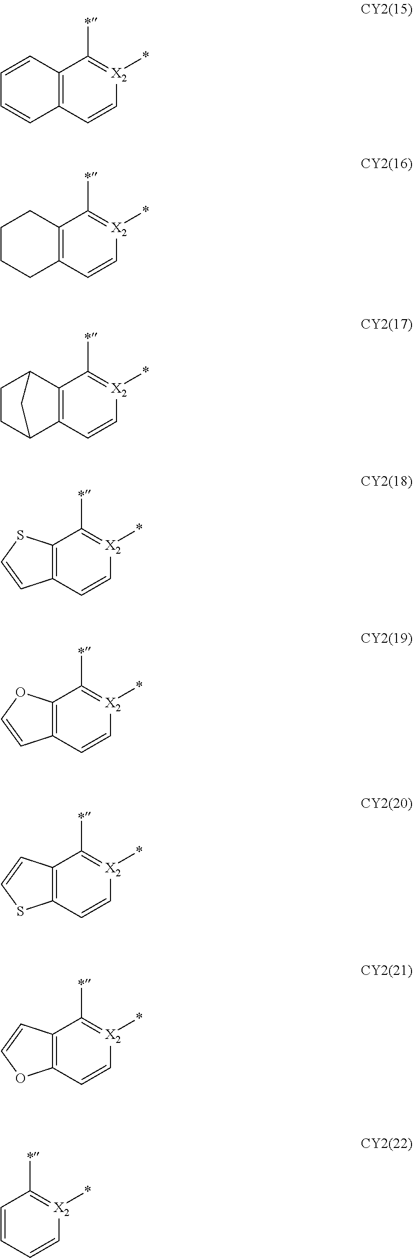

wherein, in Formulae CY2(1) to CY2(22),
X₂ may be as described herein,
* may indicate a binding site to iridium in Formula 1, and
*″ indicates a binding site to one of Y₁ to Y₄ in Formula 1.

In one or more embodiments, a group represented by

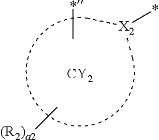

in Formula 1 may be a group represented by one of Formulae CY2-1 to CY2-6:

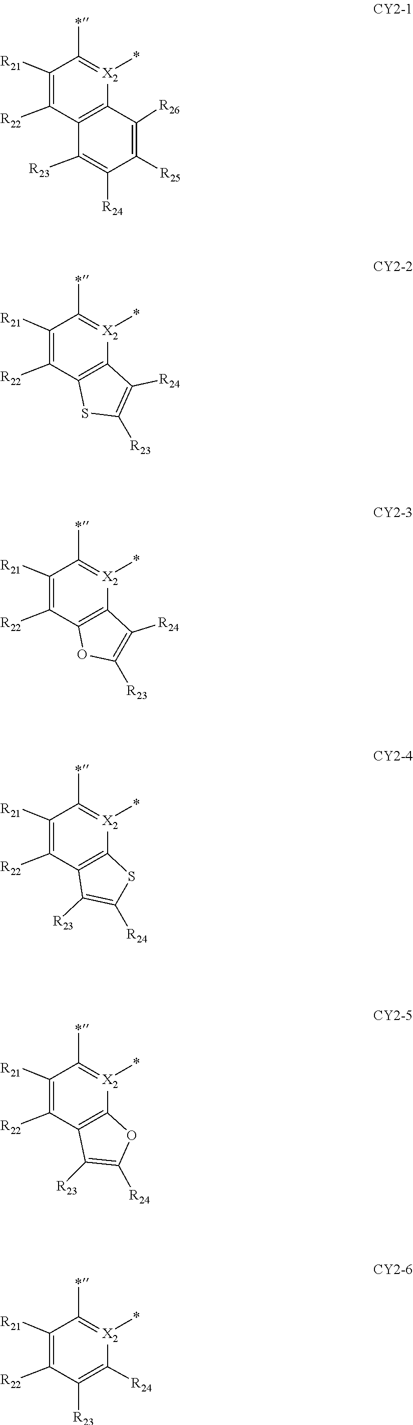

wherein, in Formulae CY2-1 to CY2-6,
X₂ may be as described herein,
R₂₁ to R₂₆ may each independently be as described in connection with R₂,
two or more of R₂₁ to R₂₆ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
R₁₀ₐ may be as described in connection with R₁,
* may indicate a binding site to iridium in Formula 1, and
*″ may indicate a binding site to one of Y₁ to Y₄ in Formula 1.

In one or more embodiments,
at least one of R₂₁ to R₂₆ in Formula CY2-1 may not be hydrogen, and
at least one of R₂₁ to R₂₄ in Formulae CY2-2 to CY2-6 may not be hydrogen.

In one or more embodiments, in Formula CY2-1, R₂₁ and R₂₃ to R₂₆ may each be hydrogen, and R₂₂ may include at least one carbon atom.

In one or more embodiments, in Formula CY2-6, R₂₁ and R₂₃ may each be hydrogen, and each of R₂₂ and R₂₄ may include at least one carbon atom.

In one or more embodiments, a group represented by

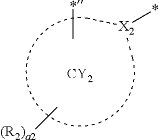

in Formula 1 may be a group represented by one of Formulae CY2-A to CY2-G:

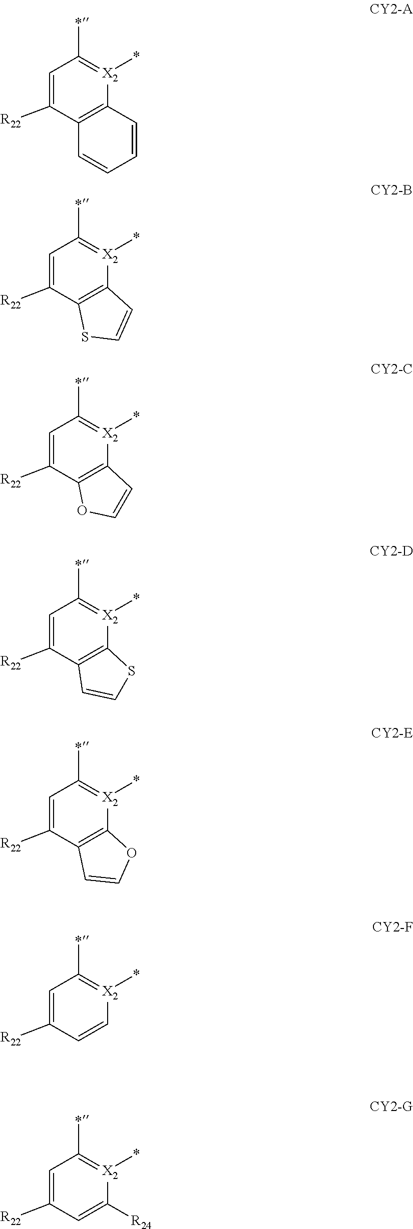

wherein, in Formulae CY2-A to CY2-G,
X₂ may be as described herein,
R₂₂ and R₂₄ may each independently be:
a C₁-C₂₀ alkyl group that is unsubstituted or substituted with at least one of deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, or a combination thereof; or
a C₃-C₁₀ cycloalkyl group, a phenyl group, or a biphenyl group, each unsubstituted or substituted with at least one of deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, or a combination thereof,
* may indicate a binding site to iridium in Formula 1, and
*″ may indicate a binding site to one of Y₁ to Y₄ in Formula 1.

In one or more embodiments, the organometallic compound may be represented by Formula 1-1 or 1-2:

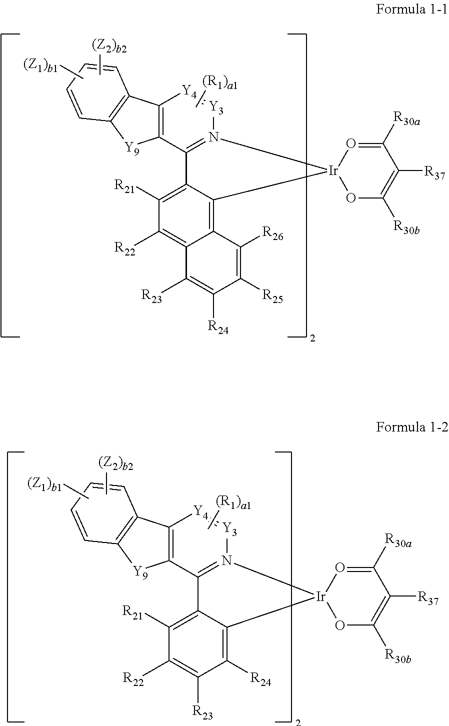

wherein, in Formulae 1-1 and 1-2,
Y₃ and Y₄ may each independently be C or N,
Y₉, Z₁, R₁, R₃₀ₐ, R_{30b}, R₃₇, Z₂, a1, b1, and b2 may each independently be as described herein,
R₂₁ to R₂₆ may each independently be as described in connection with R₂,
two or more of R₂₁ to R₂₆ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of R₃₀ₐ, R_{30b}, and R₃₇ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ, and
R₁₀ₐ may be as described in connection with R₁ herein.

In one or more embodiments, R₃₇ in Formula 1 may be hydrogen or deuterium.

In one or more embodiments, R₃₀ₐ and R_{30b} in Formula 1 may be identical to each other.

In one or more embodiments, R₃₀ₐ and R_{30b} in Formula 1 may be different from each other.

In one or more embodiments, Formula 1 may include at least one deuterium atom.

In one or more embodiments, Formula 1 may include at least one fluoro group (—F).

In one or more embodiments, at least one of R₂(s) in the number of a2 in Formula 1 may include a fluoro group (—F).

In one or more embodiments, R₂ in Formula 1 may not include a fluoro group (—F).

In Formulae described above, i) two R₁ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ, ii) two or more of a plurality of R₂ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ, iii) two or more of R₃₀ₐ, R_{30b}, and R₃₇ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ, iv) two or more of R₃₁ to R₃₃ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ, and v) two or more of R₃₄ to R₃₆ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ. R₁₀ₐ may be as described in connection with R₁.

In one or more embodiments, the organometallic compound represented by Formula 1 may emit a red light or a green light, for example, red light or green light, each having a maximum emission wavelength of about 500 nanometers (nm) or greater, or about 500 nm to about 730 nm.

In one or more embodiments, the organometallic compound represented by Formula 1 may emit a red light, for example, a red light having a maximum emission wavelength of about 580 nm to about 730 nm.

In one or more embodiments, the organometallic compound represented by Formula 1 may emit a light having a maximum emission wavelength of about 525 nm to about 650 nm, about 550 nm to about 650 nm, about 575 nm to about 650 nm, about 600 nm to about 650 nm, about 610 nm to about 645 nm, or about 620 nm to about 645 nm.

In one or more embodiments, the organometallic compound represented by Formula 1 may emit light having a full width at half maximum (FWHM) in a range of about 25 nm to about 55 nm, about 25 nm to about 50 nm, about 30 nm to about 45 nm, or about 30 nm to about 43 nm.

In one or more embodiments, the organometallic compound may be one of Compounds 1 to 18:

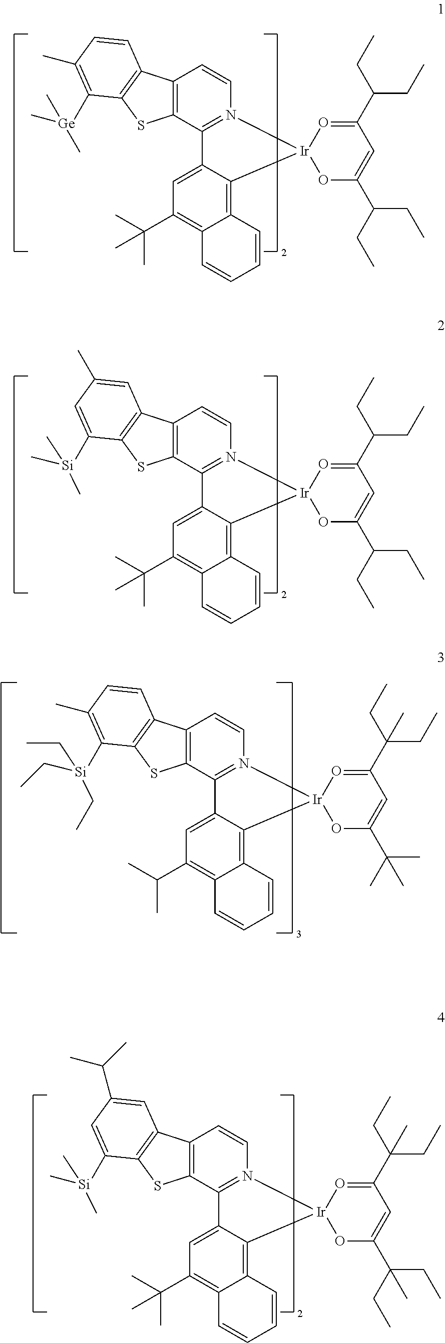

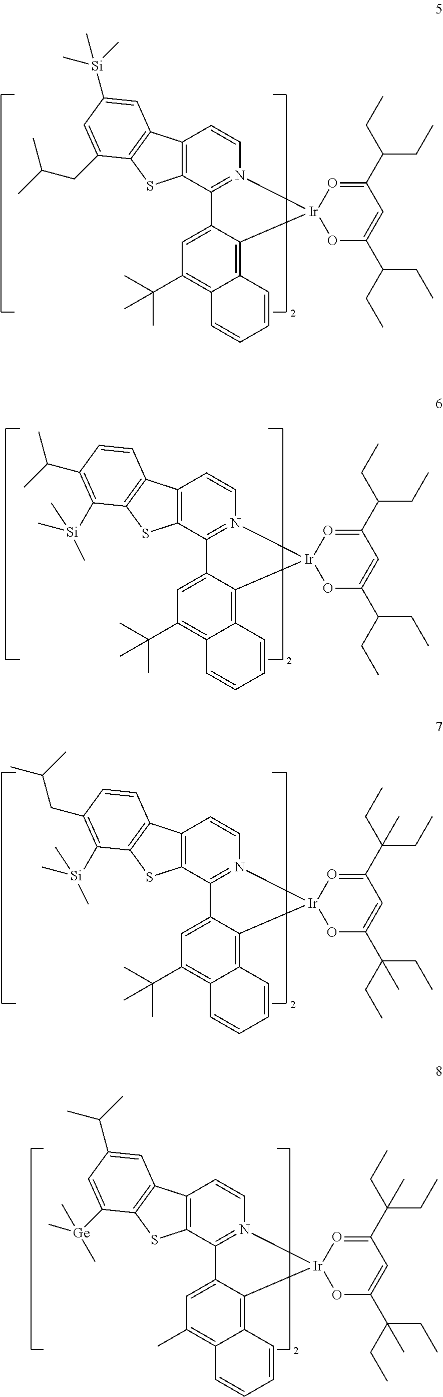

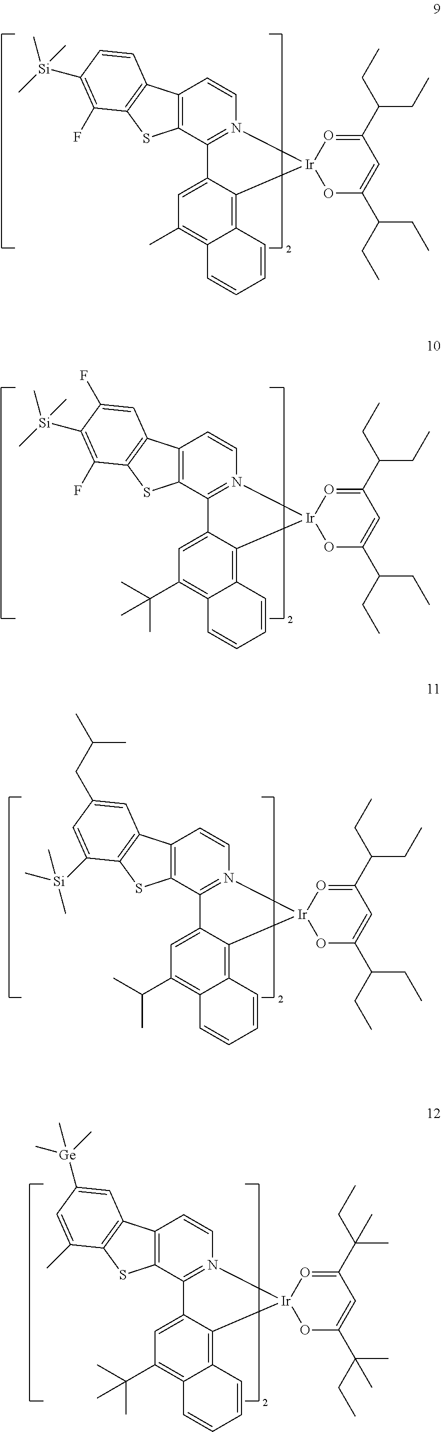

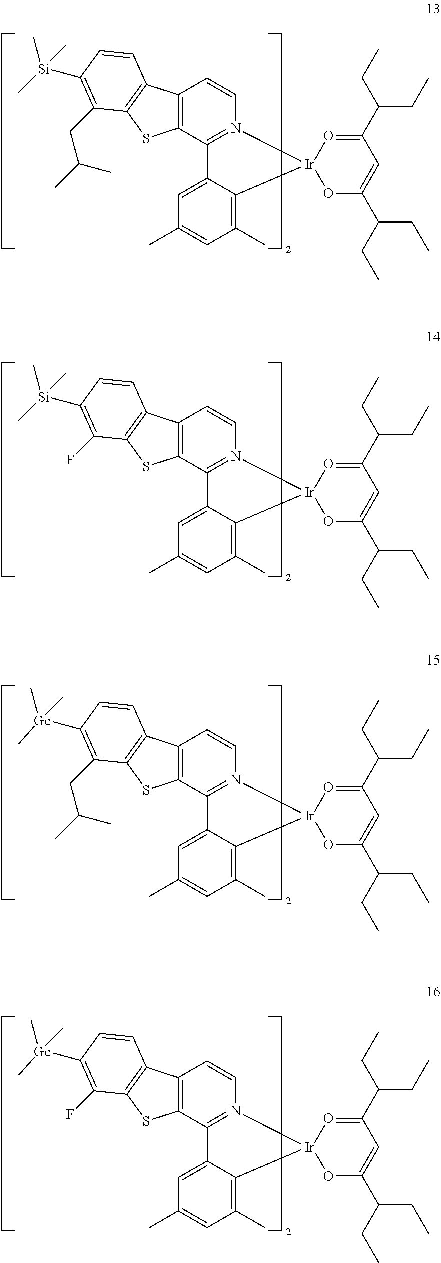

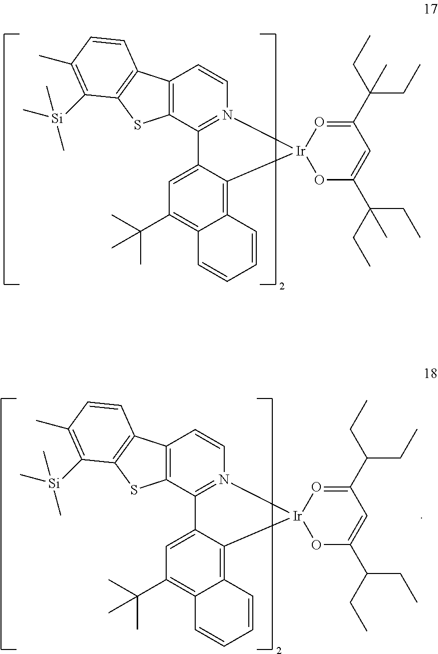

In one or more embodiments, the organometallic compound represented by Formula 1 may not be a compound of Group A:

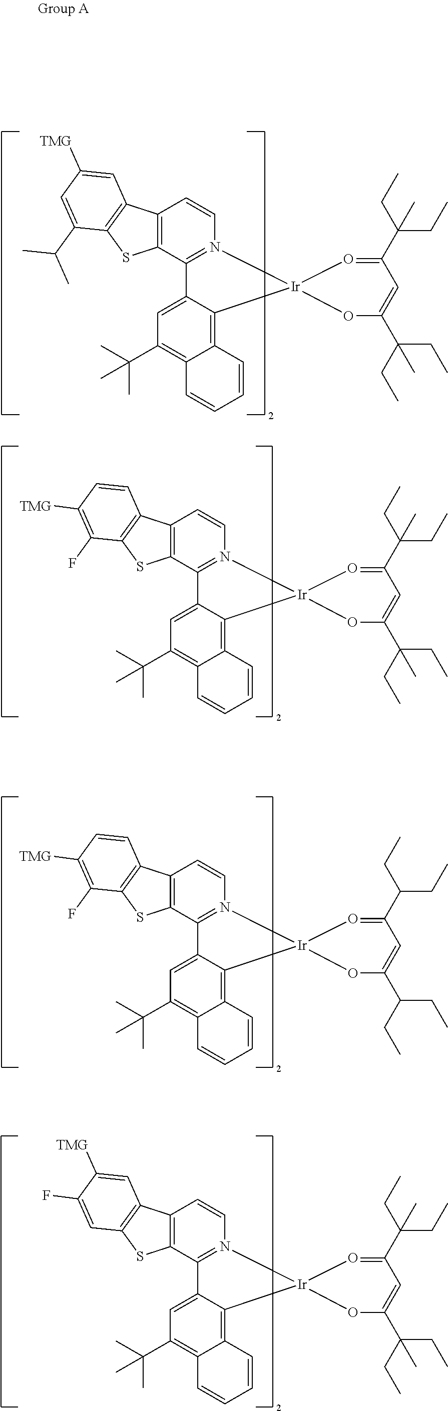

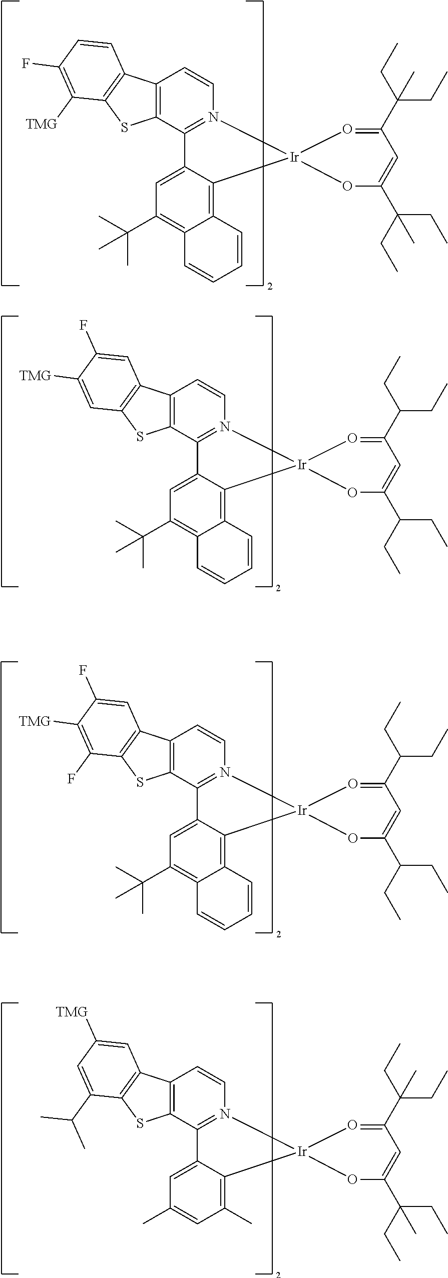

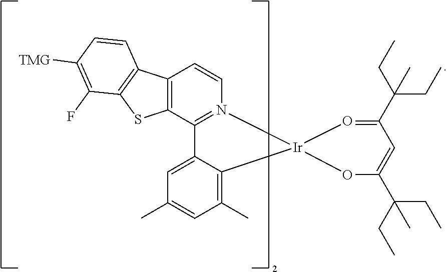

The organometallic compound represented by Formula 1 has a group represented by

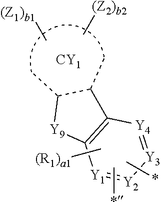

as described herein. Here, Z₁ is a group represented by —Si(Q₃)(Q₄)(Q₅) or a group represented by —Ge(Q₃)(Q₄)(Q₅), at least one of Z₂ is not hydrogen, and b1 and b2 are each independently an integer from 1 to 10. In other words, ring CY₁ in the organometallic compound represented by Formula 1 is substituted with at least one Z₁ and at least one Z₂ which is not hydrogen. Accordingly, hyper-conjugation is induced between a group represented by

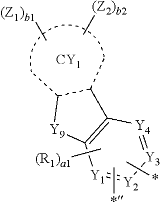

and ring CY₂ in Formula 1, and thus, dipole-orientation of the organometallic compound represented by Formula 1 is increased, thereby improving a horizontal orientation ratio of the organometallic compound. In addition, at least one of R₃₀ₐ and R_{30b} in Formula 1 is not a methyl group. Accordingly, interaction between the organometallic compounds may be reduced, and thus, a sublimation temperature of the organometallic compound may be relatively reduced. Luminescence efficiency and lifespan characteristics of an electronic device including the organometallic compound, for example, a light-emitting device, may be improved.

A highest occupied molecular orbital (HOMO) energy level, a lowest unoccupied molecular orbital (LUMO) energy level, and a triple (Ti) energy level of some compounds of the organometallic compound represented by Formula 1 were calculated using a density functional theory (DFT) method of the Gaussian 09 program with the molecular structure optimized at the B3LYP level, and results thereof are shown in Table 1. The energy levels are expressed in electron volts (eV).

TABLE 1

| Compound No. | HOMO (eV) | LUMO (eV) | T₁ (eV) |
|---|---|---|---|
| 4 | −5.202 | −2.068 | 1.991 |
| 1 | −5.201 | −2.051 | 1.995 |
| 6 | −5.222 | −2.065 | 1.994 |
| 13 | −5.255 | −2.018 | 2.060 |
| 14 | −5.285 | −2.089 | 2.031 |
| 15 | −5.242 | −2.013 | 2.059 |
| 16 | −5.275 | −2.080 | 2.030 |

In one or more embodiments, an absolute value of a HOMO energy level of the organometallic compound represented by Formula 1 may be in a range of about 5.100 eV to about 5.400 eV, for example, about 5.200 eV to about 5.300 eV.

In one or more embodiments, an absolute value of a LUMO energy level of the organometallic compound represented by Formula 1 may be in a range of about 1.900 eV to about 2.300 eV, for example, about 2.000 eV to about 2.100 eV.

In one or more embodiments, a T₁ energy level of the organometallic compound represented by Formula 1 may be in a range of about 1.900 eV to about 2.100 eV, for example, about 1.980 eV to about 2.100 eV.

A photoluminescence quantum efficiency (PLQY) in film of the organometallic compound represented by Formula 1 may be about 90% to about 100%, about 92% to about 100%, about 90% to about 95%, or about 92% to about 95%. One or more embodiments of a method of evaluating the PLQY in film may refer to Evaluation Example 1.

A horizontal orientation ratio of the organometallic compound represented by Formula 1 may be about 92% to about 100%, about 92% to about 99%, or about 92% to about 94%. One or more embodiments of a method of evaluating the horizontal orientation ratio may refer to Evaluation Example 2.

A sublimation temperature of the organometallic compound represented by Formula 1 may be less than about 300° C. In one or more embodiments, a sublimation temperature of the organometallic compound represented by Formula 1 may be about 250° C. to about 299° C., about 250° C. to about 295° C., or about 260° C. to about 295° C. One or more embodiments of a method of evaluating the sublimation temperature may refer to Evaluation Example 3.

Referring to Table 1, it was confirmed that the organometallic compound represented by Formula 1 has suitable electrical characteristics for use as a dopant in an electric device, for example, a light-emitting device.

Synthesis methods of the organometallic compound represented by Formula 1 may be recognizable by one of ordinary skill in the art by referring to the Synthesis Examples provided herein.

Accordingly, the organometallic compound represented by Formula 1 is suitable for use as a material for an organic layer of an organic light-emitting device, for example, a dopant in an emission layer of the organic layer. Thus, according to one or more embodiments, provided is a light-emitting device (for example, an organic light-emitting device) including: a first electrode; a second electrode; and an organic layer located between the first electrode and the second electrode, wherein the organic layer includes an emission layer, and wherein the organic layer includes at least one organometallic compound represented by Formula 1.

The light-emitting device includes an organic layer including the organometallic compound represented by Formula 1 as described herein, and thus, the light-emitting device may have excellent driving voltage, excellent external quantum efficiency, a relatively narrow FWHM of an emission peak of an electroluminescent (EL) spectrum, and excellent lifespan characteristics.

The organometallic compound represented by Formula 1 is arranged between a pair of electrodes of a light-emitting device. In one or more embodiments, the organometallic compound represented by Formula 1 may be included in the emission layer. In this case, the organometallic compound may serve as a dopant, and the emission layer may further include a host (that is, in the emission layer, an amount (for example, weight) of the organometallic compound represented by Formula 1 is less than an amount (for example, weight) of the host). The emission layer (or the light-emitting device including the emission layer) including the organometallic compound represented by Formula 1 may emit a red light or a green light, for example, a red light or a green light, each having a maximum emission wavelength of about 500 nm or greater, for example, about 500 nm to about 730 nm, or about 510 nm to about 730 nm, or about 520 nm to about 730 nm, or about 530 to about 730 nm, or about 540 nm to about 730 nm, or about 550 to about 730 nm. In one or more embodiments, the emission layer may emit a red light, for example, a red light having a maximum emission wavelength of about 580 nm to about 730 nm.

In one or more embodiments, the emission layer (or the light-emitting device including the emission layer) including the organometallic compound represented by Formula 1 may emit light having a maximum emission wavelength of about 525 nm to about 650 nm, about 550 nm to about 650 nm, about 575 nm to about 650 nm, about 600 nm to about 650 nm, about 610 nm to about 645 nm, or about 620 nm to about 645 nm.

In one or more embodiments, the emission layer (or the light-emitting device including the emission layer) including the organometallic compound represented by Formula 1 may emit light having a FWHM of about 25 nm to about 55 nm, about 25 nm to about 50 nm, about 30 nm to about 45 nm, or about 30 nm to about 43 nm.

The maximum emission wavelength and the FWHM may be evaluated from the EL spectrum of the light-emitting device.

In one or more embodiments, the emission layer (or the light-emitting device including the emission layer) including the organometallic compound represented by Formula 1 may emit red light.

The expression “(organic layer) includes at least one organometallic compound represented by Formula 1” as utilized herein may be to mean that the (organic layer) may include one kind of organometallic compound represented by Formula 1 or two or more different kinds of organometallic compounds, each represented by Formula 1.

In one or more embodiments, the organic layer may include Compound 1 only as the organometallic compound. In this regard, Compound 1 may be present in the emission layer of the light-emitting device. In one or more embodiments, the organic layer may include, as the organometallic compound, Compound 1 and Compound 2. In this case, Compound 1 and Compound 2 may be present in the same layer (for example, both Compound 1 and Compound 2 may be present in the emission layer).

The first electrode is an anode which is a hole injection electrode, the second electrode is a cathode which is an electron injection electrode, or the first electrode is a cathode which is an electron injection electrode, and the second electrode is an anode which is a hole injection electrode.

In one or more embodiments, in the light-emitting device, the first electrode may be an anode, the second electrode may be a cathode, the organic layer may further include a hole transport region arranged between the first electrode and the emission layer and an electron transport region arranged between the emission layer and the second electrode, the hole transport region may include a hole injection layer, a hole transport layer, an electron blocking layer, a buffer layer, or a combination thereof, and the electron transport region may include a hole blocking layer, an electron transport layer, an electron injection layer, or a combination thereof.

The term “organic layer” as utilized herein refers to a single layer and/or a plurality of layers arranged between the first electrode and the second electrode of the light-emitting device. The “organic layer” may include not only organic compounds but also organometallic complexes including metals.

The FIGURE is a schematic cross-sectional view of an organic light-emitting device 10, which is a light-emitting device according to one or more embodiments. Hereinafter, the structure and manufacturing method of the light-emitting device 10 according to one or more embodiments will be described with reference to the FIGURE. The organic light-emitting device 10 has a structure in which a first electrode 11, an organic layer 15, and a second electrode 19 are sequentially stacked.

A substrate may be additionally arranged under the first electrode 11 or above the second electrode 19. For use as the substrate, any suitable substrate that is used in organic light-emitting devices available in the art may be used, and the substrate may be a glass substrate or a transparent plastic substrate, each having excellent mechanical strength, thermal stability, transparency, surface smoothness, ease of handling, and/or water resistance.

The first electrode 11 may be, for example, formed by depositing or sputtering a material for forming the first electrode 11 on the substrate. The first electrode 11 may be an anode. The material for forming the first electrode 11 may include materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), zinc oxide (ZnO), or a combination thereof. In one or more embodiments, the material for forming the first electrode 11 may include magnesium (Mg), aluminum (Al), silver (Ag), aluminum-lithium (Al—Li), calcium (Ca), magnesium-indium (Mg—In), magnesium-silver (Mg—Ag), or a combination thereof.

The first electrode 11 may have a single-layered structure or a multi-layered structure including two or more layers. In one or more embodiments, the first electrode 11 may have a three-layered structure of ITO/Ag/ITO.

The organic layer 15 is arranged on the first electrode 11.

The organic layer 15 may include a hole transport region, an emission layer, and an electron transport region.

The hole transport region may be arranged between the first electrode 11 and the emission layer.

The hole transport region may include a hole injection layer, a hole transport layer, an electron blocking layer, a buffer layer, or a combination thereof.

The hole transport region may include a hole injection layer only or a hole transport layer only. In one or more embodiments, the hole transport region may have a hole injection layer/hole transport layer structure or a hole injection layer/hole transport layer/electron blocking layer structure, wherein, for each structure, respective layers are sequentially stacked in this stated order from the first electrode 11.

When the hole transport region includes a hole injection layer, the hole injection layer may be formed on the first electrode 11 by using one or more suitable methods, such as vacuum deposition, spin coating, casting, and Langmuir-Blodgett (LB) deposition.

When a hole injection layer is formed by vacuum deposition, the deposition conditions may vary depending on a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 angstroms per second (Å/sec) to about 100 Å/sec.

When the hole injection layer is formed using spin coating, coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C.

Conditions for forming the hole transport layer and the electron blocking layer may respectively be similar to or the same as the conditions for forming the hole injection layer.

The hole transport region may include one or more of 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(1-naphthyl)-N,N′-diphenylbenzidine (NPB), p-NPB, N,N′-bis(3-methylphenyl)-N,N′-diphenyl-[1,1-biphenyl]-4,4′-diamine (TPD), spiro-TPD, spiro-NPB, methylated NPB, 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, a compound represented by Formula 202, or a combination thereof:

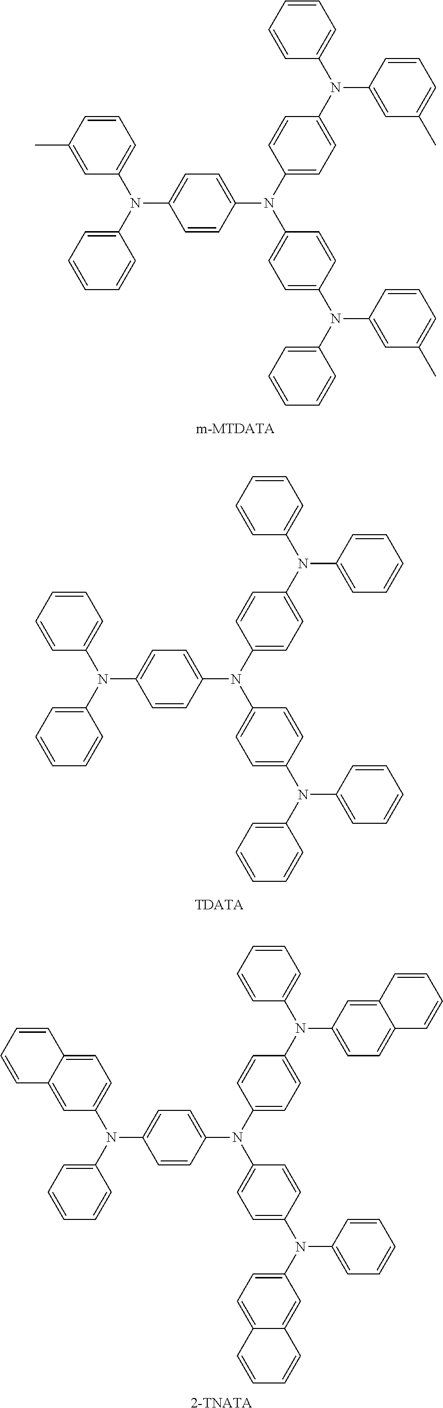

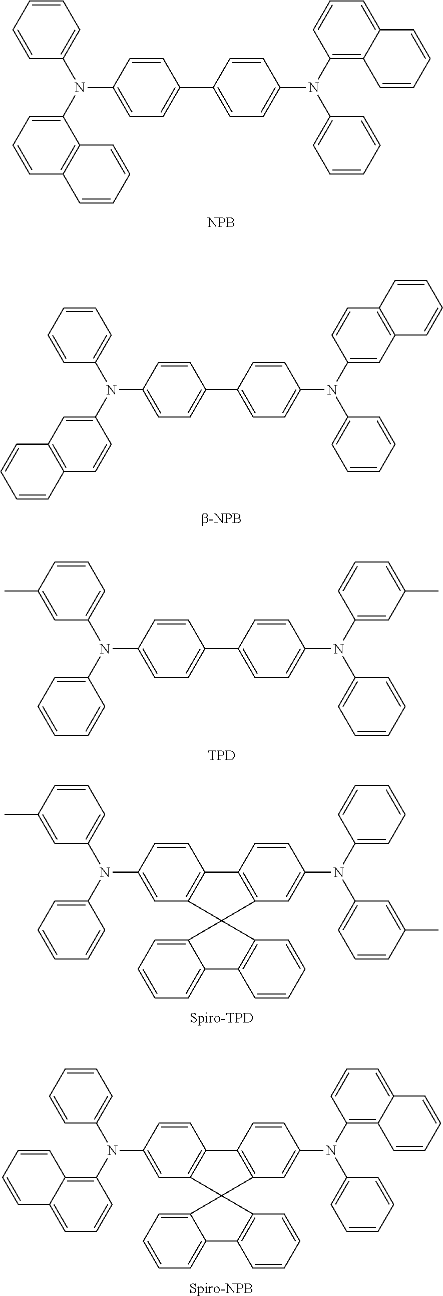

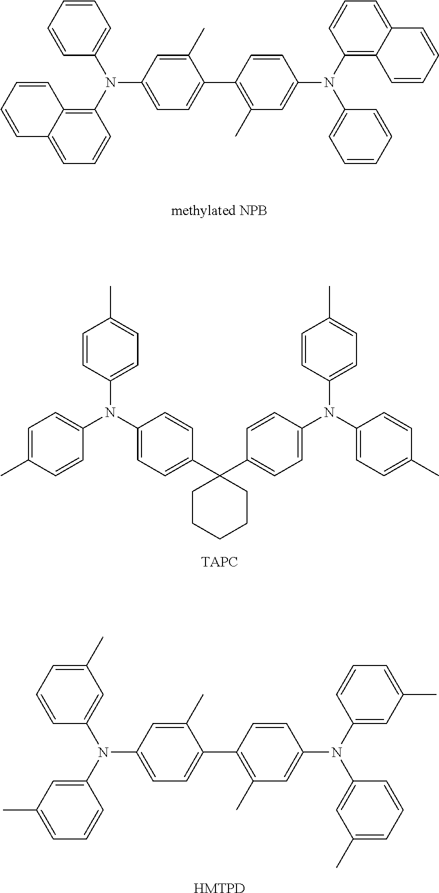

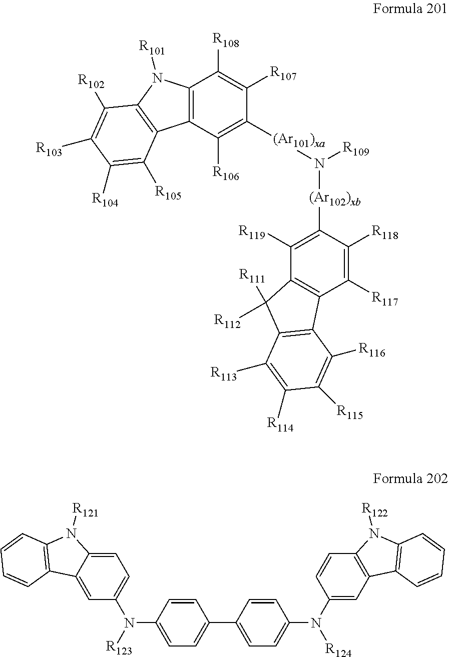

wherein, in Formula 201, Ar₁₀₁ and Ar₁₀₂ may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

In Formula 201, xa and xb may each independently be an integer from 0 to 5. In one or more embodiments, xa and xb may each independently be 0, 1, or 2. In one or more embodiments, xa may be 1 and xb may be 0.

In Formulae 201 and 202, R₁₀₁ to R₁₀₈, R₁₁₁ to R₁₁₉, and R₁₂₁ to R₁₂₄ may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, and a hexyl group), a C₁-C₁₀ alkoxy group (for example, a methoxy group, an ethoxy group, a propoxy group, a butoxy group, and a pentoxy group), or a C₁-C₁₀ alkylthio group;
a C₁-C₁₀ alkyl group, a C₁-C₁₀ alkoxy group, or a C₁-C₁₀ alkylthio group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof; or
a phenyl group, a naphthyl group, an anthracenyl group, a fluorenyl group, or a pyrenyl group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a C₁-C₁₀ alkylthio group, or a combination thereof.

R₁₀₉ in Formula 201 may be a phenyl group, a naphthyl group, an anthracenyl group, or a pyridinyl group, each unsubstituted or substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, a phenyl group, a naphthyl group, an anthracenyl group, a pyridinyl group, or a combination thereof.

In one or more embodiments, the compound represented by Formula 201 may be represented by Formula 201A:

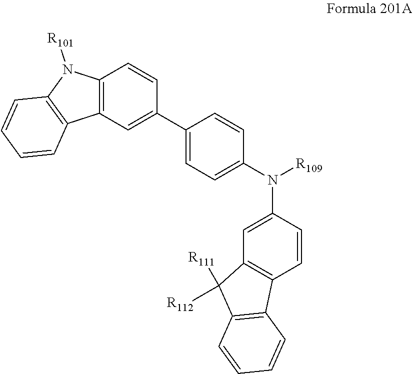

wherein, in Formula 201A, R₁₀₁, R₁₁₁, R₁₁₂, and R₁₀₉ may each independently be as described herein.

In one or more embodiments, the hole transport region may include one of Compounds HT1 to HT21, or a combination thereof:

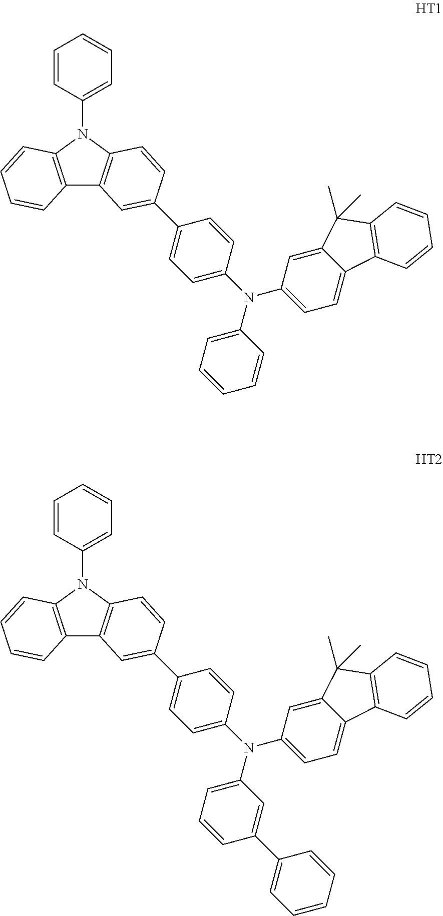 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21]

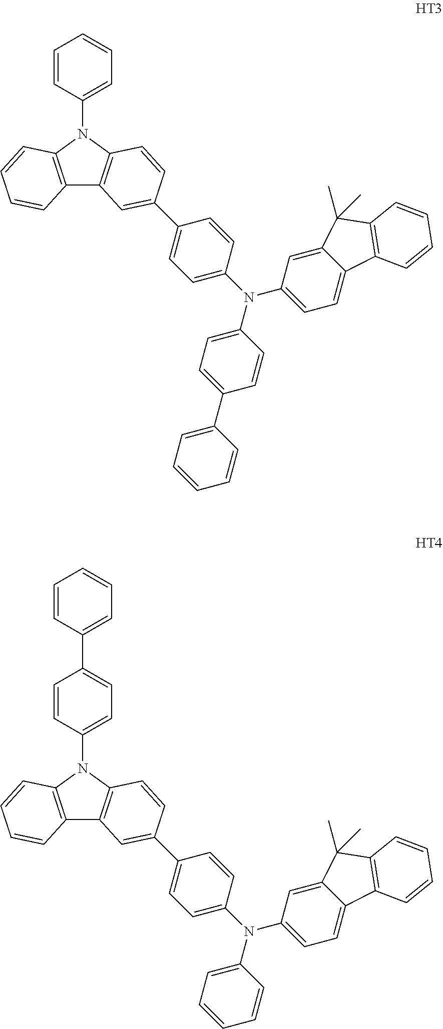 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

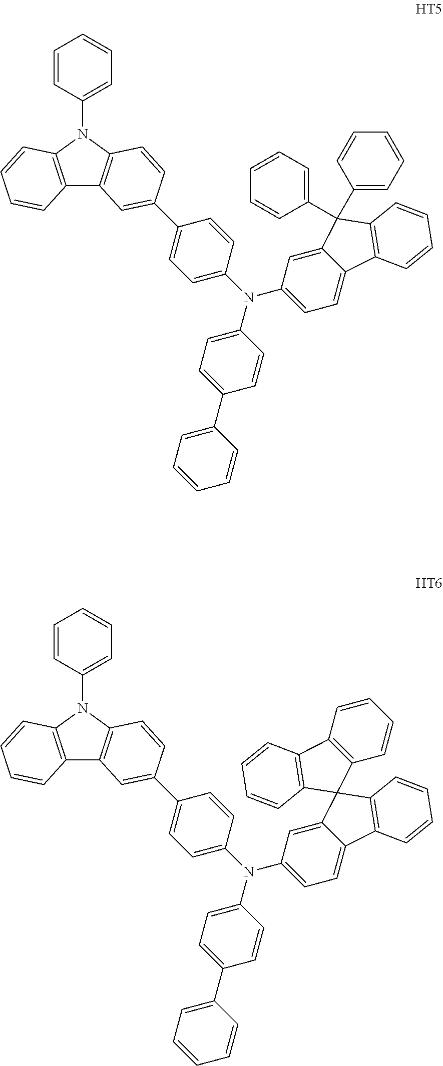 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

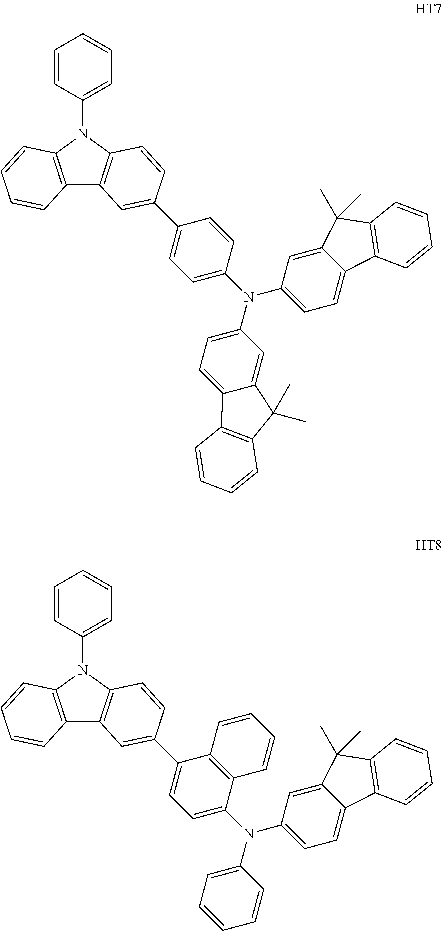 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

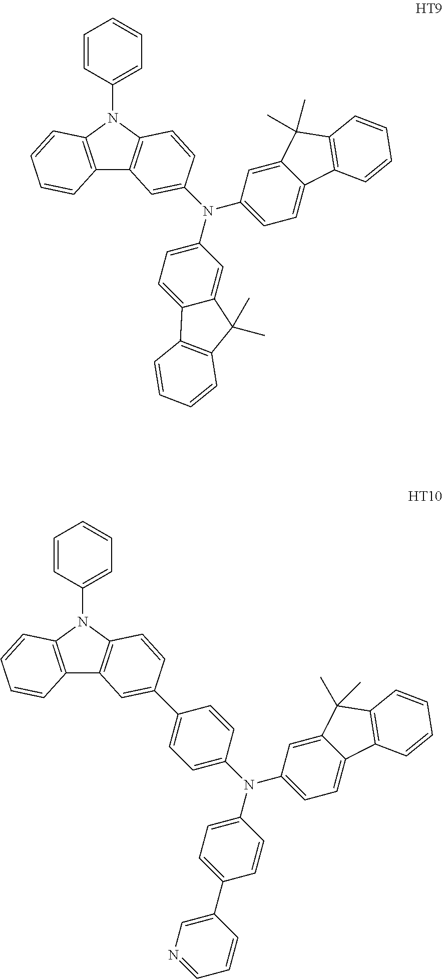 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

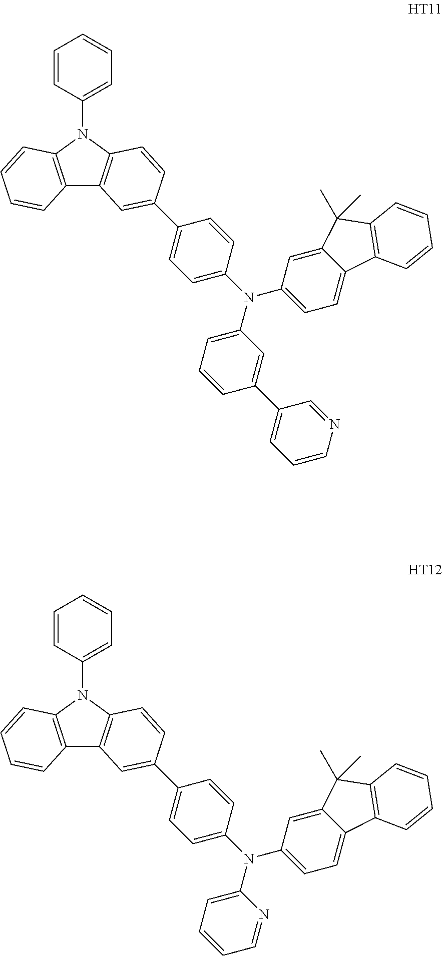 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

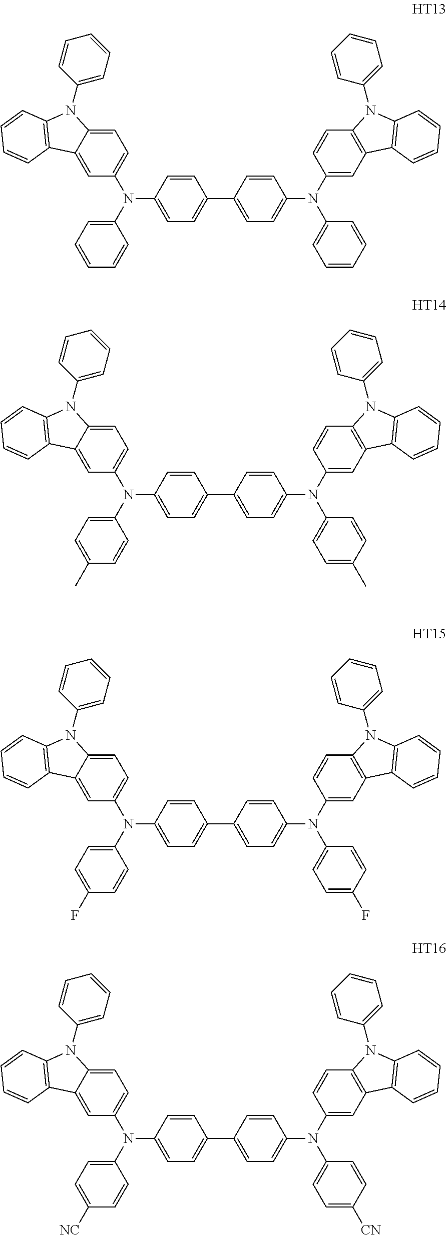 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

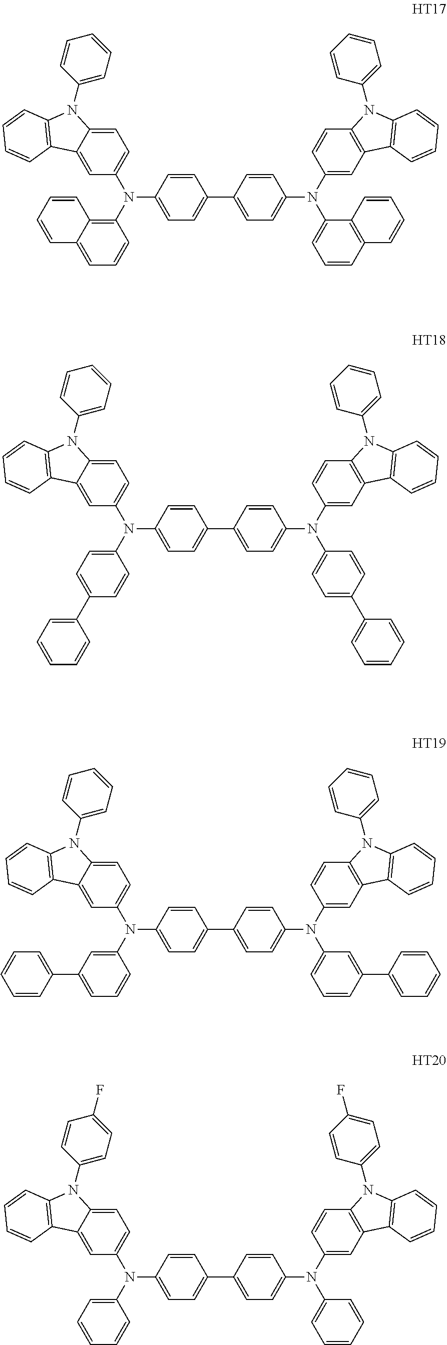 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

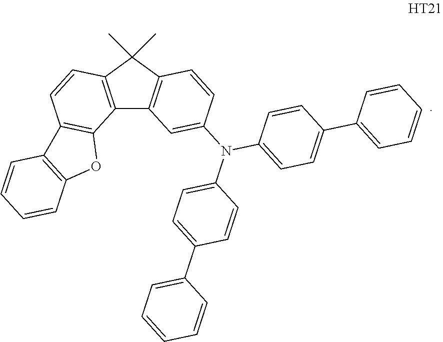 [SMILES: CC1(C)c2ccc(N(c3ccc(-c4ccccc4)cc3)c3ccc(-c4ccccc4)cc3)cc2-c2c1ccc1c2oc2ccccc21]

A thickness of the hole transport region may be in a range of about 100 angstroms (Å) to about 10,000 Å, for example, about 100 Å to about 1,000 Å. When the hole transport region includes a hole injection layer, a hole transport layer, an electron blocking layer, or a combination thereof, a thickness of the hole injection layer may be about 100 Å to about 10,000 Å, for example, about 100 Å to about 1,000 Å, and a thickness of the hole transport layer may be about 50 Å to about 2,000 Å, for example, about 100 Å to about 1,500 Å. When the thicknesses of the hole transport region, the hole injection layer, and the hole transport layer are within any of these ranges, satisfactory hole transport characteristics may be obtained without a substantial increase in driving voltage.

The hole transport region may further include a charge-generation material as well as the aforementioned materials to improve conductive properties of the hole transport region. The charge-generation material may be homogeneously or non-homogeneously dispersed in the hole transport region.

The charge-generation material may be, for example, a p-dopant. The p-dopant may include a quinone derivative, a metal oxide, a cyano group-containing compound, or a combination thereof. In one or more embodiments, the p-dopant may include: a quinone derivative such as tetracyanoquinodimethane (TCNQ), 2,3,5,6-tetrafluoro-tetracyano-1,4-benzoquinonedimethane(F4-TCNQ), or F6-TCNNQ; a metal oxide such as a tungsten oxide or a molybdenum oxide; a cyano group-containing compound such as Compound HT-D1; or a combination thereof.

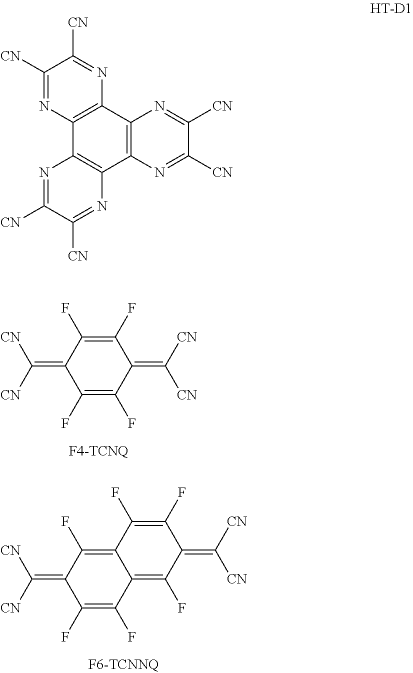

The hole transport region may further include a buffer layer.

The buffer layer may compensate for an optical resonance distance according to a wavelength of light emitted from the emission layer, and thus, efficiency of the light-emitting device may be improved.

In one or more embodiments, when the hole transport region includes an electron blocking layer, a material for forming the electron blocking layer may include a material that can be used in the hole transport region as described above, a host material described below, or a combination thereof. In one or more embodiments, when the hole transport region includes an electron blocking layer, mCP, Compound H21, or a combination thereof may be used as the material for forming the electron blocking layer.

An emission layer may be formed on the hole transport region by using one or more suitable methods, such as vacuum deposition, spin coating, casting, or LB deposition. When the emission layer is formed by vacuum deposition and spin coating, vacuum deposition and coating conditions for forming the emission layer may be generally similar to those conditions for forming a hole injection layer, though the conditions may vary depending on a compound that is used.

The emission layer may include a host and a dopant, and the dopant may include the organometallic compound represented by Formula 1 as described herein.

The host may include 1,3,5-tri(1-phenyl-1H-benzo[d]imidazol-2-yl)phenyl (TPBi), 3-tert-butyl-9,10-di(naphth-2-yl)anthracene (TBADN), 9,10-di(naphthalene-2-yl)anthracene (ADN) (also referred to as “DNA”), 4,4′-bis(N-carbazolyl)-1,1′-biphenyl (CBP), 4,4′-bis(9-carbazolyl)-2,2′-dimethyl-biphenyl (CDBP), 1,3,5-tris(carbazole-9-yl)benzene (TCP), 1,3-bis(N-carbazolyl)benzene (mCP), Compound H50, Compound H51, Compound H52, or a combination thereof:

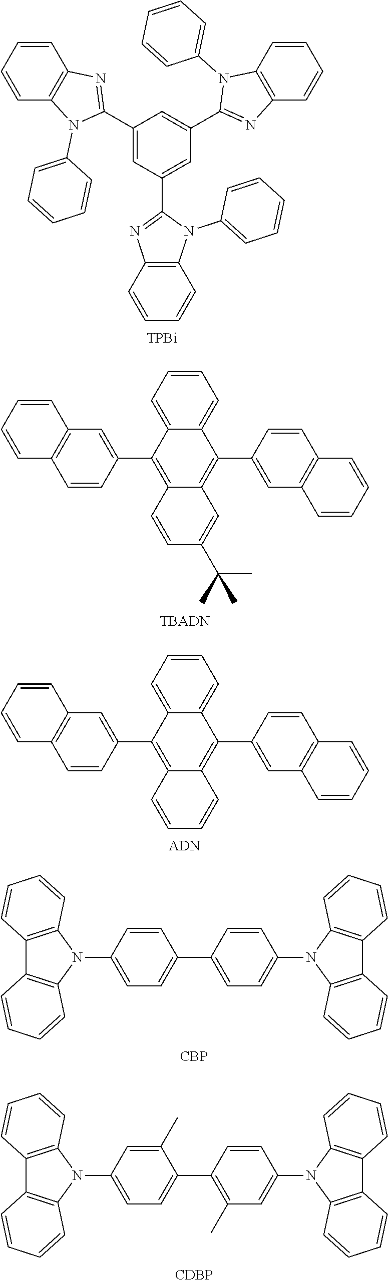

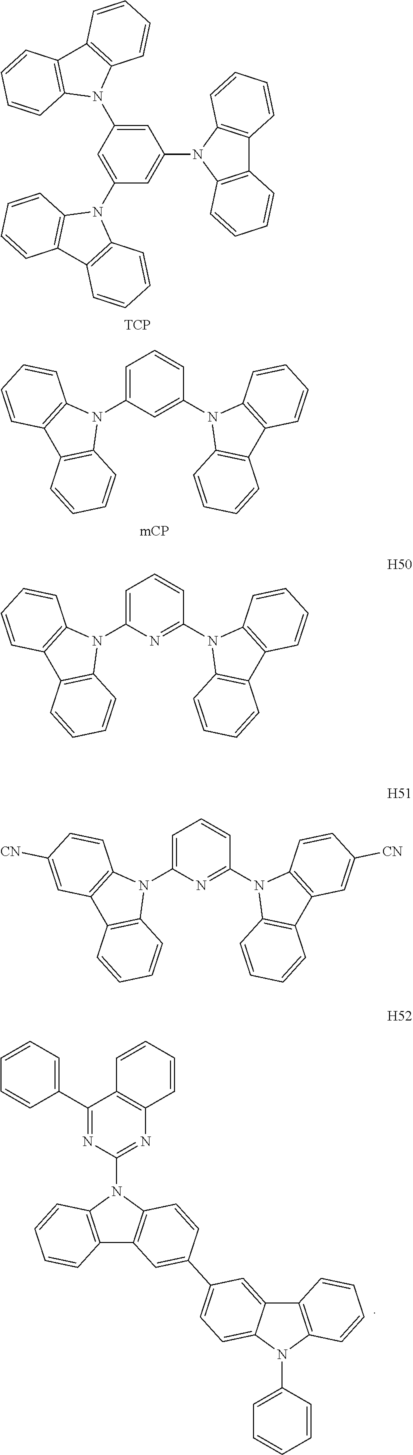

When the organic light-emitting device is a full-color organic light-emitting device, the emission layer may be patterned into a red emission layer, a green emission layer, and/or a blue emission layer. In one or more embodiments, the emission layer may have a structure in which the red emission layer, the green emission layer, and/or the blue emission layer are layered to emit white light. In one or more embodiments, the structure of the emission layer may vary.

When the emission layer includes a host and a dopant, an amount of the dopant may be about 0.01 parts by weight to about 15 parts by weight, based on 100 parts by weight of the host.

A thickness of the emission layer may be in a range of about 100 Å to about 1,000 Å, for example, about 200 Å to about 600 Å. When the thickness of the emission layer is within the range, excellent light-emission characteristics may be obtained without a substantial increase in driving voltage.

Next, the electron transport region is arranged on the emission layer.

The electron transport region may include a hole blocking layer, an electron transport layer, an electron injection layer, or a combination thereof.

In one or more embodiments, the electron transport region may have a hole blocking layer/electron transport layer/electron injection layer structure or an electron transport layer/electron injection layer structure. The electron transport layer may have a single-layered structure or a multi-layered structure including two or more different materials.

The conditions for forming a hole blocking layer, an electron transport layer, and an electron injection layer which constitute the electron transport region may be similar to or the same as the conditions for forming the hole injection layer.

When the electron transport region includes a hole blocking layer, the hole blocking layer may include, for example, at least one of 2,9-dimethyl-4,7-diphenyl-1,10-phenanthroline (BCP), 4,7-diphenyl-1,10-phenanthroline (Bphen), bis(2-methyl-8-quinolinolato-N1,O8)-(1,1′-biphenyl-4-olato)aluminum (BAIq), or a combination thereof.

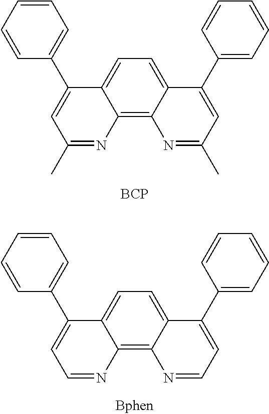

In one or more embodiments, the hole blocking layer may include the host, a material for forming an electron transport layer, a material for forming an electron injection layer, which will be described later, or a combination thereof.

A thickness of the hole blocking layer may be in a range of about 20 Å to about 1,000 Å, for example, about 30 Å to about 600 Å. When the thickness of the hole blocking layer is within these ranges, excellent hole blocking characteristics may be obtained without a substantial increase in driving voltage.

The electron transport layer may include 2,9-dimethyl-4,7-diphenyl-1,10-phenanthroline (BCP), 4,7-diphenyl-1,10-phenanthroline (Bphen), TPBi, tris(8-hydroxy-quinolinato)aluminum (Alq3), bis(2-methyl-8-quinolinolato-N1,O8)-(1,1′-biphenyl-4-olato)aluminum (BAlq), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), or a combination thereof:

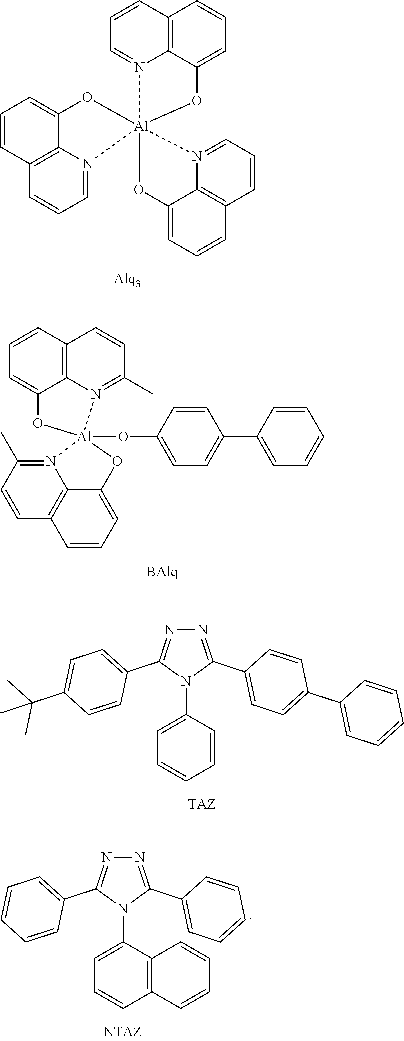

In one or more embodiments, the electron transport layer may include one of Compounds ET1 to ET25, or a combination thereof:

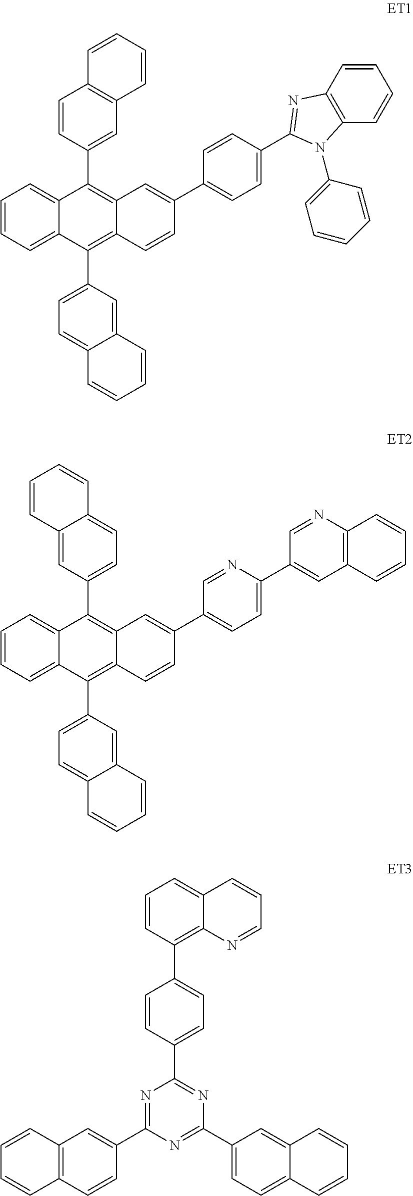 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

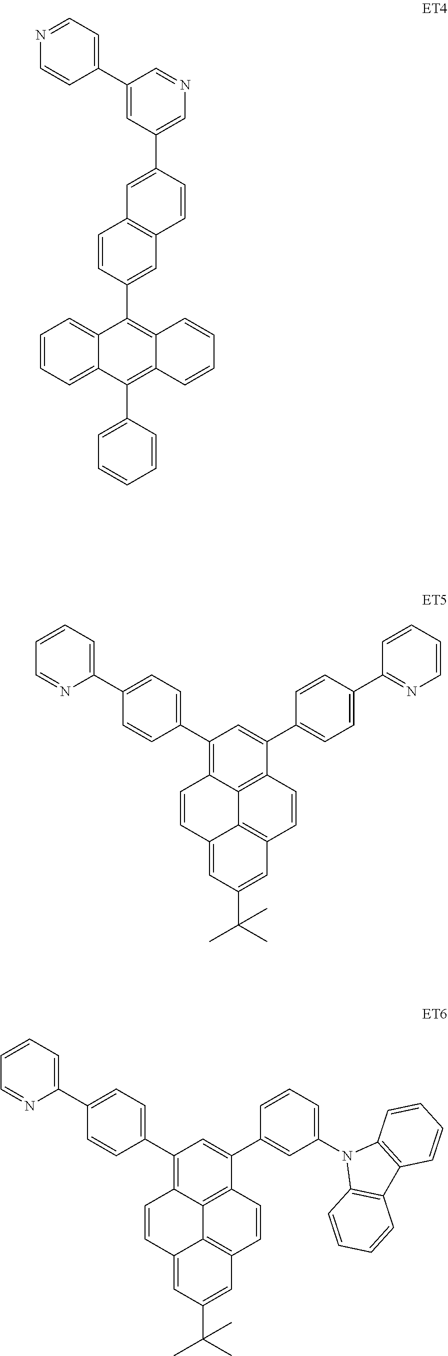 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

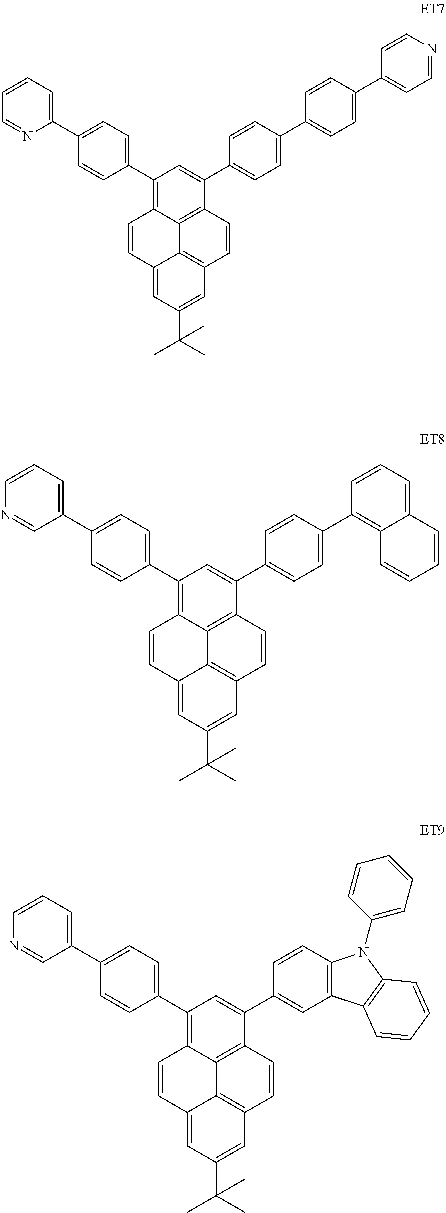 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

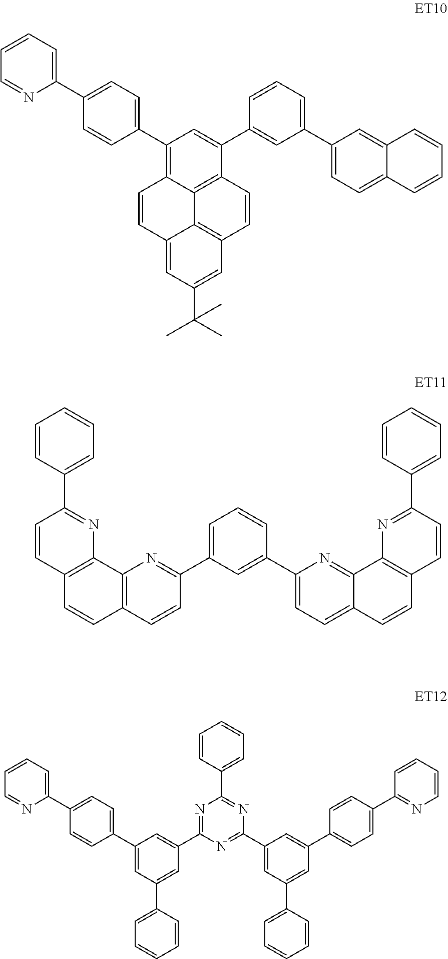 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1]

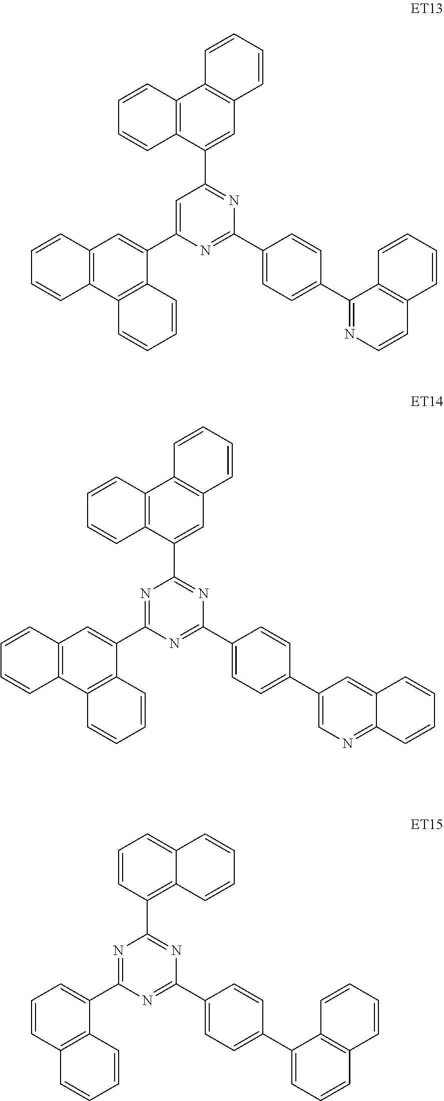 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1]

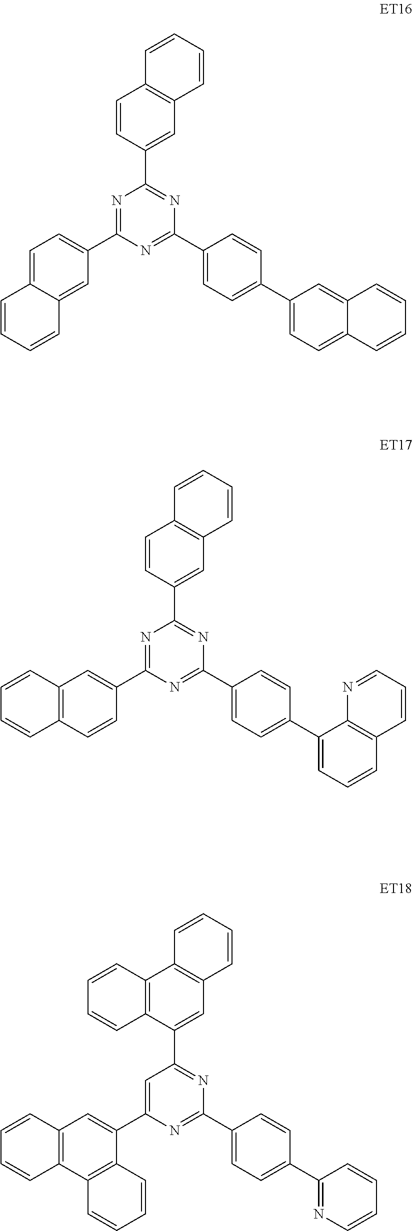 [SMILES: c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1]

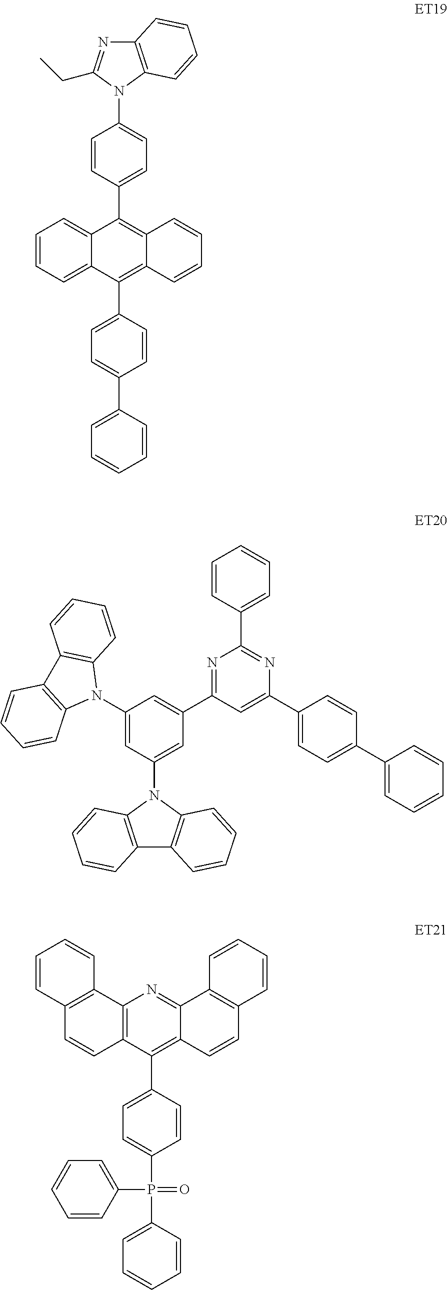 [SMILES: CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; O=P(c1ccccc1)(c1ccccc1)c1ccc(-c2c3ccc4ccccc4c3nc3c2ccc2ccccc23)cc1]

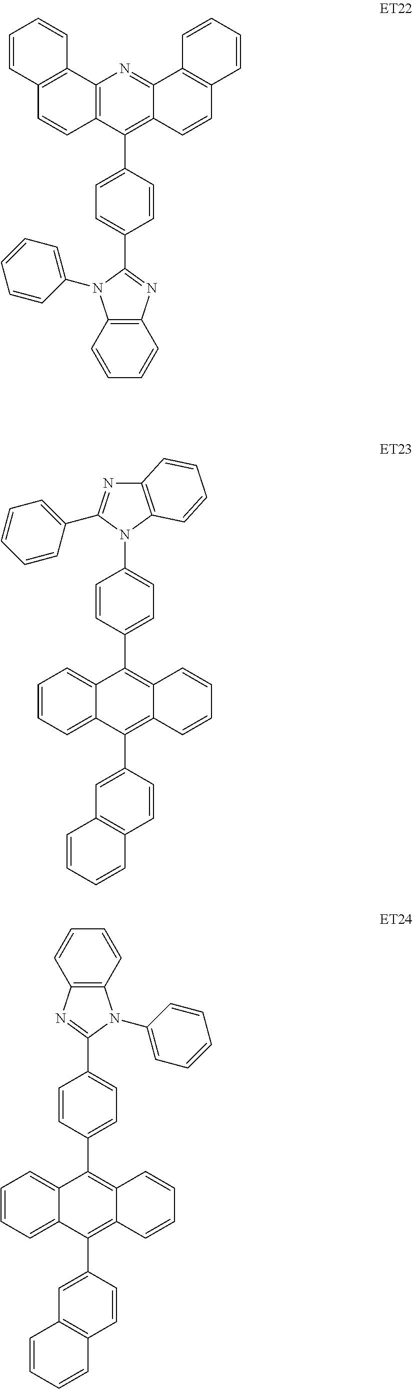

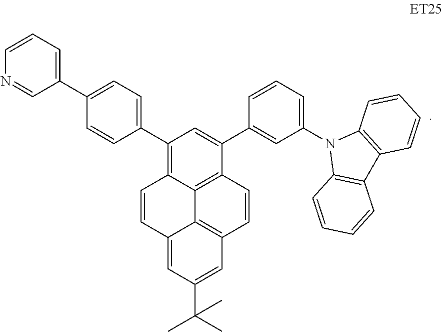 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. When the thickness of the electron transport layer is within the range described above, satisfactory electron transporting characteristics may be obtained without a substantial increase in driving voltage.

The electron transport layer may include, in addition to the materials described above, a metal-containing material.

The metal-containing material may include a Li complex. The Li complex may include, for example, Compound ET-D1 or ET-D2.

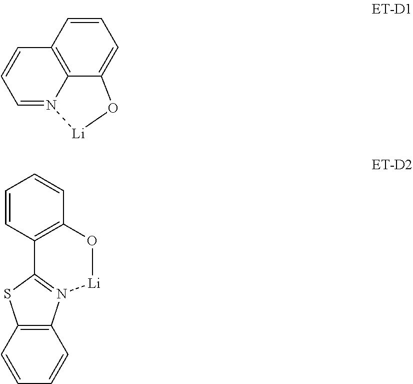

Also, the electron transport region may include an electron injection layer that facilitates electron injection from the second electrode 19.

The electron injection layer may include LiF, NaCl, CsF, Li₂O, BaO, or a combination thereof.

The thickness of the electron injection layer may be in a range of about 1 Å to about 100 Å, for example, about 3 Å to about 90 Å. When the thickness of the electron injection layer is within the range described above, satisfactory electron injection characteristics may be obtained without a substantial increase in driving voltage.

The second electrode 19 may be arranged on the organic layer 15. The second electrode 19 may be a cathode. A material for forming the second electrode 19 may be metal, an alloy, an electrically conductive compound, or a combination thereof, which have a relatively low work function. Examples of the material for forming the second electrode 19 may include lithium (Li), magnesium (Mg), aluminum (Al), silver (Ag), aluminum-lithium (Al—Li), calcium (Ca), magnesium-indium (Mg—In), magnesium-silver (Mg—Ag), or a combination thereof. In one or more embodiments, to manufacture a top-emission type light-emitting device, a transmissive electrode formed using ITO or IZO may be used as the second electrode 19.

Hereinbefore, the light-emitting device has been described in connection with the FIGURE, but embodiments are not limited thereto.

According to one or more embodiments, the light-emitting device may be included in an electronic apparatus. Therefore, provided is an electronic apparatus including the light-emitting device. The electronic apparatus may include, for example, a display, lighting, a sensor, or the like.

According to one or more embodiments, provided is a diagnostic composition including at least one organometallic compound represented by Formula 1.

Because the organometallic compound represented by Formula 1 provides high luminescence efficiency, the diagnostic efficiency of the diagnostic composition that includes the organometallic compound represented by Formula 1 may be excellent.

The diagnostic composition may be applied in various ways, such as in a diagnostic kit, a diagnostic reagent, a biosensor, or a biomarker.

The term “C₁-C₆₀ alkyl group” as used herein refers to a linear or branched saturated aliphatic hydrocarbon monovalent group having 1 to 60 carbon atoms, and the term “C₁-C₆₀ alkylene group” as used herein refers to a divalent group having the same structure as the C₁-C₆₀ alkyl group.

Non-limiting examples of the C₁-C₆₀ alkyl group, the C₁-C₂₀ alkyl group, and/or the C₁-C₁₀ alkyl group may include a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, or a tert-decyl group, each unsubstituted or substituted with at least one of a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, or the like. In one or more embodiments, Formula 9-33 is a branched C₆ alkyl group, for example, a tert-butyl group that is substituted with two methyl groups.

The term “C₁-C₆₀ alkoxy group” as used herein refers to a monovalent group having the formula of -OA₁₀₁ (where A₁₀₁ is the C₁-C₆₀ alkyl group). The term “C₁-C₆₀ alkylthio group” as used herein refers to a monovalent group having the formula of -SA₁₀₁ (where A₁₀₁ is the C₁-C₆₀ alkyl group).

Non-limiting examples of the C₁-C₆₀ alkoxy group, the C₁-C₂₀ alkoxy group, or the C₁-C₁₀ alkoxy group may include a methoxy group, an ethoxy group, a propoxy group, a butoxy group, a pentoxy group, or the like.

The term “C₂-C₆₀ alkenyl group” as used herein has a structure including at least one carbon-carbon double bond in the middle or at the terminus of the C₂-C₆₀ alkyl group.

Non-limiting examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein has a structure including at least one carbon-carbon triple bond in the middle or at the terminus of the C₂-C₆₀ alkyl group.

Non-limiting examples thereof include an ethynyl group, a propynyl group, or the like. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Non-limiting examples of the C₃-C₁₀ cycloalkyl group may include a cyclopropyl group, a cyclobutyl group, a cyclopentyl group, a cyclohexyl group, a cycloheptyl group, a cyclooctyl group, an adamantanyl group, a norbornanyl group (a bicyclo[2.2.1]heptyl group), a bicyclo[1.1.1]pentyl group, a bicyclo[2.1.1]hexyl group, a bicyclo[2.2.2]octyl group, or the like.

The term “C₁-C₁₀ heterocycloalkyl group” as used herein refers to a monovalent saturated cyclic group that includes at least one hetero atom selected from N, O, P, Si, S, Se, Ge, and B as a ring-forming atom and 1 to 10 carbon atoms, and the term “C₁-C₁₀ heterocycloalkylene group” as used herein refers to a divalent group having the same structure as the C₁-C₁₀ heterocycloalkyl group.

Non-limiting examples of the C₁-C₁₀ heterocycloalkyl group may include a silolanyl group, a silinanyl group, a tetrahydrofuranyl group, a tetrahydro-2H-pyranyl group, a tetrahydrothiophenyl group, or the like.

The term “C₃-C₁₀ cycloalkenyl group” as used herein refers to a monovalent monocyclic group including 3 to 10 carbon atoms and at least one carbon-carbon double bond in its ring, wherein the molecular structure as a whole is non-aromatic. Non-limiting examples thereof include a cyclopentenyl group, a cyclohexenyl group, a cycloheptenyl group, or the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that includes at least one heteroatom selected from N, O, P, Si, S, Se, Ge, and B as a ring-forming atom, 1 to 10 carbon atoms, and at least one double bond in the ring thereof. Non-limiting examples of the C₁-C₁₀ heterocycloalkenyl group include a 2,3-dihydrofuranyl group, a 2,3-dihydrothiophenyl group, or the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group that includes a carbocyclic aromatic system having 6 to 60 carbon atoms, and the term “C₆-Cao arylene group” as used herein refers to a divalent group that includes a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, a chrysenyl group, or the like. When the C₆-C₆₀ aryl group and a C₆-C₆₀ arylene group each include at least two rings, the at least two rings may be fused.

The term “C₇-C₆₀ alkyl aryl group” as used herein refers to a C₆-C₆₀ aryl group that is substituted with at least one C₁-C₆₀ alkyl group. The term “C₇-C₆₀ aryl alkyl group” as used herein refers to a C₁-C₆₀ alkyl group that is substituted with at least one C₆-C₆a aryl group.

The term “C₁-C₆₀ heteroaryl group” as used herein refers to a monovalent group having a cyclic aromatic system having at least one hetero atom selected from N, O, P, Si, S, Se, Ge, and B as a ring-forming atom and 1 to 60 carbon atoms, and the term “C₁-C₆₀ heteroarylene group” as used herein refers to a divalent group having a cyclic aromatic system having at least one hetero atom selected from N, O, P, Si, S, Se, Ge, and B as a ring-forming atom and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, an isoquinolinyl group, or the like. When the C₁-C₆₀ heteroaryl group and the C₁-C₆₀ heteroarylene group each include at least two rings, the at least two rings may be fused.

The term “C₂-C₆₀ alkyl heteroaryl group” as used herein refers to a C₁-C₆₀ heteroaryl group that is substituted with at least one C₁-C₆₀ alkyl group. The term “C₂-C₆₀ heteroaryl alkyl group” as used herein refers to a C₁-C₆₀ alkyl group that is substituted with at least one C₁-C₆₀ heteroaryl group.

The term “C₆-C₆₀ aryloxy group” as used herein indicates -OA₁₀₂ (wherein A102 is the C₆-C₆₀ aryl group), the term “C₆-C₆₀ arylthio group” as used herein indicates -SA₁₀₃ (wherein A103 is the C₆-C₆₀ aryl group), and the term “C₁-C₆₀ alkylthio group” as used herein indicates -SA₁₀₄ (wherein A104 is the C₁-C₆₀ alkyl group).

The term “C₁-C₆₀ heteroaryloxy group” as used herein indicates -OA₁₀₂ (wherein A102 is the C₁-C₆₀ heteroaryl group), and the term “C₁-C₆₀ heteroarylthio group” as used herein indicates -SA₁₀₃ (wherein A103 is the C₁-C₆₀ heteroaryl group).

The term “monovalent non-aromatic condensed polycyclic group” as used herein refers to a monovalent group having two or more rings condensed to each other, only carbon atoms (for example, having 8 to 60 carbon atoms) as ring-forming atoms, and non-aromaticity in its molecular structure when considered as a whole. Non-limiting examples of the monovalent non-aromatic condensed polycyclic group include a fluorenyl group or the like. The term “divalent non-aromatic condensed polycyclic group” as used herein refers to a divalent group having the same structure as a monovalent non-aromatic condensed polycyclic group.

The term “monovalent non-aromatic condensed heteropolycyclic group” as used herein refers to a monovalent group (for example, having 1 to 60 carbon atoms) having two or more rings condensed to each other, at least one heteroatom selected from N, O, P, Si, S, Se, Ge, and B, other than carbon atoms, as a ring-forming atom, and no aromaticity in its molecular structure when considered as a whole. Non-limiting examples of the monovalent non-aromatic condensed heteropolycyclic group include a carbazolyl group or the like. The term “divalent non-aromatic condensed heteropolycyclic group” as used herein refers to a divalent group having the same structure as a monovalent non-aromatic condensed heteropolycyclic group.

The term “C₅-C₃₀ carbocyclic group” as used herein refers to a saturated or unsaturated cyclic group including 5 to 30 carbon atoms only as ring-forming atoms. The C₅-C₃₀ carbocyclic group may be a monocyclic group or a polycyclic group. Non-limiting examples of the “C₅-C₃₀ carbocyclic group (unsubstituted or substituted with at least one R₁₀ₐ)” may include an adamantane group, a norbornane group (a bicyclo[2.2.1]heptane group), a norbornene group, a bicyclo[1.1.1]pentane group, a bicyclo[2.1.1]hexane group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a fluorene group, or the like (each unsubstituted or substituted with at least one R₁₀ₐ).

The term “C₁-C₃₀ heterocyclic group” as used herein refers to a saturated or unsaturated cyclic group having, as a ring-forming atom, at least one heteroatom selected from N, O, P, Si, Se, Ge, B, and S other than 1 to 30 carbon atoms. The C₁-C₃₀ heterocyclic group may be a monocyclic group or a polycyclic group. Non-limiting examples of the “C₁-C₃₀ heterocyclic group (unsubstituted or substituted with at least one R₁₀ₐ)” may include a thiophene group, a furan group, a pyrrole group, a silole group, a borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an iso-oxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, or the like (each unsubstituted or substituted with at least one R₁₀ₐ).

The terms “fluorinated C₁-C₆₀ alkyl group (or, a fluorinated C₁-C₂₀ alkyl group, or the like)”, “fluorinated C₃-C₁₀ cycloalkyl group”, “fluorinated C₁-C₁₀ heterocycloalkyl group”, and “fluorinated phenyl group” as used herein respectively refer to a C₁-C₆₀ alkyl group (or, a C₁-C₂₀ alkyl group, or the like), a C₃-C₁₀ cycloalkyl group, a C₁-C₁₀ heterocycloalkyl group, and a phenyl group, each substituted with at least one fluoro group (—F). In one or more embodiments, the term “fluorinated C₁ alkyl group (i.e., a fluorinated methyl group)” includes —CF₃, —CF₂H, and —CFH₂. The “fluorinated C₁-C₆₀ alkyl group (or, a fluorinated C₁-C₂₀ alkyl group, or the like)”, the “fluorinated C₃-C₁₀ cycloalkyl group”, the “fluorinated C₁-C₁₀ heterocycloalkyl group”, or the “fluorinated a phenyl group” may be i) a fully fluorinated C₁-C₆₀ alkyl group (or, a fully fluorinated C₁-C₂₀ alkyl group, etc.), a fully fluorinated C₃-C₁₀ cycloalkyl group, a fully fluorinated C₁-C₁₀ heterocycloalkyl group, or a fully fluorinated phenyl group, wherein, in each group, all hydrogen included therein is substituted with a fluoro group, or ii) a partially fluorinated C₁-C₆₀ alkyl group (or, a partially fluorinated C₁-C₂₀ alkyl group, or the like), a partially fluorinated C₃-C₁₀ cycloalkyl group, a partially fluorinated C₁-C₁₀ heterocycloalkyl group, or a partially fluorinated phenyl group, wherein, in each group, all hydrogen included therein is not substituted with a fluoro group.

The term “deuterated C₁-C₆₀ alkyl group (or, a deuterated C₁-C₂₀ alkyl group, or the like)”, “deuterated C₃-C₁₀ cycloalkyl group”, “deuterated C₁-C₁₀ heterocycloalkyl group”, and “deuterated phenyl group” as used herein respectively refer to a C₁-C₆₀ alkyl group (or, a C₁-C₂₀ alkyl group, or the like), a C₃-C₁₀ cycloalkyl group, a C₁-C₁₀ heterocycloalkyl group, and a phenyl group, each substituted with at least one deuterium.

In one or more embodiments, the “deuterated C₁ alkyl group (i.e., a deuterated methyl group)” may include-CD₃, —CD₂H, and -CDH₂, and examples of the “deuterated C₃-C₁₀ cycloalkyl group” may refer to, for example, Formula 10-501. The “deuterated C₁-C₆₀ alkyl group (or, the deuterated C₁-C₂₀ alkyl group, or the like)”, the “deuterated C₃-C₁₀ cycloalkyl group”, the “deuterated C₁-C₁₀ heterocycloalkyl group”, or the “deuterated phenyl group” may be i) a fully deuterated C₁-C₆₀ alkyl group (or, a fully deuterated C₁-C₂₀ alkyl group, or the like), a fully deuterated C₃-C₁₀ cycloalkyl group, a fully deuterated C₁-C₁₀ heterocycloalkyl group, or a fully deuterated phenyl group, in which, in each group, all hydrogen included therein is substituted with deuterium, or ii) a partially deuterated C₁-C₆₀ alkyl group (or, a partially deuterated C₁-C₂₀ alkyl group, or the like), a partially deuterated C₃-C₁₀ cycloalkyl group, a partially deuterated C₁-C₁₀ heterocycloalkyl group, or a partially deuterated phenyl group, in which, in each group, all hydrogen included therein is not substituted with deuterium.

The term “(C₁-C₂₀ alkyl) ‘X’ group” as used herein refers to an ‘X’ group that is substituted with at least one C₁-C₂₀ alkyl group. In one or more embodiments, the term “(C₁-C₂₀ alkyl)C₃-C₁₀ cycloalkyl group” as used herein refers to a C₃-C₁₀ cycloalkyl group that is substituted with at least one C₁-C₂₀ alkyl group, and the term “(C₁-C₂₀ alkyl)phenyl group” as used herein refers to a phenyl group that is substituted with at least one C₁-C₂₀ alkyl group. Non-limiting examples of a (C₁ alkyl)phenyl group is a toluyl group or the like.

The terms “azaindole group”, “azabenzoborole group”, “azabenzophosphole group”, “azaindene group”, “azabenzosilole group”, “azabenzogermole group”, “azabenzothiophene group”, “azabenzoselenophene group”, “azabenzofuran group”, “azacarbazole group”, “azadibenzoborole group”, “azadibenzophosphole group”, “azafluorene group”, “azadibenzosilole group”, “azadibenzogermole group”, “azadibenzothiophene group”, “azadibenzoselenophene group”, “azadibenzofuran group”, “azadibenzothiophene 5-oxide group”, “aza-9H-fluorene-9-one group”, and “azadibenzothiophene 5,5-dioxide group” respectively refer to hetero rings having the same backbones as an “indole group”, a “benzoborole group”, a “benzophosphole group”, an “indene group”, a “benzosilole group”, a “benzogermole group”, a “benzothiophene group”, a “benzoselenophene group”, a “benzofuran group”, a “carbazole group”, a “dibenzoborole group”, a “dibenzophosphole group”, a “fluorene group”, a “dibenzosilole group”, a “dibenzogermole group”, a “dibenzothiophene group”, a “dibenzoselenophene group”, a “dibenzofuran group”, a “dibenzothiophene 5-oxide group”, a “9H-fluorene-9-one group”, and a “dibenzothiophene 5,5-dioxide group”, in which, in each group, at least one of ring-forming carbon atoms is substituted with nitrogen.

Substituents of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may each independently be:
deuterium, —F, —Cl, —Br, —I, —SF₅, —CDs, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —SF₅, —CDs, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or a combination thereof.

Q₁ to Q₉, Q₁₁ to Q₁₉, Q₂₁ to Q₂₉, and Q₃₁ to Q₃₉ used herein may each independently be: hydrogen, deuterium, —F, —Cl, —Br, —I, SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

Hereinafter, a compound and an organic light-emitting device according to one or more embodiments will be described in detail with reference to Synthesis Examples and Examples. However, embodiments are not limited thereto. The wording “B was used instead of A” used in describing Synthesis Examples indicates that an amount of B used was identical to an amount of A used based on molar equivalence.

### EXAMPLES

### Synthesis Example 1 (Compound 1)

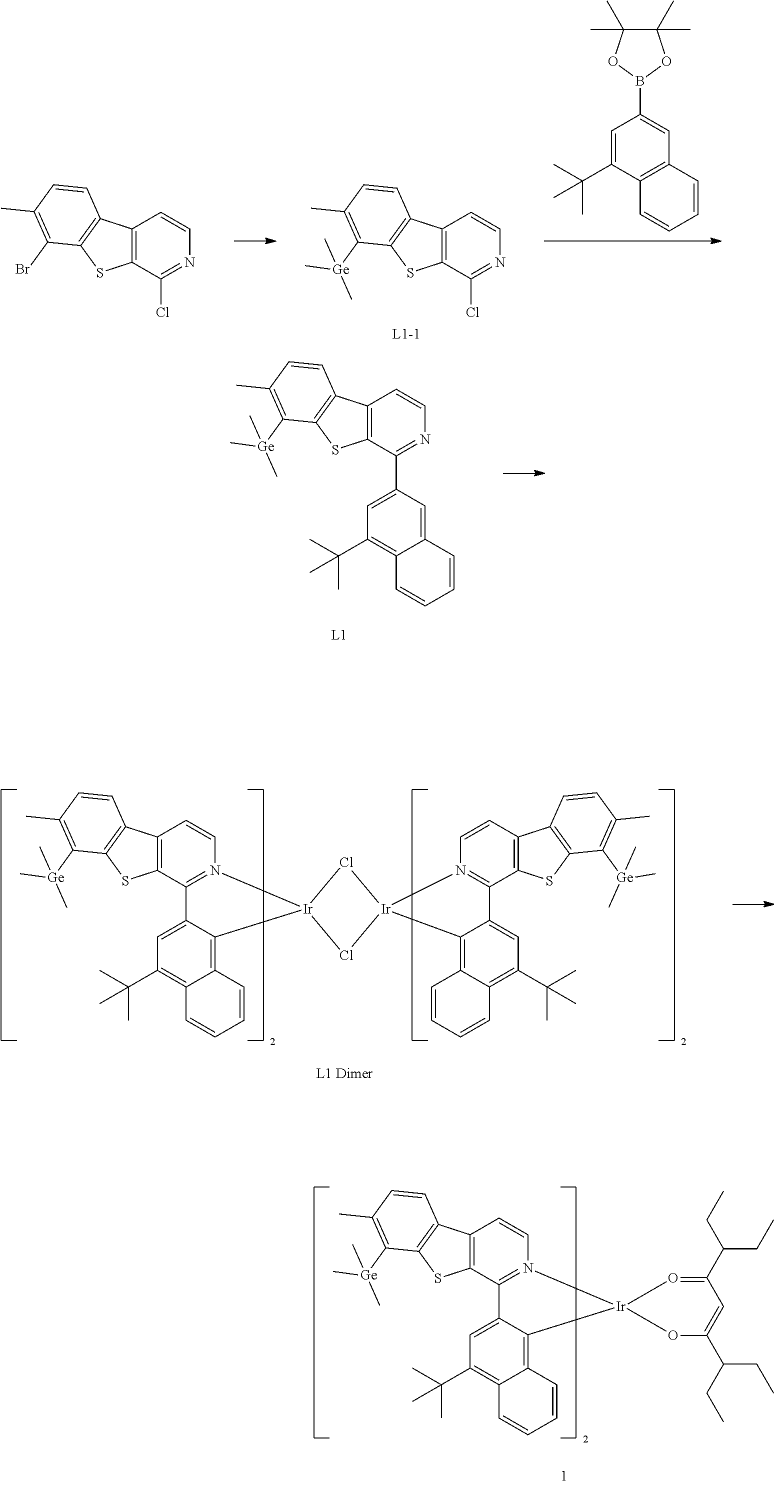

### Synthesis of Intermediate L1-1

2.0 grams (g) (6.4 millimoles (mmol)) of 8-bromo-1-chloro-7-methylbenzo[4,5]thieno[2,3-c]pyridine was dissolved in 60 milliliters (mL) of anhydrous tetrahydrofuran (THF), and then, 4.4 mL (7.1 mmol) of 1.6 M butyl lithium (BuLi) solution in hexane was slowly added thereto at −78° C. After about 30 minutes, 1.0 mL (8.3 mmol) of chlorotrimethylgermane was slowly added dropwise thereto, followed by stirring at room temperature for 4 hours. After completion of the reaction, an organic layer was obtained by extraction with 40 mL of deionized (DI) water and ethyl acetate (EA), the organic layer was dried by using magnesium sulfate, and the solvents were removed under reduced pressure, followed by purification of the product by liquid chromatography, to thereby obtain 1.9 g (yield: 86%) of Intermediate L1-1.

Liquid chromatography-mass spectrometry (LC-MS) m/z=351 (M+H)+.

### Synthesis of Intermediate L1

1.5 g (4.3 mmol) of Intermediate L1-1 was dissolved in 40 mL of THF and 10 mL of DI water, and 1.6 g (5.2 mmol) of 2-(4-(tert-butyl)naphthalen-2-yl)-4,4,5,5-tetramethyl-1,3,2-dioxaborolane, 0.35 g (0.3 mmol) of (tetrakis(triphenylphosphine)palladium(0), Pd(PPh₃)₄), and 1.5 g (10.6 mmol) of K₂CO₃ were added thereto, followed by heating at reflux for one day. After completion of the reaction, an organic layer was obtained by adding ethyl acetate and DI water thereto for extraction, the organic layer was dried by using magnesium sulfate, and the solvent was removed under reduced pressure, followed by purification of the product by liquid chromatography, to thereby obtain 1.7 g (yield: 80%) of Intermediate L1.

LC-MS m/z=499 (M+H)⁺.

### Synthesis of Intermediate L1 Dimer

1.0 g (2.0 mmol) of Intermediate L1 and 0.33 g (0.95 mmol) of iridium chloride trihydrate were mixed with 40 ml of ethoxyethanol and 10 ml of DI water, followed by heating at reflux for 18 hours. When the reaction was completed, the temperature was cooled to room temperature, and a solid material formed therefrom was filtered and washed thoroughly with DI water and then methanol. The solid obtained therefrom was dried in a vacuum oven to obtain 1.0 g of Intermediate L1 Dimer.

### Synthesis of Compound 1

1.0 g (0.41 mmol) of Intermediate L1 Dimer, 0.26 g (1.2 mmol) of 3,7-diethylnonane-4,6-dione, and 0.17 g (1.2 mmol) of K₂CO₃ were mixed with 40 mL of ethoxyethanol, followed by stirring at room temperature for 18 hours. When the reaction was completed, a solid material was formed by adding DI water, the solid was filtered and purified by liquid chromatography, to thereby obtain 0.5 g (yield: 44%) of Compound 1.

LC-MS m/z=1399 (M+H)⁺.

### Synthesis Example 2 (Compound 4)

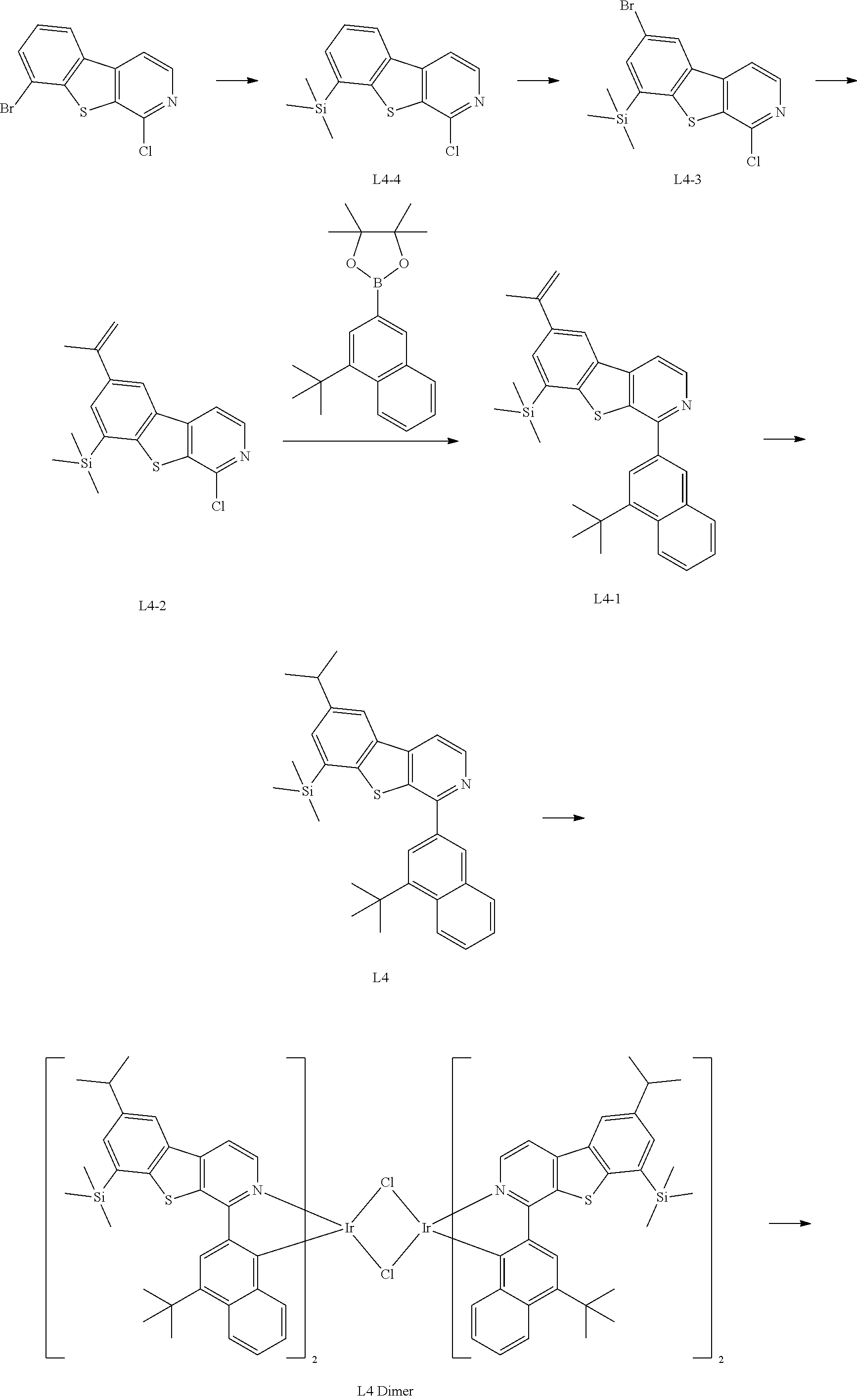

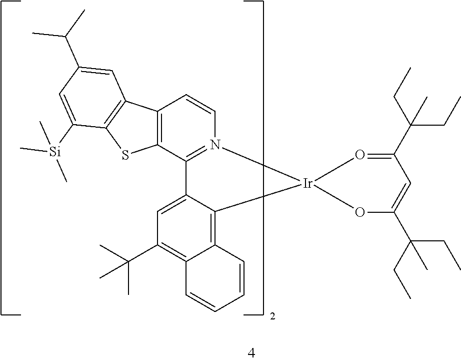

### Synthesis of Intermediate L4-4

2.5 g (yield: 85%) of Intermediate L4-4 was obtained in a similar manner as used to obtain Intermediate L1-1 of Synthesis Example 1, except that 8-bromo-1-chlorobenzo[4,5]thieno[2,3-c]pyridine was used instead of 8-bromo-1-chloro-7-methylbenzo[4,5]thieno[2,3-c]pyridine, and chlorotrimethylsilane was used instead of chlorotrimethylgermane.

LC-MS m/z=292 (M+H)⁺.

### Synthesis of Intermediate L4-3

2.2 g (7.5 mmol) of Intermediate L4-4 was dissolved in 60 mL of dichloromethane, and then 1.6 g (9.0 mmol) of N-bromosuccinimide was slowly added thereto at 0° C., followed by stirring at room temperature for 3 days. After completion of the reaction, an organic layer was obtained by adding DI water for extraction, the organic layer was dried by using magnesium sulfate, and the solvent was removed under reduced pressure, followed by purification of the product by liquid chromatography, to thereby obtain 1.4 g (yield: 50%) of Intermediate L4-3.

LC-MS m/z=371 (M+H)⁺.

### Synthesis of Intermediate L4-2

1.4 g (3.8 mmol) of Intermediate L4-3 was dissolved in 60 mL of THF and 15 mL of DI water, and 0.8 g (4.6 mmol) of 4,4,5,5-tetramethyl-2-(prop-1-en-2-yl)-1,3,2-dioxaborolane, 0.22 g (0.2 mmol) of Pd(PPh₃)₄, and 1.3 g (9.5 mmol) of K₂CO₃ were added thereto, followed by heating at reflux for 18 hours. After completion of the reaction, an organic layer was obtained by adding EA and DI water thereto for extraction, the organic layer was dried by using magnesium sulfate, and the solvent was removed under reduced pressure, followed by purification of the product by liquid chromatography, to thereby obtain 1.1 g (yield: 90%) of Intermediate L4-2.

LC-MS m/z=333 (M+H)⁺.

### Synthesis of Intermediate L4-1

1.2 g (yield: 85%) of Intermediate L4-1 was obtained in a similar manner as used to obtain Intermediate L1 of Synthesis Example 1, except that Intermediate L4-2 was used instead of Intermediate L1-1.

LC-MS m/z=480 (M+H)⁺.

### Synthesis of Intermediate L4

1.2 g (2.5 mmol) of Intermediate L4-1 was mixed with 50 mL of ethanol, 0.2 g (15 wt %) of palladium on carbon (Pd/C) was added thereto, and then hydrogen (H2) was added thereto, followed by stirring at room temperature for 24 hours. After completion of the reaction, the reaction mixture was passed through a celite pad and concentrated under reduced pressure, followed by purification by liquid chromatography, to thereby obtain 0.9 g (yield: 80%) of Intermediate L4.

LC-MS m/z=483 (M+H)⁺.

### Synthesis of Intermediate L4 Dimer

Intermediate L4 Dimer was obtained in a similar manner as used to obtain Intermediate L1 Dimer of Synthesis Example 1, except that Intermediate L4 was used instead of Intermediate L1.

### Synthesis of Compound 4

0.3 g (yield: 42%) of Compound 4 was obtained in a similar manner as used to obtain Compound 1 of Synthesis Example 1, except that Intermediate L4 Dimer was used instead of Intermediate L1 Dimer, and 3,7-diethyl-3,7-dimethylnonane-4,6-dione was used instead of 3,7-diethylnonane-4,6-dione.

LC-MS m/z=1379 (M+H)⁺.

### Synthesis Example 3 (Compound 14)

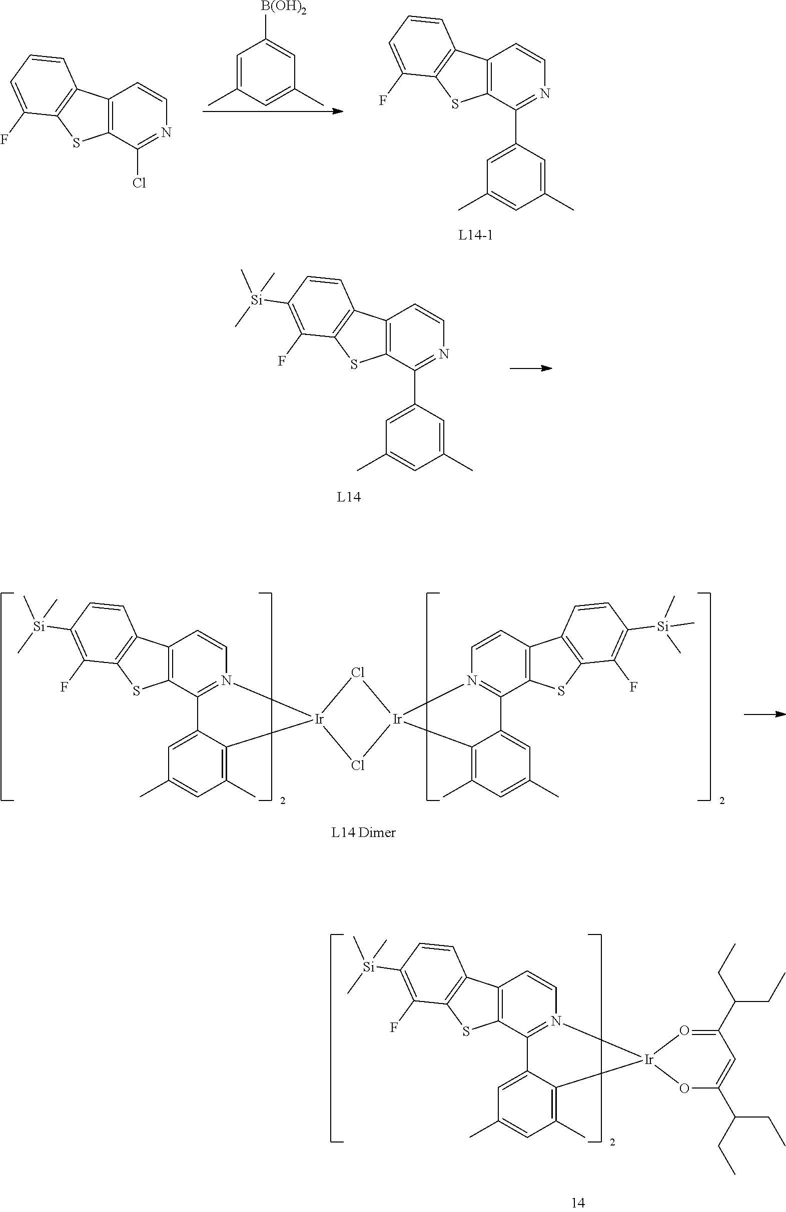

### Synthesis of Intermediate L14-1

1.5 g (6.3 mmol) of 1-chloro-8-fluorobenzo[4,5]thieno[2,3-c]pyridine was dissolved in 60 mL of THF and 15 mL of DI water, and 1.1 g (7.6 mmol) of 3,5-dimethylphenylboronic acid, 0.07 g (0.32 mmol) of palladium(II) acetate (Pd(Oac)₂), 0.25 g (0.64 mmol) of 2-dicyclohexylphosphino-2′,6′-dimethoxybiphenyl (SPhos), and 2.2 g (15.8 mmol) of K₂CO₃ were added thereto, followed by heating at reflux for one day. After completion of the reaction, an organic layer was obtained by adding EA and DI water thereto for extraction, the organic layer was dried by using magnesium sulfate, and the solvent was removed under reduced pressure, followed by purification of the product by liquid chromatography, to thereby obtain 1.5 g (yield: 76%) of Intermediate L14-1.

LC-MS m/z=308 (M+H)⁺.

### Synthesis of Intermediate L14

1.1 g (3.7 mmol) of L14-1 was dissolved in 60 mL of anhydrous THF, and then, 2.4 mL (3.7 mmol) of 1.6 M BuLi solution in hexane was slowly added thereto at −78° C. After about an hour, 0.6 ml (4.5 mmol) of chlorotrimethylsilane was slowly added dropwise thereto, followed by stirring at room temperature for 18 hours. After completion of the reaction, an organic layer obtained by extraction with 50 ml of EA and a saturated sodium thiosulfate aqueous solution, the organic layer was dried by using magnesium sulfate, and the solvent was removed under reduced pressure, followed by purification of the product by liquid chromatography, to thereby obtain 1.0 g (yield: 73%) of Intermediate L14.

LC-MS m/z=380 (M+H)⁺.

### Synthesis of Intermediate L14 Dimer

Intermediate L14 Dimer was obtained in a similar manner as was used to obtain Intermediate L1 Dimer of Synthesis Example 1, except that Intermediate L14 was used instead of Intermediate L1.

### Synthesis of Compound 14

0.4 g (yield: 40%) of Compound 14 was obtained in a similar manner as was used to obtain Compound 1 of Synthesis Example 1, except that Intermediate L14 Dimer was used instead of Intermediate L1 Dimer.

LC-MS m/z=1162 (M+H)⁺.

### Synthesis Example 4 (Compound 6)

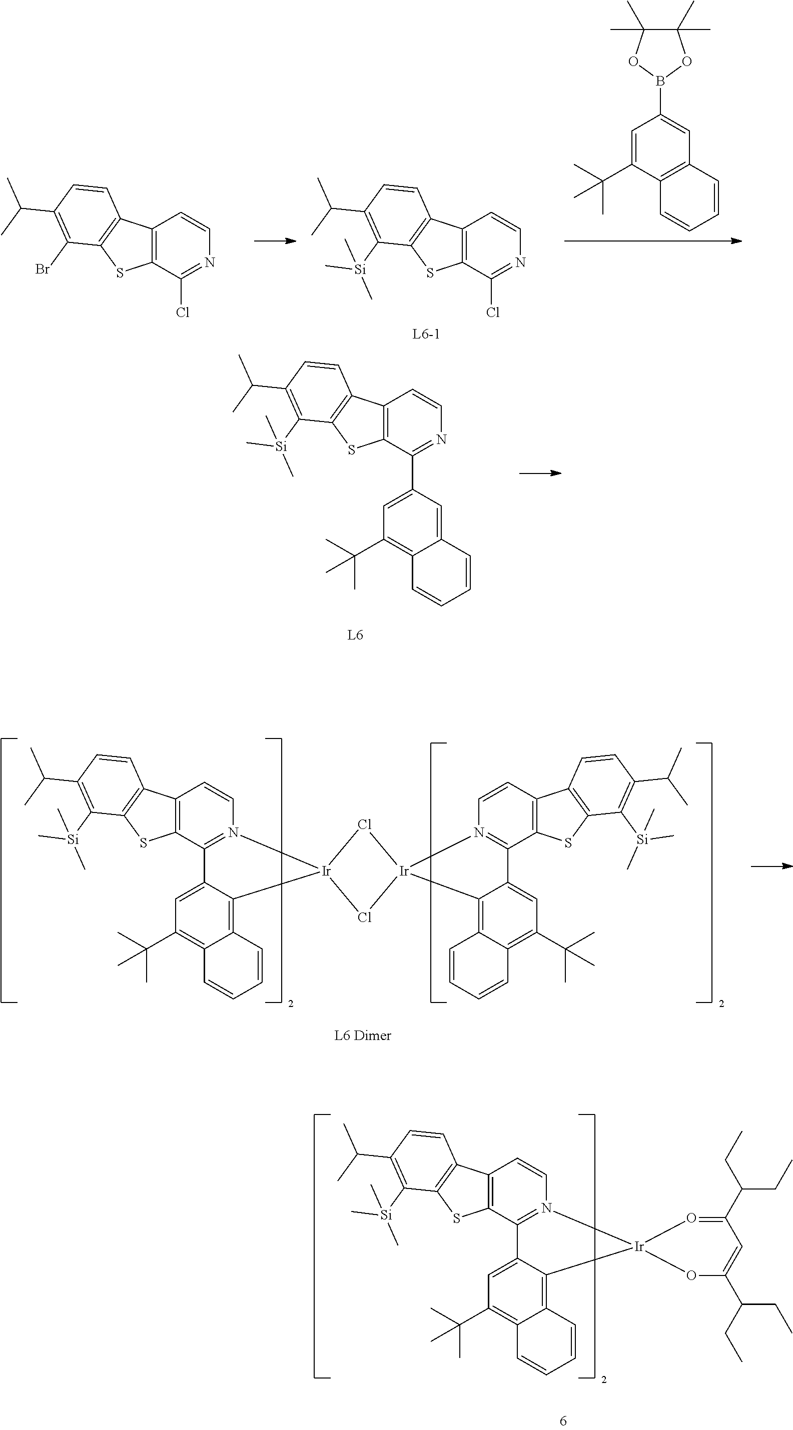

### Synthesis of Intermediate L6-1

1.3 g (yield: 90%) of Intermediate L6-1 was obtained in a similar manner as was used to obtain Intermediate L1-1 of Synthesis Example 1, except that 8-bromo-1-chloro-7-isopropylbenzo[4,5]thieno[2,3-c]pyridine was used instead of 8-bromo-1-chloro-7-methylbenzo[4,5]thieno[2,3-c]pyridine, and chlorotrimethylsilane was used instead of chlorotrimethylgermane.

LC-MS m/z=335 (M+H)⁺.

### Synthesis of Intermediate L6

1.4 g (yield: 75%) of Intermediate L6 was obtained in a similar manner as was used to obtain Intermediate Li of Synthesis Example 1, except that Intermediate L6-1 was used instead of Intermediate L1-1.

LC-MS m/z=483 (M+H)⁺.

### Synthesis of Intermediate L6 Dimer

Intermediate L6 Dimer was obtained in a similar manner as was used to obtain Intermediate Li Dimer of Synthesis Example 1, except that Intermediate L6 was used instead of Intermediate L1.

### Synthesis of Compound 6

0.6 g (yield: 45%) of Compound 6 was obtained in a similar manner as was used to obtain Compound 1 of Synthesis Example 1, except that Intermediate L6 Dimer was used instead of Intermediate L1 Dimer.

LC-MS m/z=1367 (M+H)⁺.

### Synthesis Example 5 (Compound 13)

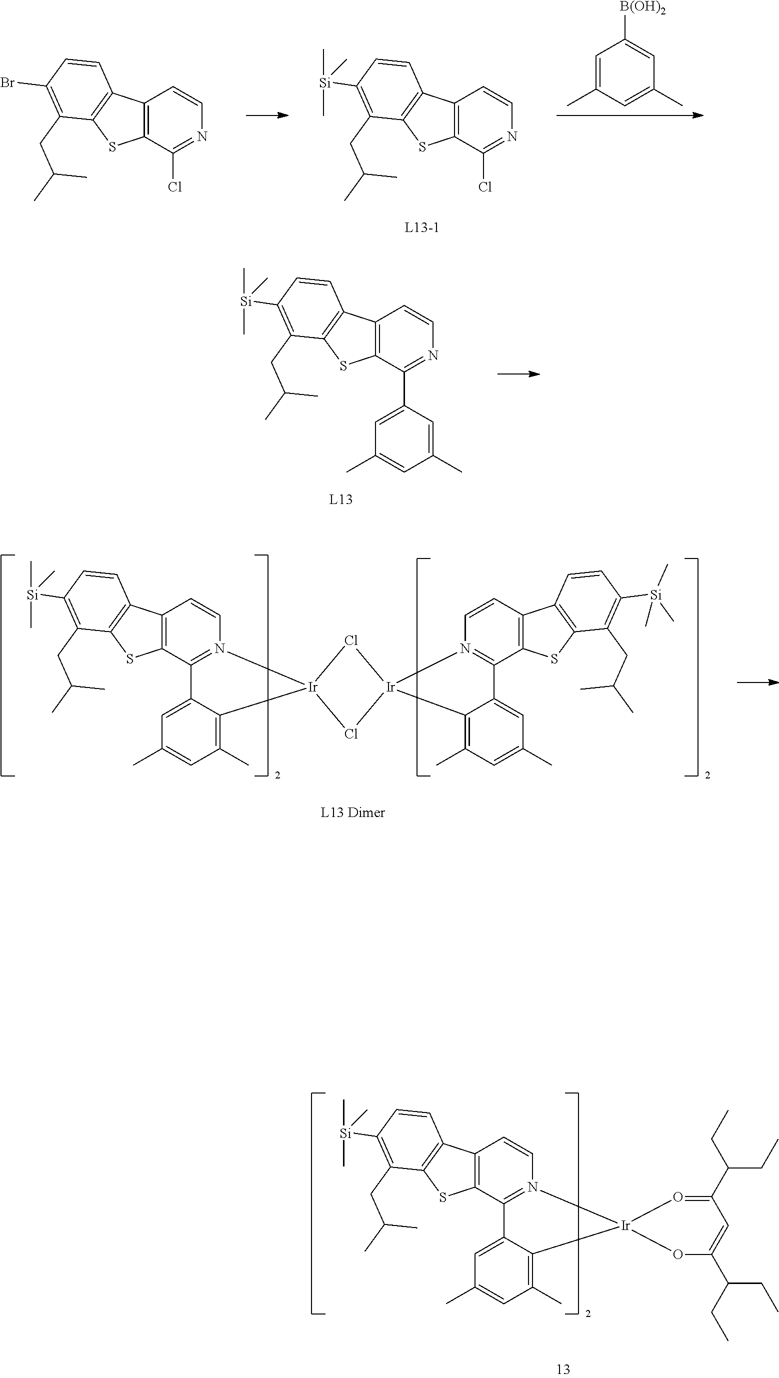

### Synthesis of Intermediate L13-1

0.8 g (yield: 70%) of Intermediate L13-1 was obtained in a similar manner as was used to obtain Intermediate L1-1 of Synthesis Example 1, except that 7-bromo-1-chloro-8-isobutylbenzo[4,5]thieno[2,3-c]pyridine was used instead of 8-bromo-1-chloro-7-methylbenzo[4,5]thieno[2,3-c]pyridine, and chlorotrimethylsilane was used instead of chlorotrimethylgermane.

LC-MS m/z=349 (M+H)⁺.

### Synthesis of Intermediate L13

0.8 g (yield: 80%) of Intermediate L13 was obtained in a similar manner as was used to obtain Intermediate L14-1 of Synthesis Example 3, except that Intermediate L13-1 was used instead of 1-chloro-8-fluorobenzo[4,5]thieno[2,3-c]pyridine.

LC-MS m/z=478 (M+H)⁺.

### Synthesis of Intermediate L13 Dimer

Intermediate L13 Dimer was obtained in a similar manner as used to obtain Intermediate L1 Dimer of Synthesis Example 1, except that Intermediate L13 was used instead of Intermediate L1.

### Synthesis of Compound 13

0.35 g (yield: 45%) of Compound 13 was obtained in a similar manner as was used to obtain Compound 1 of Synthesis Example 1, except that Intermediate L13 Dimer was used instead of Intermediate L1 Dimer.

LC-MS m/z=1238 (M+H)⁺.

### Synthesis Example 6 (Compound 15)

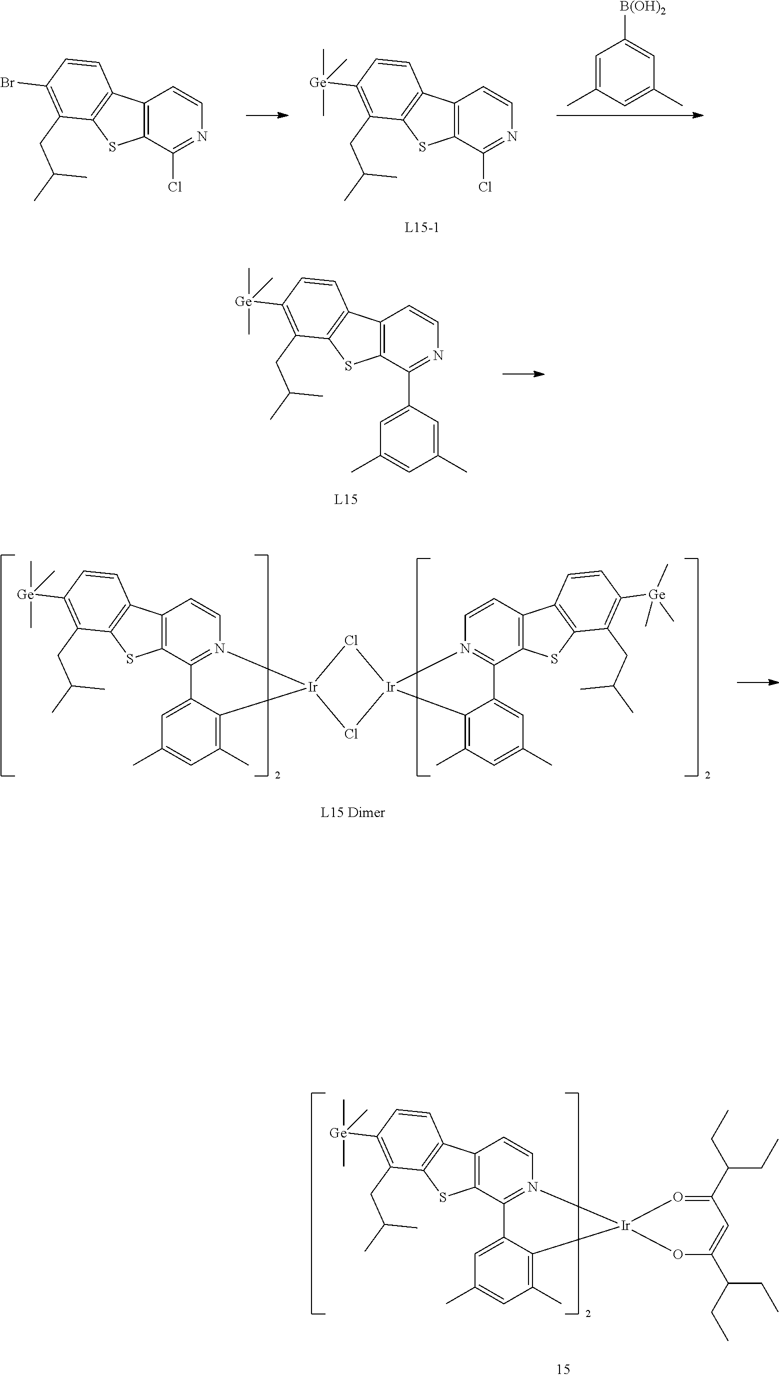

### Synthesis of Intermediate L15-1

1.0 g (yield: 75%) of Intermediate L15-1 was obtained in a similar manner as was used to obtain Intermediate L1-1 of Synthesis Example 1, except that 7-bromo-1-chloro-8-isobutylbenzo[4,5]thieno[2,3-c]pyridine was used instead of 8-bromo-1-chloro-7-methylbenzo[4,5]thieno[2,3-c]pyridine.

LC-MS m/z=393 (M+H)⁺.

### Synthesis of Intermediate L15

0.9 g (yield: 75%) of Intermediate L15 was obtained in a similar manner as was used to obtain Intermediate L14-1 of Synthesis Example 3, except that Intermediate L15-1 was used instead of 1-chloro-8-fluorobenzo[4,5]thieno[2,3-c]pyridine.

LC-MS m/z=463 (M+H)⁺.

### Synthesis of Intermediate L15 Dimer

Intermediate L15 Dimer was obtained in a similar manner as was used to obtain Intermediate L1 Dimer of Synthesis Example 1, except that Intermediate L15 was used instead of Intermediate L1.

### Synthesis of Compound 15

0.4 g (yield: 40%) of Compound 15 was obtained in a similar manner as was used to obtain Compound 1 of Synthesis Example 1, except that Intermediate L15 Dimer was used instead of Intermediate L1 Dimer.

LC-MS m/z=1327 (M+H)⁺.

### Synthesis Example 7 (Compound 16)

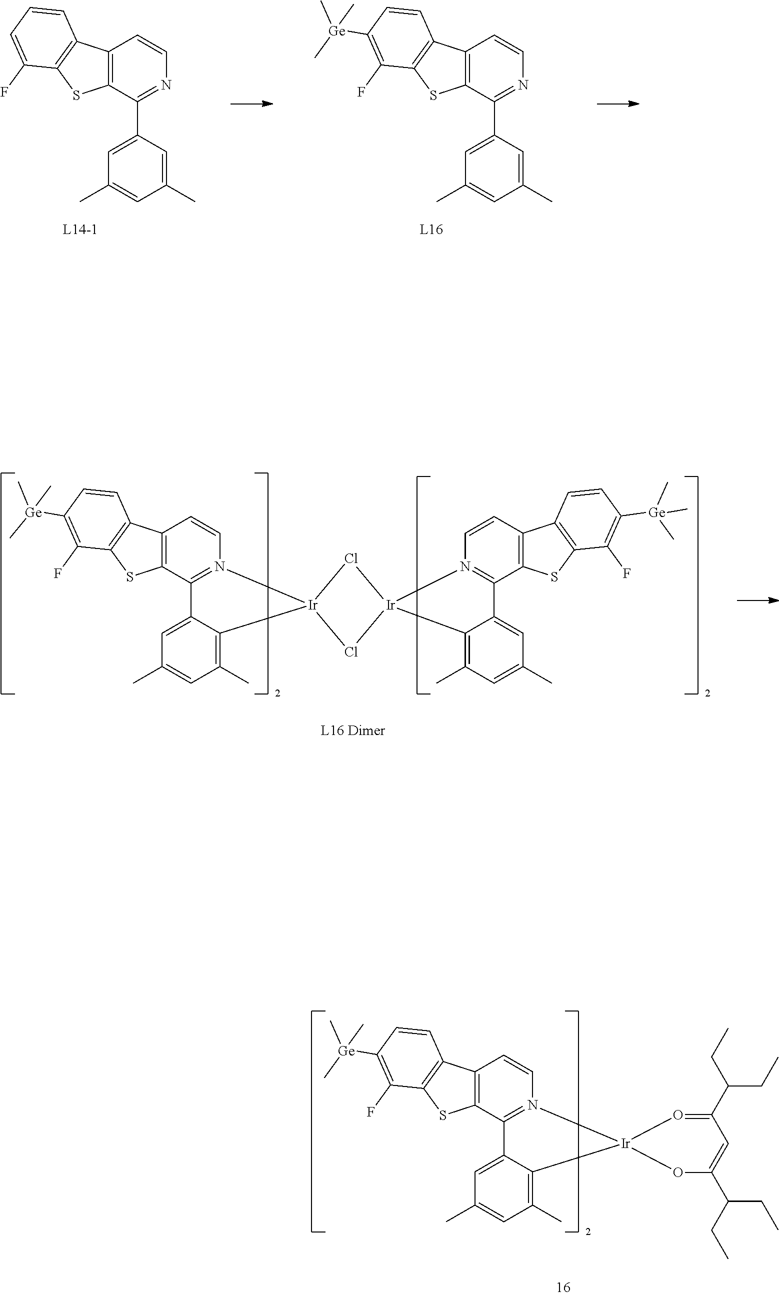

### Synthesis of Intermediate L16

0.8 g (yield: 80%) of Intermediate L16 was obtained in a similar manner as was used to obtain Intermediate L14 of Synthesis Example 3, except that chlorotrimethylgermane was used instead of chlorotrimethylsilane.

LC-MS m/z=425 (M+H)⁺.

### Synthesis of Intermediate L16 Dimer

Intermediate L16 Dimer was obtained in a similar manner as was used to obtain Intermediate L1 Dimer of Synthesis Example 1, except that Intermediate L16 was used instead of Intermediate L1.

### Synthesis of Compound 16

0.5 g (yield: 50%) of Compound 16 was obtained in a similar manner as was used to obtain Compound 1 of Synthesis Example 1, except that Intermediate L16 Dimer was used instead of Intermediate L1 Dimer.

LC-MS m/z=1250 (M+H)⁺.

### Synthesis Example 8 (Compound 17)

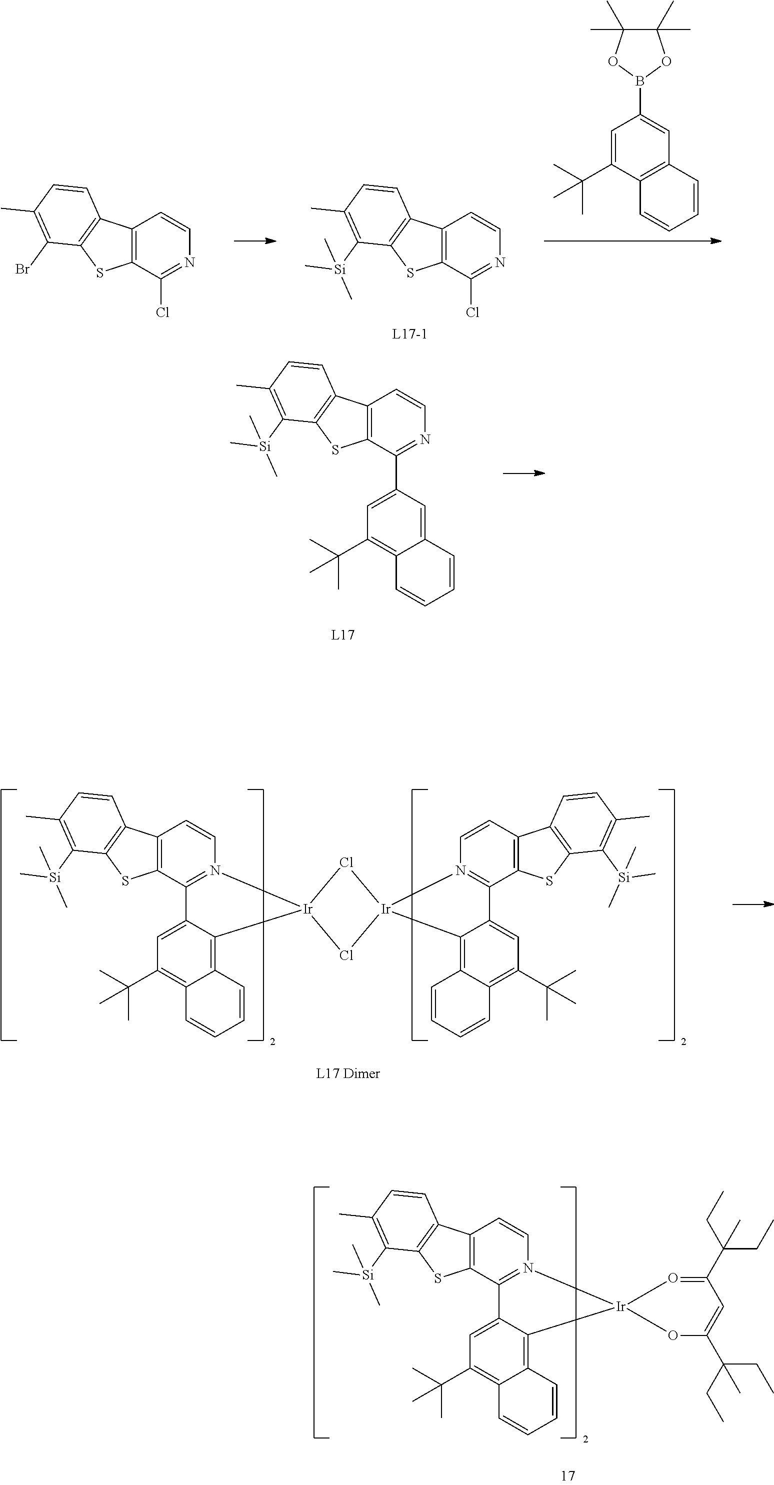

### Synthesis of Intermediate L17-1

1.1 g (yield: 85%) of Intermediate L17-1 was obtained in a similar manner as was used to obtain Intermediate L1-1 of Synthesis Example 1, except that chlorotrimethylsilane was used instead of chlorotrimethylgermane.

LC-MS m/z=306 (M+H)⁺.

### Synthesis of Intermediate L17

1.2 g (yield: 75%) of Intermediate L17 was obtained in a similar manner as was used to obtain Intermediate L1 of Synthesis Example 1, except that Intermediate L17-1 was used instead of Intermediate L1-1.

LC-MS m/z=454 (M+H)⁺.

### Synthesis of Intermediate L17 Dimer

Intermediate L17 Dimer was obtained in a similar manner as was used to obtain Intermediate L1 Dimer of Synthesis Example 1, except that Intermediate L17 was used instead of Intermediate L1.

### Synthesis of Compound 17

0.5 g (yield: 45%) of Compound 17 was obtained in a similar manner as was used to obtain Compound 1 of Synthesis Example 1, except that Intermediate L17 Dimer was used instead of Intermediate L1 Dimer, and 3,7-diethyl-3,7-dimethylnonane-4,6-dione was used instead of 3,7-diethylnonane-4,6-dione.

LC-MS m/z=1337 (M+H)⁺.

### Evaluation Example 1: Evaluation of Photoluminescence Quantum Yield (PLQY)

Compound H52 and Compound 4 were co-deposited at a vacuum pressure of 10⁻⁷ torr at a weight ratio of 98:2 to produce a film having a thickness of 40 nm.

The PLQY in film was evaluated by using a Hamamatsu Photonics absolute PL quantum yield measurement system equipped with a xenon light source, a monochromator, a photonic multichannel analyzer, and an integrating sphere, and using PLQY measurement software (Hamamatsu Photonics, Ltd., Shizuoka, Japan). The results are shown in Table 2.

Films were manufactured in the same way as described above, except that each of Compounds 1, 6, 13 to 17, and A to E was used instead of Compound 4, respectively.

The PLQY measurement was performed on each films, and the results are shown in Table 2.

TABLE 2

| Compound No. | PLQY in film (%) |
|---|---|
| 4 | 94 |
| 1 | 95 |
| 6 | 95 |
| 17 | 95 |
| 13 | 92 |
| 14 | 93 |
| 15 | 92 |
| 16 | 94 |
| A | 88 |
| B | 86 |
| C | 87 |
| D | 88 |
| E | 89 |

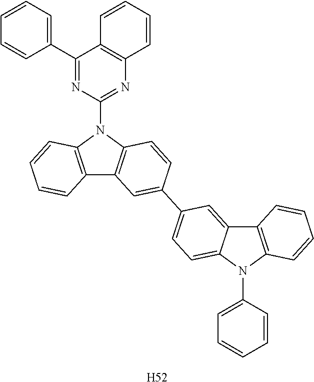 [SMILES: c1ccc(-c2nc(-n3c4ccccc4c4cc(-c5ccc6c(c5)c5ccccc5n6-c5ccccc5)ccc43)nc3ccccc23)cc1 ; "H52"]

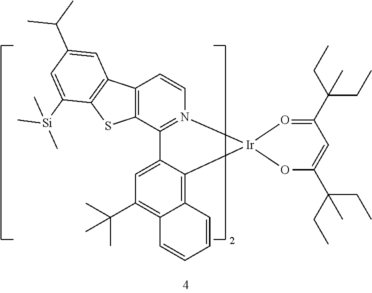

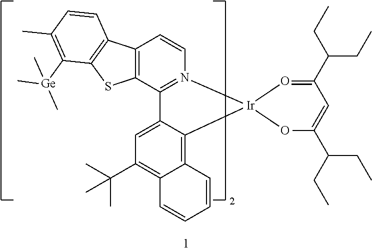

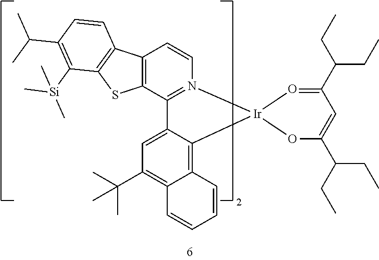

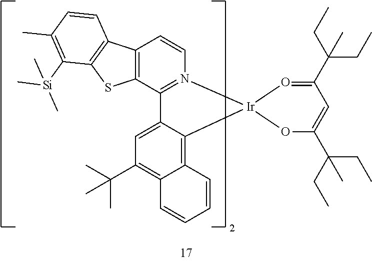

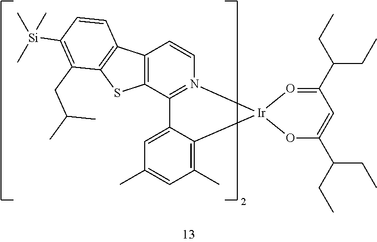

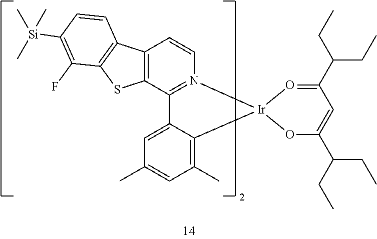

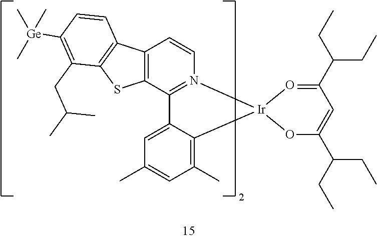

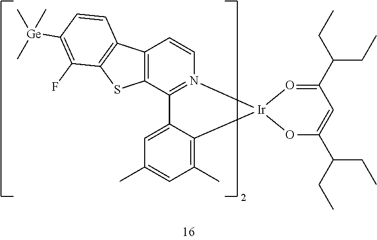

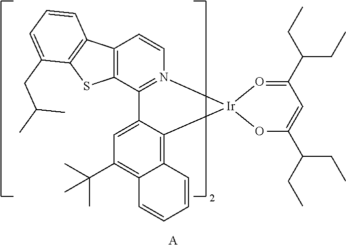

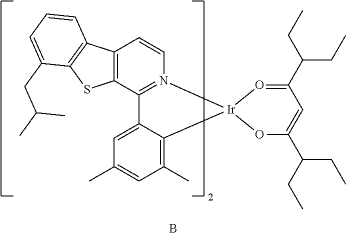

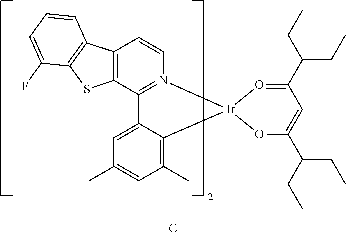

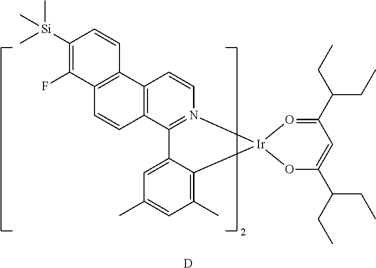

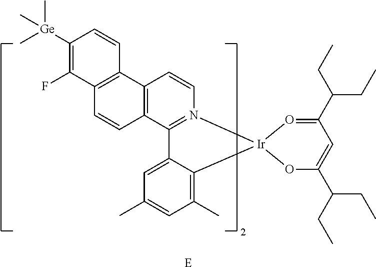

Referring to Table 2, it was confirmed that Compounds 4, 1, 6, and 13 to 17 had excellent PLQY characteristics compared to those of Compounds A to E.

Evaluation Example 2: Evaluation of horizontal orientation ratio (optical orientation ratio)

In a vacuum deposition apparatus having a vacuum pressure of 1×10⁻⁷ torr, Compound H52 and Compound 4 were co-deposited at a weight ratio of 98:2 on a fused silica layer (thickness: 1 mm) to form a film having a thickness of 40 nm, and then the film was sealed with glass and glue under a nitrogen atmosphere.

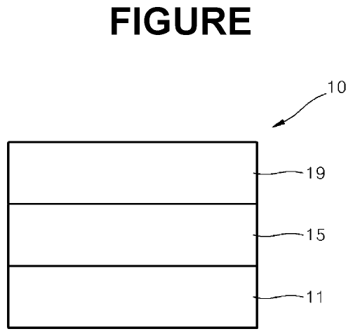

Meanwhile, an angle-dependent photoluminescence (PL) measurement apparatus having the same structure as that shown in FIG. 3 of Korean Patent Application Publication No. 2013-0150834 was prepared. Detailed specifications are as follows:
Excitation-light wavelength: 325 nm
Source of excitation-light: He—Cd laser of Melles Griot Inc.
Excitation-light irradiation member: optical fiber having a diameter of 1 mm of Thorlabs Inc.
Semi-cylindrical prism: a fused silica having a diameter of 100 mm and a length of 30 mm
Emitted-light detection member: photomultiplier tube of Acton Inc.
Polarizer mounted on emitted-light detection member: linear polarizer of Thorlabs Inc.
Recoder: SpectraSense of Acton Inc.
Incidence angle of excitation light: θP=45°, θH=0°
Distance from a sample to the emitted-light detection member (or a radius of a movement path of the emitted-light detection member): 900 mm

Subsequently, the film was fixed on a semi-cylindrical lens and irradiated with 325 nm laser to emit light. The emitted light passed through a polarization film, and then, in order to measure a p-polarized photoluminescence intensity with respect to light at a Max wavelength of a spectrum in a range of 90 degrees to 0 degree, the semi-cylindrical lens, on which the sample was fixed, was gradually rotated by 1 degree with respect to an axis of the semi-cylindrical lens by using a charge-coupled device (CCD).

The p-polarized photoluminescence intensity (a first p-polarized photoluminescence intensity) in a case where each compound is vertically aligned and the p-polarized photoluminescence intensity (a second p-polarized photoluminescence intensity) in a case where each compound is horizontally aligned were respectively calculated within a range of 0 degree to 90 degrees. The p-polarized photoluminescence intensity obtained by multiplying the first p-polarized photoluminescence intensity and the second p-polarized photoluminescence intensity respectively by a weight value was obtained to obtain a weight value corresponding to the measured p-polarization photoluminescence intensity. Then, the horizontal orientation ratio of each compound shown in Table 2 was measured and results thereof are shown in Table 2. In this case, the angle-dependent photoluminescence spectrum was analyzed by using a classical dipole model, in which the emission from excitons is regarded as dissipated power consumed from an oscillating dipole, to evaluate a horizontal orientation ratio with respect to Compound 4.

This was performed on each of Compounds 1, 6, 13 to 17, and A to E, and the result are shown in Table 3.

TABLE 3

| | Horizontal orientation ratio |
|---|---|
| Co-deposition material | (optical orientation ratio) (%) |
| H52:Compound 4 (2 wt %) | 93 |
| H52:Compound 1 (2 wt %) | 92 |
| H52:Compound 6 (2 wt %) | 94 |
| H52:Compound 17 (2 wt %) | 93 |
| H52:Compound 13 (2 wt %) | 92 |
| H52:Compound 14 (2 wt %) | 93 |
| H52:Compound 15 (2 wt %) | 92 |
| H52:Compound 16 (2 wt %) | 93 |
| H52:Compound A (2 wt %) | 89 |
| H52:Compound B (2 wt %) | 90 |
| H52:Compound C (2 wt %) | 90 |
| H52:Compound D (2 wt %) | 91 |
| H52:Compound E (2 wt %) | 91 |

Referring to Table 3, it was confirmed that Compounds 4, 1, 6, and 13 to 17 had excellent horizontal orientation ratios compared to those of Compounds A to E.

### Evaluation Example 3: Evaluation of Thermal Characteristics

Thermal analysis (N2 atmosphere, temperature span: room temperature to 800° C. (10° C./min) thermogravimetric analysis (TGA), room temperature to 400° C. differential scanning calorimetry (DSC), pan type: Pt pan in disposable A1 pan (TGA), disposable A1 pan (DSC)) was performed on Compounds 4, 1, 6, 17, and A by using TGA and DSC, and the results are shown in Table 4.

TABLE 4

| Compound No. | Ts_10% (° C.) |
|---|---|
| 4 | 280 |
| 1 | 290 |
| 6 | 291 |
| 17 | 293 |
| A | 300 |

Ts_10%: a temperature at which a compound loses 10% of its weight.

Referring to Table 4, Compounds 4, 1, 6, and 17 had relatively lower sublimation temperature than that of Compound A, and thus, may be used to manufacture a thin-film having excellent performance.

### Example 1

As an anode, a glass substrate with ITO/Ag/ITO formed thereon to a thickness of 70 Å/1,000 Å/70 Å was cut to a size of 50 millimeters (mm)×50 mm×0.5 mm, sonicated with isopropyl alcohol and DI water each for 5 minutes, and then cleaned by irradiation of ultraviolet rays and exposure of ozone thereto for 30 minutes. Then the resultant glass substrate was loaded onto a vacuum deposition apparatus.

2-TNATA was vacuum-deposited on the anode to form a hole injection layer having a thickness of 600 Å, and 4,4′-bis[N-(1-naphthyl)-N-phenylamino]biphenyl (NPB) was vacuum-deposited on the hole injection layer to form a hole transport layer having a thickness of 1,350 Å.

Next, a host (CBP) and a dopant (Compound 4) were co-deposited on the hole transport layer at a weight ratio of 98:2 to form an emission layer having a thickness of 400 Å.

BCP was vacuum-deposited on the emission layer to form a hole blocking layer having a thickness of 50 Å, Alq3 was vacuum-deposited on the hole blocking layer to form an electron transport layer having a thickness of 350 Å, LiF was vacuum-deposited on the electron transport layer to form an electron injection layer having a thickness of 10 Å, and Mg and Ag were co-deposited thereon at a weight ratio of 90:10 to form a cathode having a thickness of 120 Å, thereby completing the manufacture of an organic light-emitting device.

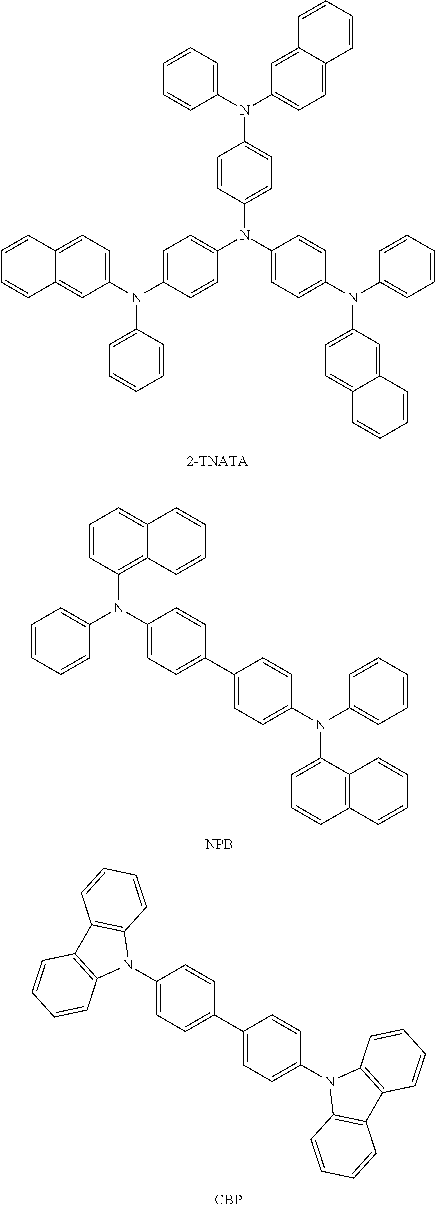 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; c1ccc2c(c1)c1ccccc1n2-c1ccc(-c2ccc(-n3c4ccccc4c4ccccc43)cc2)cc1 ; "CBP"]

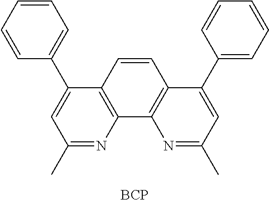

### Examples 2 to 4 and Comparative Example A

Organic light-emitting devices were manufactured in a similar manner as was used in Example 1, except that in forming an emission layer, for use as a dopant, corresponding compounds shown in Table 5 were used instead of Compound 4.

### Evaluation Example 4: Evaluation of Device Characteristics

The driving voltage (volts, V), current density (milliampere per square centimeter, mA/cm²), maximum value of external quantum efficiency (Max EQE, %), FWHM (nm) of an emission peak of an EL spectrum, maximum emission wavelength (nm), and lifespan (LT₉₇, relative %) of each of the organic light-emitting devices manufactured according to Examples 1 to 4 and Comparative Example A were evaluated. The results are shown in Table 5. As an evaluation device, a current-voltmeter (Keithley 2400) and a luminance meter (Minolta Cs-1000A) were used, and the lifespan (LT₉₇) (at 3,500 candela per square meter, cd/m²) was evaluated as the time taken for luminance to reduce to 97% relative to 100% of the initial luminance.

TABLE 5

| | Compound | | | Max | | | |
|---|---|---|---|---|---|---|---|
| | No. as a | | | EQE | | Maximum | LT₉₇ |
| | dopant in | Driving | Current | (relative | | emission | (relative |
| | emission | voltage | density | value, | FWHM | wavelength | value, |
| | layer | (V) | (mA/cm²) | %) | (nm) | (nm) | %) |
| Example 1 | 4 | 4.0 | 10 | 28 | 34 | 623 | 160 |
| Example 2 | 1 | 4.0 | 10 | 28 | 34 | 622 | 180 |
| Example 3 | 6 | 4.0 | 10 | 29 | 34 | 621 | 200 |
| Example 4 | 17 | 4.0 | 10 | 28 | 33 | 620 | 200 |
| Comparative | A | 4.3 | 10 | 25 | 35 | 626 | 100 |
| Example A | | | | | | | |

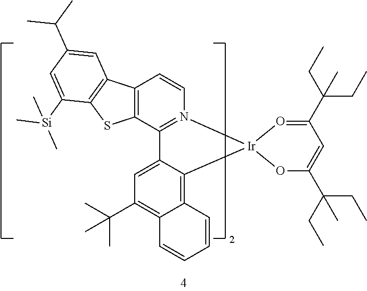

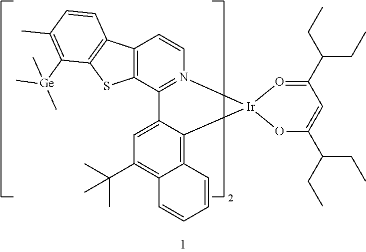

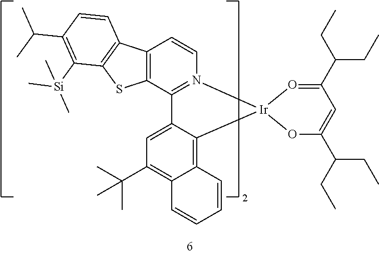

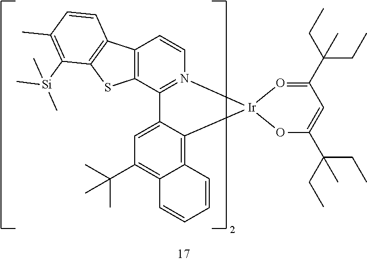

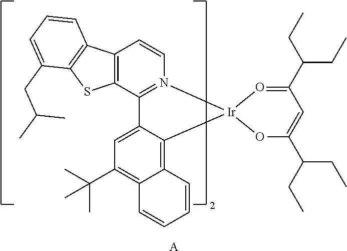

From Table 5, it was confirmed that the organic light-emitting devices of Examples 1 to 4 have improved driving voltage, improved external quantum efficiency, and improved lifespan characteristics, as compared to the organic light-emitting device of Comparative Example A, and may emit light having a relatively small FWHM.

### Examples 5 to 8 and Comparative Examples B to C

Organic light-emitting devices were manufactured in a similar manner as was used in Example 1, except that in forming an emission layer, for use as a dopant, corresponding compounds shown in Table 6 were used instead of Compound 4.

### Evaluation Example 5: Evaluation of Device Characteristics

The driving voltage (V), current density (mA/cm²), maximum value of external quantum efficiency (Max EQE, %), FWHM (nm) of an emission peak of an EL spectrum, maximum emission wavelength (nm), and lifespan (LT₉₇, relative %) of each of the organic light-emitting devices manufactured according to Examples 5 to 8 and Comparative Examples B and C were evaluated as described in Evaluation Example 4. The results are shown in Table 6.

TABLE 6

| | Compound | | | Max | | | |
|---|---|---|---|---|---|---|---|
| | No. as a | | | EQE | | Maximum | LT₉₇ |
| | dopant in | Driving | Current | (relative | | emission | (relative |
| | emission | voltage | density | value, | FWHM | wavelength | value, |
| | layer | (V) | (mA/cm²) | %) | (nm) | (nm) | %) |
| Example 5 | 13 | 4.4 | 10 | 25 | 51 | 602 | 130 |
| Example 6 | 14 | 4.2 | 10 | 26 | 52 | 611 | 110 |
| Example 7 | 15 | 4.3 | 10 | 26 | 49 | 603 | 110 |
| Example 8 | 16 | 4.2 | 10 | 26 | 51 | 611 | 140 |
| Comparative | B | 4.6 | 10 | 22 | 56 | 601 | 80 |
| Example B | | | | | | | |
| Comparative | C | 4.4 | 10 | 24 | 54 | 613 | 90 |
| Example C | | | | | | | |

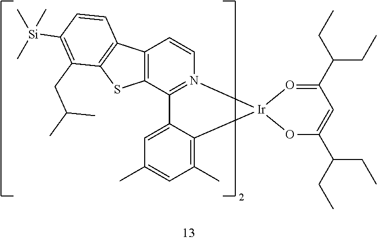

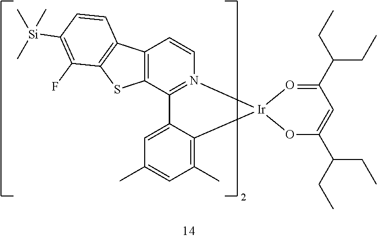

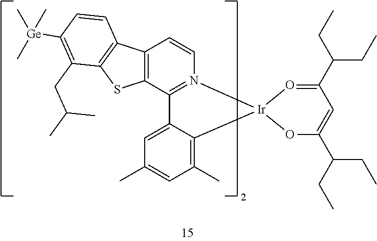

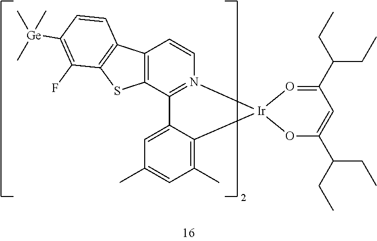

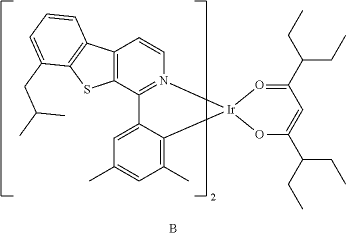

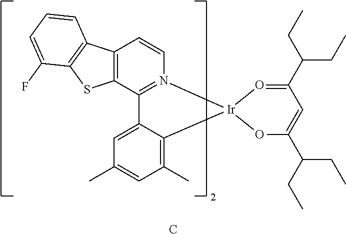

From Table 6, it was confirmed that the organic light-emitting devices of Examples 5 to 8 have improved driving voltage, improved external quantum efficiency, and improved lifespan characteristics, as compared to the organic light-emitting devices of Comparative Examples B and C, and may emit light having a relatively small FWHM.

The organometallic compounds have excellent thermal stability and electrical characteristics. Accordingly, an electronic device, for example, a light-emitting device, including the organometallic compound may have improved driving voltage, improved external quantum efficiency, and improved lifespan characteristics and may emit light having a relatively small FWHM.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments. While one or more exemplary embodiments have been described with reference to the FIGURE, it will be understood by those of ordinary skill in the art that various changes in form and details may be made therein without departing from the spirit and scope as defined by the following claims.

What is claimed is:

1. An organometallic compound represented by Formula 1: 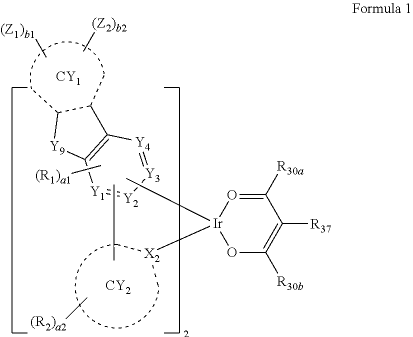
wherein, in Formula 1,
Y₁ to Y₄ are each independently C or N,
one of Y₁ to Y₄ is N bonded to Ir in Formula 1, and one of the remaining Y₁ to Y₄ is C bonded to ring CY₂ in Formula 1,
Y₉ is O, S, N(R₁₉), C(R₁₉ₐ)(R_{19b}), or Si(R₁₉ₐ)(R_{19b}),
X₂ is C,
ring CY₁ and ring CY₂ are each independently a C₅-C₃₀ carbocyclic group or a C₁-C₃₀ heterocyclic group,
Z₁ is a group represented by —Si(Q₃)(Q₄)(Q₅) or a group represented by —Ge(Q₃)(Q₄)(Q₅),
R₁, R₁₉, R₁₉ₐ, R_{19b}, R₂, R₃₀ₐ, R_{30b}, R₃₇, and Z₂ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —B(Q₆)(Q₇), —P(═O)(Q₈)(Q₉), or —P(Q₈)(Q₉),
with the provisos that i) at least one of Z₂ is not hydrogen, and ii) at least one of R₃₀ₐ and R_{30b} is not a methyl group,
a1 is an integer from 0 to 2,
a2 is an integer from 0 to 20,
b1 and b2 are each independently an integer from 1 to 10,
two R₁ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of a plurality of R₂ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of R₃₀ₐ, R_{30b}, and R₃₇ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
R₁₀ₐ is as described in connection with R₁,
substituents of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group are each independently:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₀ alkoxy group, or a C₁-C₆₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and
Q₁ to Q₉, Q₁₁ to Q₁₉, Q₂₁ to Q₂₉, and Q₃₁ to Q₃₉ are each independently: hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group; or a substituted or unsubstituted monovalent non-aromatic condensed heteropolycyclic group.

2. The organometallic compound of claim 1, wherein
ring CY₁ and ring CY₂ are each independently i) a first ring, ii) a second ring, iii) a condensed ring in which two or more first rings are condensed with each other, iv) a condensed ring in which two or more second rings are condensed with each other, or v) a condensed ring in which one or more first rings and one or more second rings are condensed with each other,
the first ring is a cyclopentane group, a cyclopentene group, a furan group, a thiophene group, a pyrrole group, a silole group, a germole group, a borole group, a selenophene group, a phosphole group, an oxazole group, an oxadiazole group, an oxatriazole group, a thiazole group, a thiadiazole group, a thiatriazole group, a pyrazole group, an imidazole group, a triazole group, a tetrazole group, an azasilole group, an azagermole group, an azaborole group, an azaselenophene group, or an azaphosphole group, and
the second ring is an adamantane group, a norbornane group, a norbornene group, a bicyclo[1.1.1]pentane group, a bicyclo[2.1.1]hexane group, a bicyclo[2.2.2]octane group, a cyclohexane group, a cyclohexene group, a benzene group, a pyridine group, a pyrimidine group, a pyrazine group, a pyridazine group, or a triazine group.

3. The organometallic compound of claim 1, wherein ring CY₁ and ring CY₂ are each independently a benzene group, a naphthalene group, a phenanthrene group, a pyridine group, a pyrimidine group, a pyrazine group, a pyridazine group, a quinoline group, an isoquinoline group, a quinoxaline group, a benzoquinoline group, a benzoisoquinoline group, a benzoquinoxaline group, a benzofuran group, or a benzothiophene group.

4. The organometallic compound of claim 1, wherein at least one of Z₂ in the number of b2 comprises at least one carbon atom.

5. The organometallic compound of claim 1, wherein all of Z₂ in the number of b2 do not comprise —F.

6. The organometallic compound of claim 1, wherein Z₂ comprises:
—F;
a C₁-C₂₀ alkyl group that is unsubstituted or substituted with at least one of deuterium, —F, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, or a combination thereof; or
a C₃-C₁₀ cycloalkyl group that is unsubstituted or substituted with at least one of deuterium, —F, a C₁-C₂₀ alkyl group, a deuterated C₁-C₂₀ alkyl group, a fluorinated C₁-C₂₀ alkyl group, a C₁-C₂₀ alkoxy group, a C₁-C₂₀ alkylthio group, or a combination thereof.

7. The organometallic compound of claim 1, wherein one of Condition 1 to Condition 4 is satisfied:
Condition 1
Z₁ is a group represented by —Si(Q₃)(Q₄)(Q₅), and at least one of Z₂(s) in the number of b2 comprises at least one carbon atom;
Condition 2
Z₁ is a group represented by —Ge(Q₃)(Q₄)(Q₅), and at least one of Z₂(s) in the number of b2 comprises at least one carbon atom;
Condition 3
Z₁ is a group represented by —Si(Q₃)(Q₄)(Q₅), and at least one of Z₂(s) in the number of b2 are —F;
Condition 4
Z₁ is a group represented by —Ge(Q₃)(Q₄)(Q₅), and at least one of Z₂(s) in the number of b2 are —F.

8. The organometallic compound of claim 1, wherein one of Condition A1 to Condition A6 is satisfied:
Condition A1
R₃₀ₐ in Formula 1 is a group represented by *—C(R₃₁)(R₃₂)(R₃₃), and
each of R₃₁ to R₃₃ comprises one or more carbon atoms;
Condition A2
R₃₀ₐ in Formula 1 is a group represented by *—C(R₃₁)(R₃₂)(R₃₃),
each of R₃₁ and R₃₃ comprises one or more carbon atoms, and
R₃₂ is hydrogen, deuterium, or —F;
Condition A3
R₃₀ₐ in Formula 1 is a group represented by *—C(R₃₁)(R₃₂)(R₃₃), and
each of R₃₁ to R₃₃ comprises one or more carbon atoms, wherein at least one of R₃₁ to R₃₃ comprises two or more carbon atoms;
Condition A4
R₃₀ₐ in Formula 1 is a group represented by *—C(R₃₁)(R₃₂)(R₃₃),
each of R₃₁ and R₃₃ comprises one or more carbon atoms, wherein at least one of R₃₁ and R₃₃ comprises two or more carbon atoms, and
R₃₂ is hydrogen, deuterium, or —F;
Condition A5
R₃₀ₐ in Formula 1 is a group represented by *—C(R₃₁)(R₃₂)(R₃₃), and
R₃₁ to R₃₃ are each independently hydrogen, deuterium, or —F, wherein at least one of R₃₁ to R₃₃ is deuterium or —F;
Condition A6
R₃₀ₐ in Formula 1 is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆a alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₁-C₆a heteroaryloxy group, a substituted or unsubstituted C₁-C₆a heteroarylthio group, a substituted or unsubstituted monovalent non-aromatic condensed polycyclic group, or a substituted or unsubstituted monovalent non-aromatic condensed heteropolycyclic group.

9. The organometallic compound of claim 1, wherein one of Condition B1 to Condition B6 is satisfied:
Condition B1
R_{30b} in Formula 1 is a group represented by *—C(R₃₄)(R₃₅)(R₃₆), and
each of R₃₄ to R₃₆ comprises one or more carbon atoms;
Condition B2
R_{30b} in Formula 1 is a group represented by *—C(R₃₄)(R₃₅)(R₃₆),
each of R₃₄ and R₃₆ comprises one or more carbon atoms, and
R₃₅ is hydrogen, deuterium, or —F;
Condition B3
R_{30b} in Formula 1 is a group represented by *—C(R₃₄)(R₃₅)(R₃₆), and
each of R₃₄ to R₃₆ comprises one or more carbon atoms, wherein at least one of R₃₄ to R₃₆ comprises two or more carbon atoms;
Condition B4
R_{30b} in Formula 1 is a group represented by *—C(R₃₄)(R₃₅)(R₃₆),
each of R₃₄ and R₃₆ comprises one or more carbon atoms, wherein at least one of R₃₄ and R₃₆ comprises two or more carbon atoms, and
R₃₅ is hydrogen, deuterium, or —F;
Condition B5
R_{30b} in Formula 1 is a group represented by *—C(R₃₄)(R₃₅)(R₃₆), and
R₃₄ to R₃₆ are each independently hydrogen, deuterium, or —F, wherein at least one of R₃₄ to R₃₆ is deuterium or —F;
Condition B6
R_{30b} in Formula 1 is a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

10. The organometallic compound of claim 1, wherein a group represented by 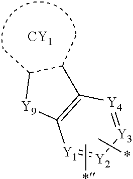
in Formula 1 is a group represented by one of Formulae CY1(1) to CY1(6): 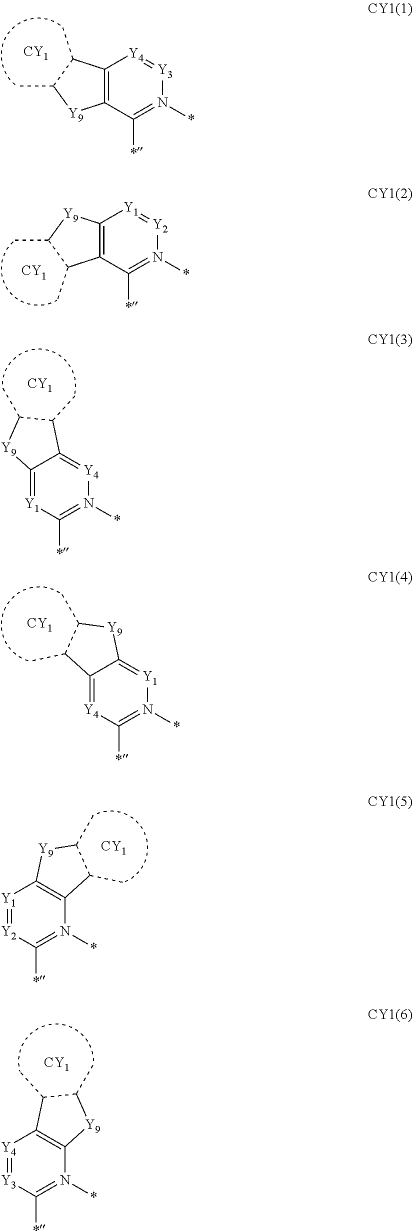
wherein, in Formulae CY1(1) to CY1(6),
Y₉ and ring CY₁ are each independently as described in claim 1,
Y₁ to Y₄ are each independently C or N,
* indicates a binding site to iridium in Formula 1, and
*″ indicates a binding site to ring CY₂ in Formula 1.

11. The organometallic compound of claim 1, wherein a group represented by 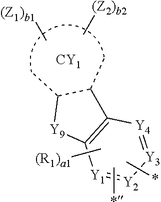
in Formula 1 is a group represented by one of Formulae CY1-1 to CY1-28: 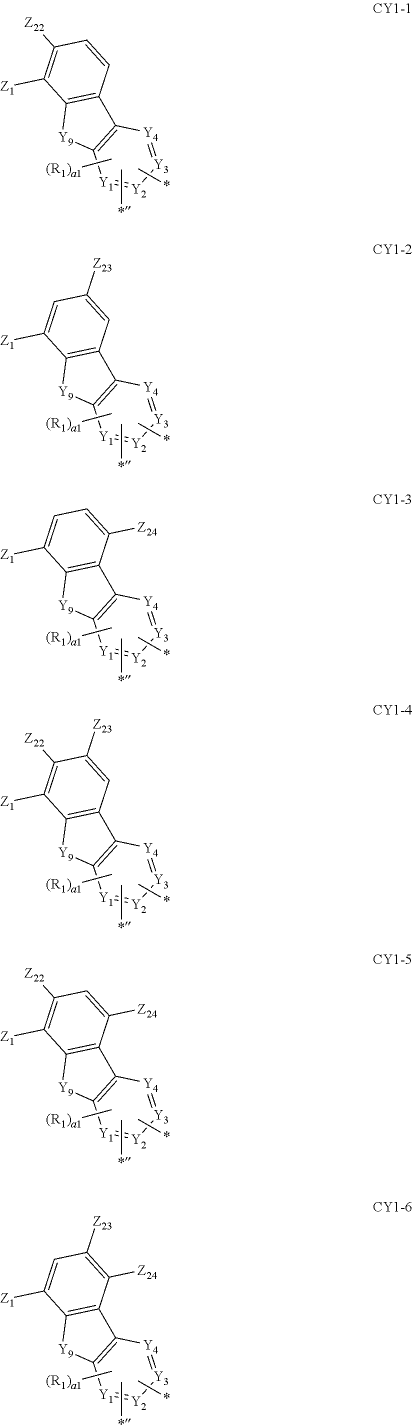 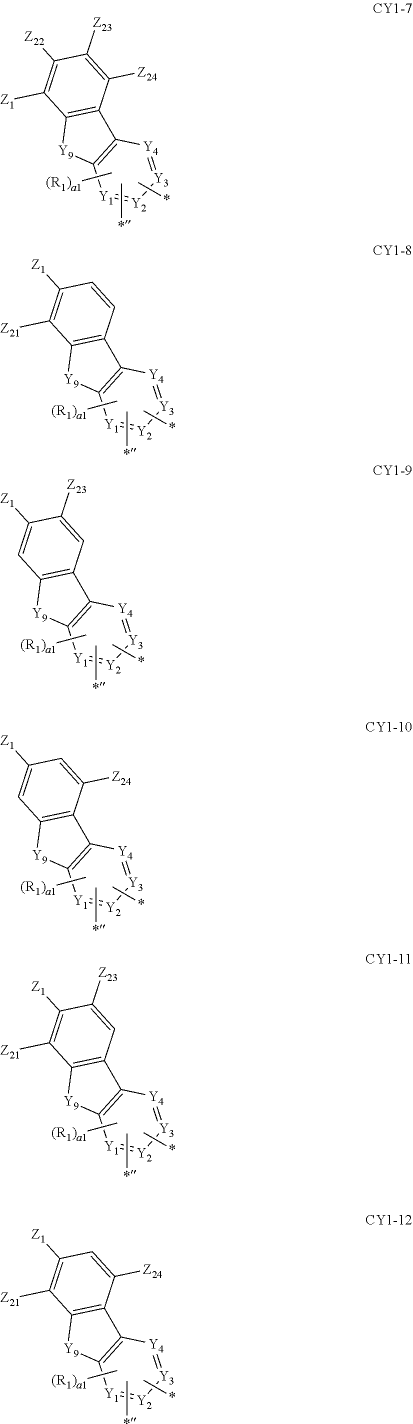 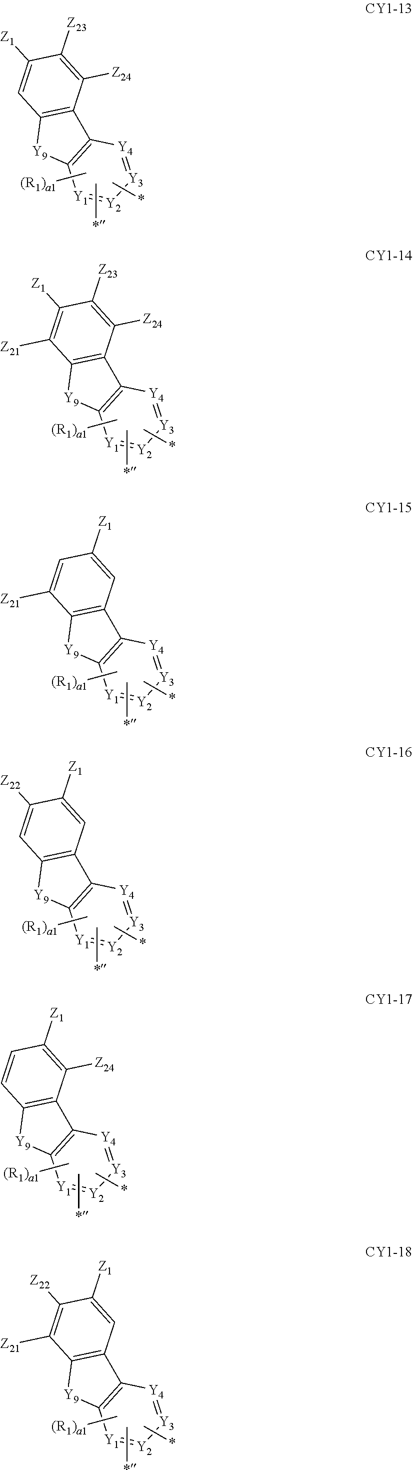 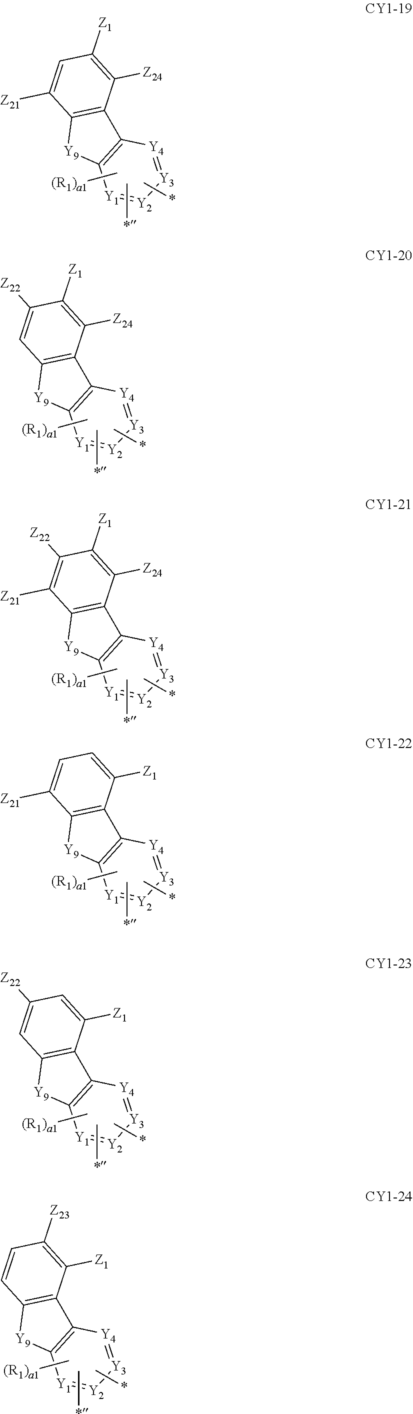 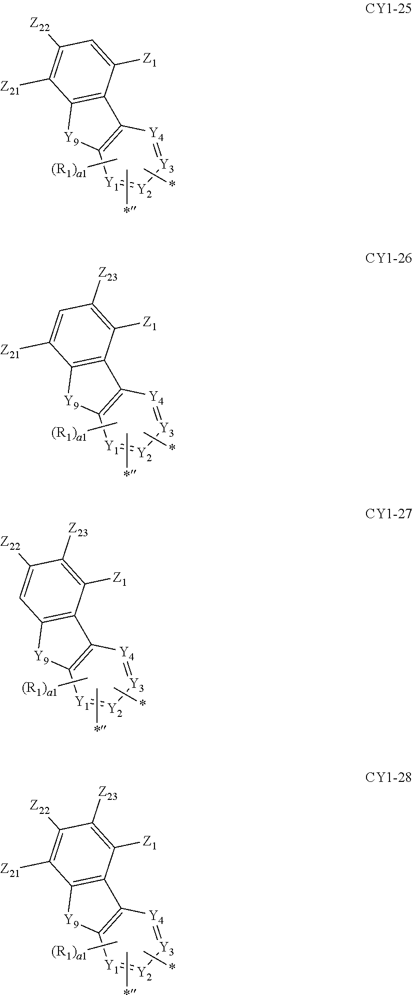
wherein, in Formulae CY1-1 to CY1-28,
Y₁ to Y₄, Y₉, Z₁, R₁, and a1 are each independently as described in claim 1,
Z₂₁ to Z₂₄ are each independently as described in connection with Z₂ in claim 1 and are not hydrogen,
* indicates a binding site to iridium in Formula 1, and
*″ indicates a binding site to ring CY₂ in Formula 1.

12. The organometallic compound of claim 11, wherein, in Formulae CY1-1 to CY1-28, Y₂ is N bonded to Ir in Formula 1, and Y₁ is C bonded to ring CY₂ in Formula 1.

13. The organometallic compound of claim 1, wherein a group represented by 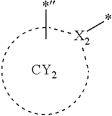
in Formula 1 is a group represented by one of Formulae CY2(1) to CY2(22): 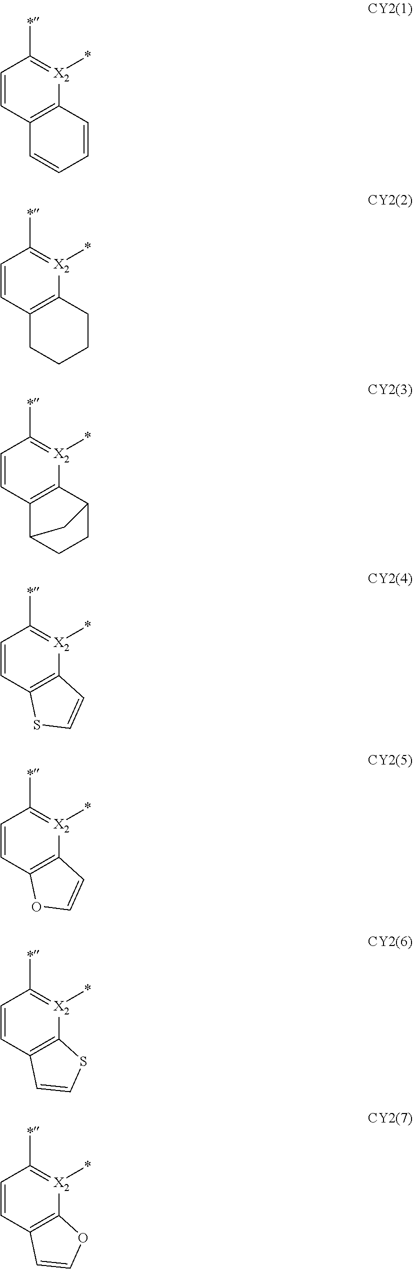 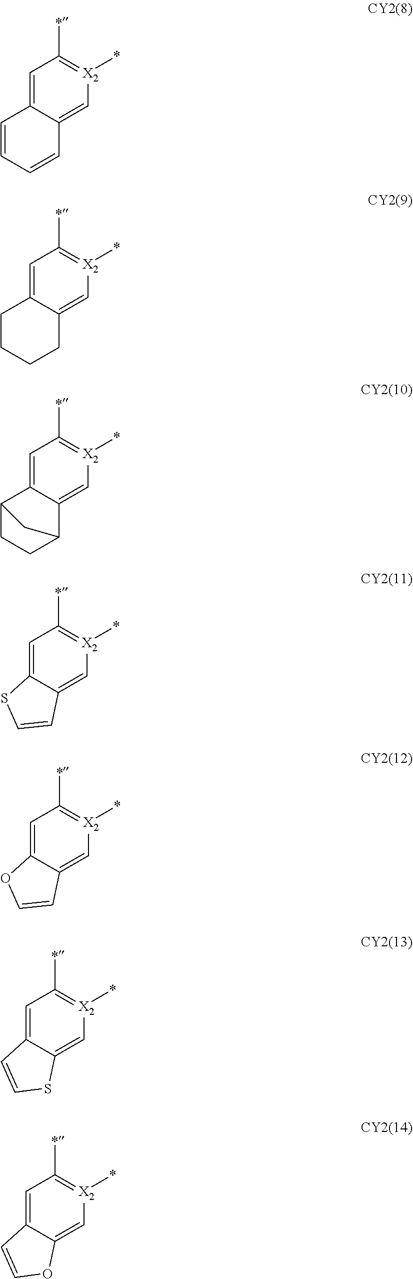 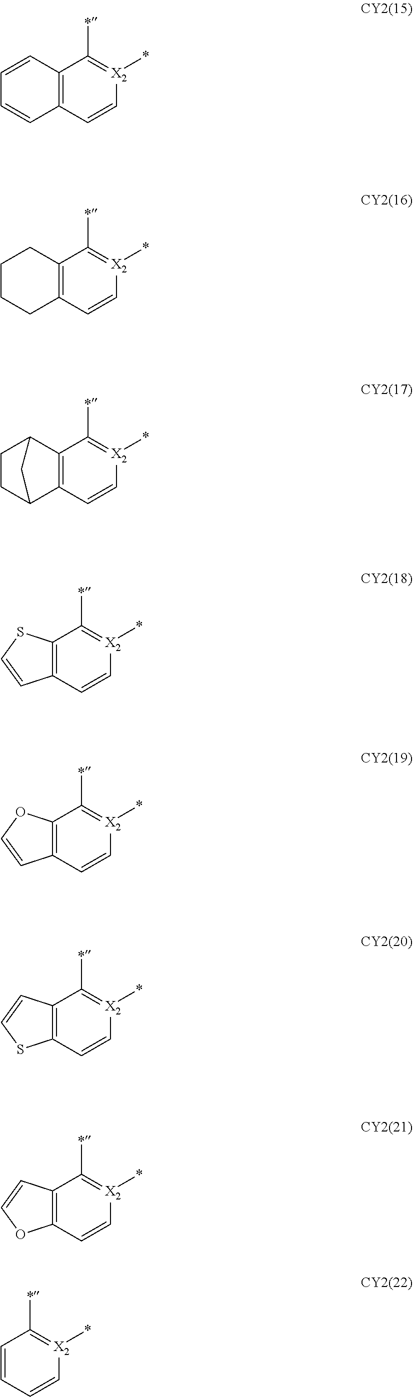
wherein, in Formulae CY2(1) to CY2(22),
X₂ is as described in claim 1,
* indicates a binding site to iridium in Formula 1, and
*″ indicates a binding site to one of Y₁ to Y₄ in Formula 1.

14. The organometallic compound of claim 1, wherein a group represented by 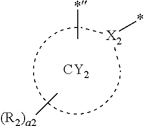
in Formula 1 is a group represented by one of Formulae CY2-1 to CY2-6: 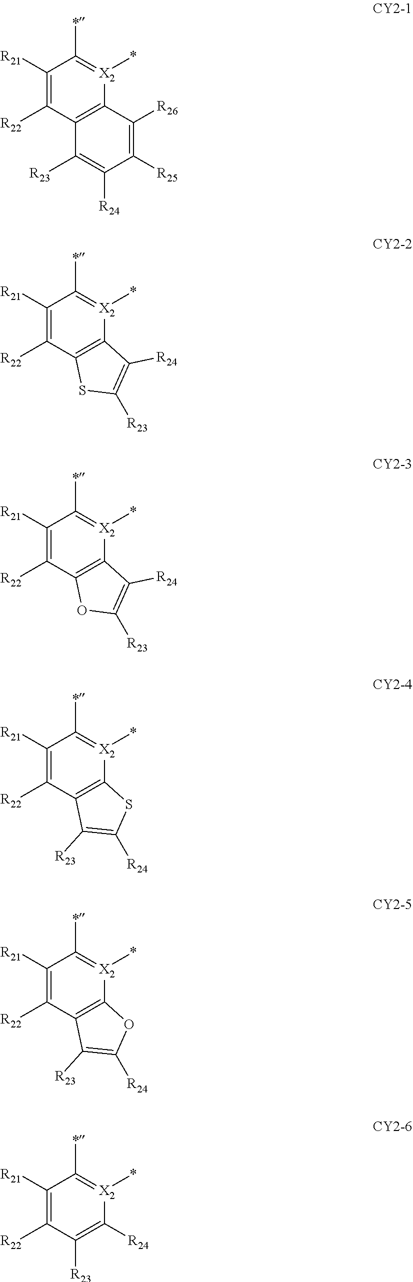
wherein, in Formulae CY2-1 to CY2-6,
X₂ is as described in claim 1,
R₂₁ to R₂₆ are each independently as described in connection with R₂ in claim 1,
Two or more of R₂₁ to R₂₆ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
R₁₀ₐ is as described in connection with R₁ in claim 1,
* indicates a binding site to iridium in Formula 1, and
*″ indicates a binding site to one of Y₁ to Y₄ in Formula 1.

15. The organometallic compound of claim 14, wherein, in Formula CY2-1, R₂₁ and R₂₃ to R₂₆ are each hydrogen, and R₂₂ comprises at least one carbon atom.

16. The organometallic compound of claim 1, wherein the organometallic compound is one of Compounds 1 to 18:

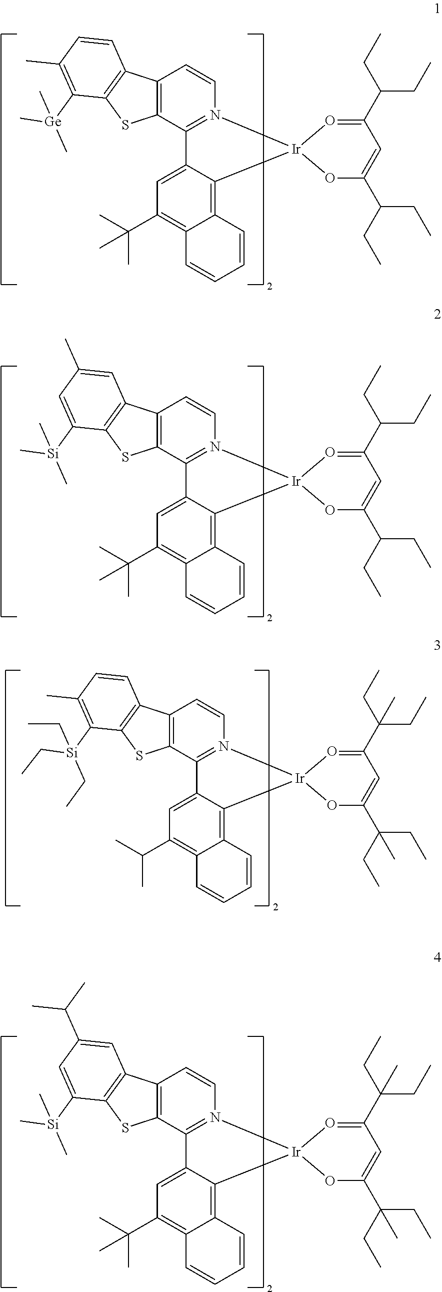

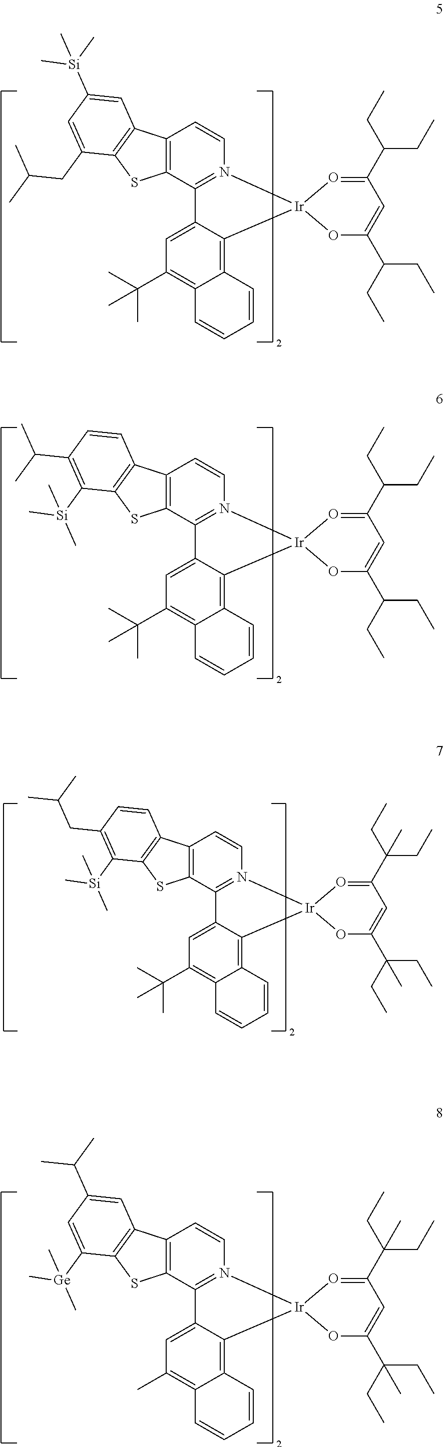

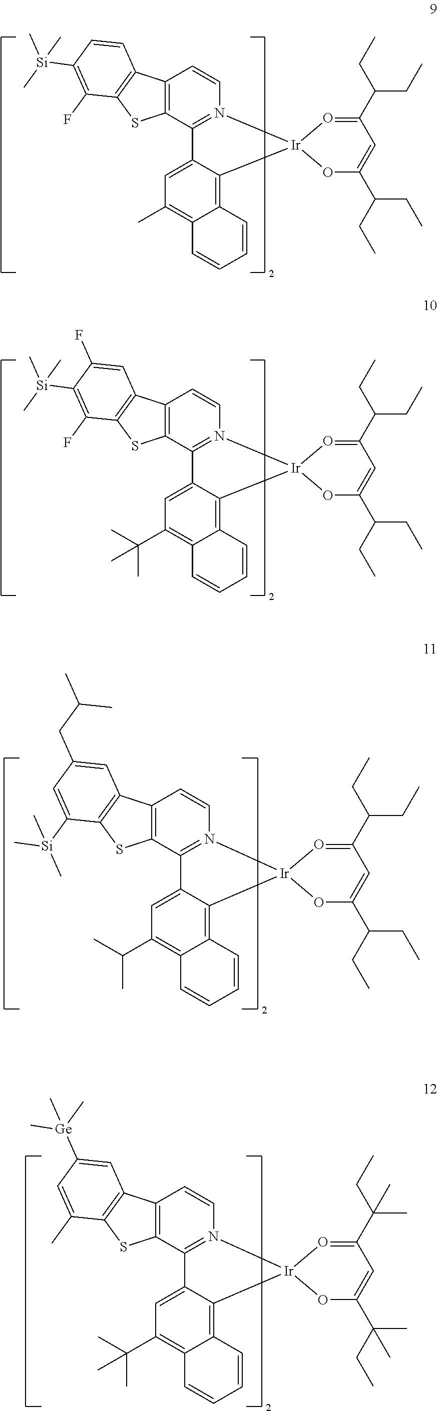

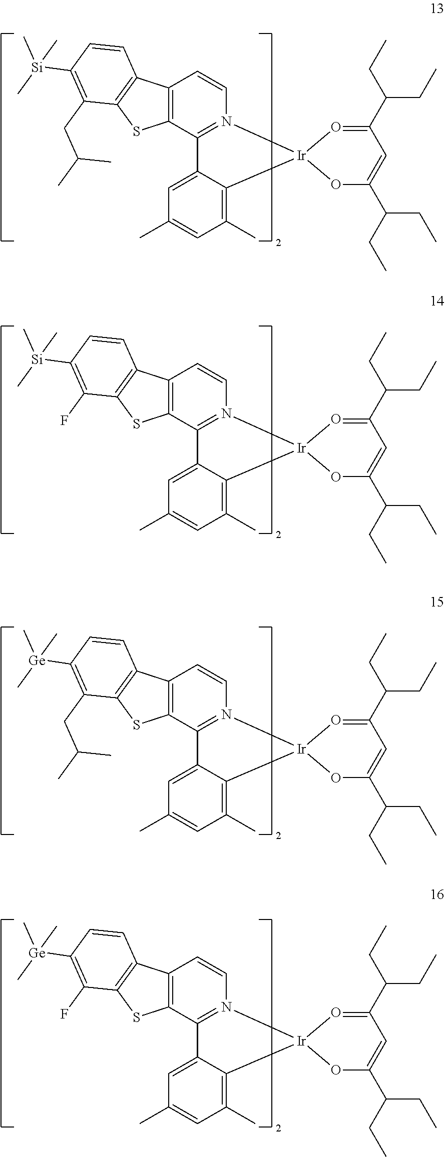

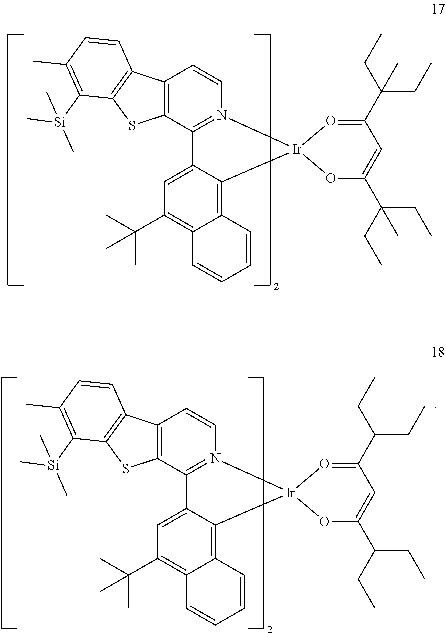

17. A light-emitting device, comprising:
a first electrode;
a second electrode; and
an organic layer arranged between the first electrode and the second electrode,
wherein the organic layer comprises an emission layer, and
wherein the organic layer comprises at least one organometallic compound of claim 1.

18. The light-emitting device of claim 17, wherein the emission layer comprises the organometallic compound.

19. The light-emitting device of claim 18, wherein the emission layer emits a red light having a maximum emission wavelength of 580 nanometers to 730 nanometers.

20. An electronic apparatus, comprising the light-emitting device of claim 17.
